(19) United States
(12) Patent Application Publication
(10) Pub. No.: US 2024/0237435 A1
(43) Pub. Date: Jul. 11, 2024

(54) Semiconductor Device, Display Apparatus, and Electronic Device

(71) Applicant: Semiconductor Energy Laboratory Co., Ltd., Kanagawa-ken (JP)

(72) Inventors: Kazuki TSUDA, Atsugi, Kanagawa (JP); Hidefumi RIKIMARU, Tama, Tokyo (JP); Satoru OHSHITA, Hadano, Kanagawa (JP); Hiromichi GODO, Isehara, Kanagawa (JP); Yoshiyuki KUROKAWA, Sagamihara, Kanagawa (JP)

(73) Assignee: Semiconductor Energy Laboratory Co., Ltd., Kanagawa-ken (JP)

(21) Appl. No.: 18/288,495

(22) PCT Filed: Apr. 20, 2022
(86) PCT No.: PCT/IB2022/053665

§ 371 Date: Oct. 26, 2023

(30) Foreign Application Priority Data
Apr. 30, 2021 (JP) 2021-077410

(51) Int. Cl. H10K 59/131

(52) U.S. Cl. CPC H10K 59/131

(57) ABSTRACT

A semiconductor device with reduced circuit area is provided. The semiconductor device includes first and second cell arrays and a first converter circuit. The first cell array includes a first cell and a second cell in the same row, and the second cell array includes third and fourth cells in the same row. The first cell is electrically connected to first and second wirings, the second cell is electrically connected to the first and third wirings, the third cell is electrically connected to fourth and sixth wirings, and the fourth cell is electrically connected to fifth and seventh wirings. The sixth wiring is electrically connected to the seventh wiring. The first to fourth cells each have a function of outputting current corresponding to a product of retained data and input data. Specifically, the first cell, the second cell, the third cell, and the fourth cell output current to the second wiring, the third wiring, the sixth wiring, and the seventh wiring, respectively. The first converter circuit has a function of making data corresponding to a total amount of current flowing through the second and third wirings flow to the fourth and fifth wirings, respectively.

### TECHNICAL FIELD

One embodiment of the present invention relates to a semiconductor device, a display apparatus, and an electronic device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting device, a power storage device, an imaging device, a memory device, a signal processing device, a processor, an electronic device, a system, a driving method thereof, a manufacturing method thereof, and a testing method thereof.

### BACKGROUND ART

Integrated circuits that imitate the mechanism of the human brain are currently under active development. The integrated circuits incorporate electronic circuits as the brain mechanism and include circuits corresponding to “neurons” and “synapses” of the human brain. Such integrated circuits may therefore be called “neuromorphic”, “brain-morphic”, or “brain-inspired” circuits, for example. The integrated circuits have a non-von Neumann architecture and are expected to be able to perform parallel processing with extremely low power consumption as compared with a von Neumann architecture, in which power consumption increases with increasing processing speed.

An information processing model that imitates a biological neural network including “neurons” and “synapses” is called an artificial neural network (ANN). For example, Non-Patent Document 1 and Non-Patent Document 2 each disclose an arithmetic device including an artificial neural network constructed using an SRAM (Static Random Access Memory).

An attempt has been made to use an arithmetic device in which an artificial neural network is constructed, for example, for correction of images to be displayed by a display apparatus. For example, in a display apparatus disclosed in Patent Document 1, an arithmetic circuit in which an artificial neural network is constructed is used to adjust the luminance and tone of displayed images in accordance with the preference of the user.

### REFERENCES

### Patent Document

[Patent Document 1] Japanese Published Patent Application No. 2018-36639

### Non-Patent Documents

[Non-Patent Document 1] M. Kang et al., “IEEE Journal Of Solid-State Circuits”, 2018, Volume 53, No. 2, pp. 642-655.
[Non-Patent Document 2] J. Zhang et al., “IEEE Journal Of Solid-State Circuits”, 2017, Volume 52, No. 4, pp. 915-924.

### SUMMARY OF THE INVENTION

### Problems to be Solved by the Invention

Examples of an arithmetic device in which an artificial neural network is constructed include an arithmetic circuit that performs product-sum operation by yielding the sum of analog currents each corresponding to the product of a weight coefficient and input data. Since the arithmetic circuit uses analog current for arithmetic operation, the circuit scale can be smaller than that of an arithmetic circuit formed of a digital circuit and the circuit area can be small. Furthermore, the arithmetic circuit can have lower power consumption when designed such that the analog current used in the arithmetic operation becomes lower.

The above-described arithmetic circuit, for example, has a structure including a cell array where arithmetic cells, each of which multiplies a weight coefficient and input data and outputs the product as analog current, are arranged in a matrix. For example, with the structure of yielding the sum of analog currents that are output by the arithmetic cells arranged in one column, where the amount of added analog currents can be regarded as a product-sum value of a weight coefficient and input data, arithmetic operation can be performed at higher speed than product-sum operation using a digital circuit.

In a hierarchical neural network, which is an artificial neural network, the number of neurons is different in each hierarchy. For example, the number of neurons included in one layer corresponds to the number of products summed in product-sum operation; thus, the number of arithmetic cells necessary for each calculation (for each layer) varies in the above-described arithmetic circuit. Accordingly, when product-sum operation in each of the layers of a hierarchical neural network is performed in an arithmetic circuit of the same cell array size, there may be an arithmetic cell that is not used for arithmetic operation depending on the layer. That is, increasing the number of arithmetic cells in a cell array of an arithmetic circuit is suitable for performing a large-scale calculation (a calculation in which a large number of products are summed); however, when a small-scale calculation (a calculation in which a small number of products are summed) is performed, the number of arithmetic cells that are not used for arithmetic operation is increased, and thus arithmetic efficiency per area is decreased.

An object of one embodiment of the present invention is to provide a semiconductor device with reduced circuit area. Another object of one embodiment of the present invention is to provide a semiconductor device in which arithmetic efficiency per area does not decrease even when a small-scale calculation is performed. Another object of one embodiment of the present invention is to provide a display apparatus including any of the above semiconductor devices. Another object of one embodiment of the present invention is to provide an electronic device including the above display apparatus. Another object of one embodiment of the present invention is to provide a novel semiconductor device, a novel display apparatus, or a novel electronic device.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all the objects listed above and the other objects.

### Means for Solving the Problems

(1)

One embodiment of the present invention is a semiconductor device including a first cell array, a second cell array, and a first converter circuit. The first cell array includes a first cell and a second cell positioned in the same row as the first cell, and the second cell array includes a third cell and a fourth cell positioned in the same row as the third cell. The first converter circuit includes a plurality of input terminals and a plurality of output terminals. The first cell is electrically connected to a first wiring and a second wiring, and the second cell is electrically connected to the first wiring and a third wiring. Each of the plurality of input terminals of the first converter circuit is electrically connected to the second wiring and the third wiring, and each of the plurality of output terminals of the first converter circuit is electrically connected to a fourth wiring and a fifth wiring. The third cell is electrically connected to the fourth wiring and a sixth wiring, and the fourth cell is electrically connected to the fifth wiring and a seventh wiring. The sixth wiring is electrically connected to the seventh wiring. The first cell has a function of making a first current with an amount corresponding to a product of a first data retained in the first cell and a second data input from the first wiring to the first cell flow to the second wiring. The second cell has a function of making a second current with an amount corresponding to a product of a third data retained in the second cell and a fourth data input from the first wiring to the second cell flow to the third wiring. The first converter circuit has a function of making a fifth data corresponding to a total amount of current flowing from the second wiring flow to the fourth wiring and a function of making a sixth data corresponding to a total amount of current flowing from the third wiring flow to the fifth wiring. The third cell has a function of making a third current with an amount corresponding to a product of a seventh data retained in the third cell and the fifth data input from the fourth wiring to the third cell flow to the sixth wiring. The fourth cell has a function of making a fourth current with an amount corresponding to a product of an eighth data retained in the fourth cell and the sixth data input from the fifth wiring to the fourth cell flow to the seventh wiring.

(2)

In (1), one embodiment of the present invention may include a second converter circuit. In particular, it is preferable that the second converter circuit include an input terminal and an output terminal and the input terminal of the second converter circuit be electrically connected to the sixth wiring. The second converter circuit preferably has a function of outputting a ninth data corresponding to a total amount of current flowing from the sixth wiring to the output terminal of the second converter circuit.

(3)

In (1) or (2), one embodiment of the present invention may include a fifth cell, a sixth cell, and a seventh cell. In particular, the first cell, the second cell, the third cell, and the fourth cell each preferably include a first transistor, a second transistor, and a first capacitor. The fifth cell, the sixth cell, and the seventh cell each preferably include a third transistor, a fourth transistor, and a second capacitor. In each of the first cell, the second cell, the third cell, and the fourth cell, it is preferably that a gate of the first transistor be electrically connected to a first terminal of the first capacitor and a first terminal of the second transistor and a first terminal of the first transistor be electrically connected to a second terminal of the second transistor. In the first cell, it is preferable that the first terminal of the first transistor be electrically connected to the second wiring and a second terminal of the first capacitor be electrically connected to the first wiring. In the second cell, it is preferable that the first terminal of the first transistor be electrically connected to the third wiring and a second terminal of the first capacitor be electrically connected to the first wiring. In the third cell, it is preferable that the first terminal of the first transistor be electrically connected to the sixth wiring and a second terminal of the first capacitor be electrically connected to the fourth wiring. In the fourth cell, it is preferable that the first terminal of the first transistor be electrically connected to the seventh wiring and a second terminal of the first capacitor be electrically connected to the fifth wiring. In each of the fifth cell, the sixth cell, and the seventh cell, it is preferable that a gate of the third transistor be electrically connected to a first terminal of the second capacitor and a first terminal of the fourth transistor and a first terminal of the third transistor be electrically connected to a second terminal of the fourth transistor. In the fifth cell, it is preferable that the first terminal of the third transistor be electrically connected to the first wiring and a second terminal of the second capacitor be electrically connected to the first wiring. In the sixth cell, it is preferable that the first terminal of the third transistor be electrically connected to the fourth wiring and a second terminal of the second capacitor be electrically connected to the fourth wiring. In the seventh cell, it is preferable that the first terminal of the third transistor be electrically connected to the fifth wiring and a second terminal of the second capacitor be electrically connected to the fifth wiring.

(4)

In (3), one embodiment of the present invention may include a first circuit and a second circuit, in which the first circuit is electrically connected to the first wiring and the second circuit is electrically connected to the fourth wiring and the fifth wiring. It is preferable that the first circuit have a function of inputting the second data to the first wiring and the second circuit have a function of making current flow to the fourth wiring and the fifth wiring.

(5)

One embodiment of the present invention is a display apparatus including a first layer including the semiconductor device of any one of (1) to (4) and a second layer including a display portion, and the second layer includes a region overlapping with the first layer.

(6)

One embodiment of the present invention is an electronic device including the display apparatus of (5) and a housing.

Note that in this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, a memory device, a display apparatus, a light-emitting device, a lighting device, and an electronic device themselves are semiconductor devices or include semiconductor devices in some cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Each of X and Y denotes an object (e.g., a device, an element, a circuit, a wiring, an electrode, a terminal, a conductive film, and a layer).

For example, in the case where X and Y are electrically connected, one or more elements that allow electrical connection between X and Y (e.g., a switch, a transistor, a capacitor, an inductor, a resistor, a diode, a display apparatus, a light-emitting device, and a load) can be connected between X and Y. Note that a switch has a function of being controlled to be turned on or off. That is, the switch has a function of being in a conducting state (on state) or a non-conducting state (off state) to control whether current flows or not.

For example, in the case where X and Y are functionally connected, one or more circuits that allow functional connection between X and Y (e.g., a logic circuit (e.g., an inverter, a NAND circuit, and a NOR circuit); a signal converter circuit (e.g., a digital-analog converter circuit, an analog-digital converter circuit, and a gamma correction circuit); a potential level converter circuit (e.g., a power supply circuit (e.g., a step-up circuit and a step-down circuit) and a level shifter circuit for changing the potential level of a signal); a voltage source; a current source; a switching circuit; an amplifier circuit (e.g., a circuit that can increase signal amplitude, the current amount, or the like, an operational amplifier, a differential amplifier circuit, a source follower circuit, and a buffer circuit); a signal generation circuit; a memory circuit; and a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

This specification describes a circuit structure in which a plurality of elements are electrically connected to a wiring (a wiring for supplying a constant potential or a wiring for transmitting a signal). For example, in the case in which X is directly connected to a wiring and Y is directly connected to the wiring, this specification may describe that X and Y are directly electrically connected to each other.

It can be expressed as, for example, “X, Y, and a source (or a first terminal or the like) and a drain (or a second terminal or the like) of a transistor are electrically connected to each other, and X, the source (or the first terminal or the like) of the transistor, the drain (or the second terminal or the like) of the transistor, and Y are electrically connected in this order”. Alternatively, it can be expressed as “a source (or a first terminal or the like) of a transistor is electrically connected to X; a drain (or a second terminal or the like) of the transistor is electrically connected to Y; and X, the source (or the first terminal or the like) of the transistor, the drain (or the second terminal or the like) of the transistor, and Y are electrically connected to each other in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit structure is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film has functions of both of the components that are a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” sometimes includes a wiring having a resistance value, a transistor in which current flows between its source and drain, a diode, and a coil. Thus, the term “resistor” can be sometimes replaced with the terms “resistance”, “load”, “region having a resistance value”, and the like. Conversely, the terms “resistance”, “load”, “region having a resistance value”, and the like can be sometimes replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The terms “capacitor”, “parasitic capacitance”, “gate capacitance”, and the like can be replaced with the term “capacitance” in some cases. Conversely, the term “capacitance” can be replaced with the term “capacitor”, “parasitic capacitance”, or “gate capacitance” in some cases. The term “pair of electrodes” of “capacitor” can be replaced with “pair of conductors”, “pair of conductive regions”, or “pair of regions”. Note that the electrostatic capacitance value can be higher than or equal to 0.05 fF and lower than or equal to 10 μF, for example. As another example, the electrostatic capacitance value may be higher than or equal to 1 μF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source”, “drain”, and the like can be sometimes rephrased with one another in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the withstand voltage of the transistor can be increased (the reliability can be improved). Alternatively, with the multi-gate structure, drain-source current does not change very much even if drain-source voltage changes at the time of operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit or a current mirror circuit having excellent properties can be obtained, for example.

The case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal or a wiring can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit, and a potential output from a circuit change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with a positive charge moves, and the amount of current is expressed as a positive value. In other words, the direction in which a carrier with a negative charge moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A”. The description “current is input to element A” can be rephrased as “current is output from element A”.

Ordinal numbers such as “first”, “second”, and “third” in this specification and the like are used to avoid confusion among components. Thus, the terms do not limit the number of components. In addition, the terms do not limit the order of components. In this specification and the like, for example, a “first” component in one embodiment can be referred to as a “second” component in other embodiments or the scope of claims. As another example, a “first” component in one embodiment in this specification and the like can be omitted in other embodiments or the scope of claims.

In this specification and the like, the terms for describing positioning, such as “over” and “under”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed on and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relation between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film”, “layer”, and the like can be interchanged with each other depending on the situation. For example, the term “conductive layer” can be changed into the term “conductive film” in some cases. As another example, the term “insulating film” can be changed into the term “insulating layer” in some cases. Alternatively, the terms “film”, “layer”, and the like are not used and can be interchanged with another term depending on the case or the situation. For example, the term “conductive layer” or “conductive film” can be changed into the term “conductor” in some cases. As another example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode”, “wiring”, or the like can also mean, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings” or “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region” or the like depending on the case.

In this specification and the like, the terms “wiring”, “signal line”, “power supply line”, and the like can be interchanged with each other depending on the case or the situation. For example, the term “wiring” can be changed into the term “signal line” in some cases. As another example, the term “wiring” can be changed into the term “power supply line” in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, an impurity in a semiconductor refers to, for example, an element other than a main component of a semiconductor layer. For example, an element with a concentration of lower than 0.1 atomic % is an impurity. When an impurity is contained, for example, the density of defect states in a semiconductor is increased, carrier mobility is decreased, or crystallinity is decreased in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. Specifically, in the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to determine whether current flows or not. Alternatively, a switch has a function of selecting and changing a current path. Thus, a switch may have two or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device with a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when emission colors of a first light-emitting layer and a second light-emitting layer are complementary colors, the light-emitting device can be configured to emit white light as a whole. When white light emission is obtained using three or more light-emitting layers, the light-emitting device is configured to emit white light as a whole by combining emission colors of the three or more light-emitting layers.

A device with a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the case of a single structure. In the device with a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. The light-emitting device having an SBS structure is suitable for the case where the power consumption is required to be low. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 850 and less than or equal to 950 is also included. Furthermore, “approximately perpendicular” or “substantially perpendicular” indicates a state where two straight lines are placed at an angle greater than or equal to 60° and less than or equal to 120°.

### Effect of the Invention

According to one embodiment of the present invention, a semiconductor device with reduced circuit area can be provided. According to another embodiment of the present invention, a semiconductor device in which arithmetic efficiency per area does not decrease even when a small-scale calculation is performed can be provided. According to another embodiment of the present invention, a display apparatus including any of the above semiconductor devices can be provided. According to another embodiment of the present invention, an electronic device including the above display apparatus can be provided. According to another embodiment of the present invention, a novel semiconductor device, a novel display apparatus, or a novel electronic device can be provided.

Note that the effects of one embodiment of the present invention are not limited to the effects listed above. The effects listed above do not preclude the existence of other effects. Note that the other effects are effects that are not described in this section and will be described below. The effects that are not described in this section are derived from the description of the specification, the drawings, and the like and can be extracted as appropriate from the description by those skilled in the art. Note that one embodiment of the present invention has at least one of the effects listed above and the other effects. Accordingly, depending on the case, one embodiment of the present invention does not have the effects listed above in some cases.

### BRIEF DESCRIPTION OF THE DRAWINGS

FIG. 1 is a block diagram illustrating a structure example of a semiconductor device.

FIG. 2 is a block diagram illustrating a structure example of a semiconductor device.

FIG. 3 is a circuit diagram illustrating a structure example of a semiconductor device.

FIG. 4A is a block diagram illustrating a structure example of a circuit included in a semiconductor device, FIG. 4B is a circuit diagram illustrating a structure example of the circuit included in the semiconductor device, and FIG. 4C is a block diagram illustrating a structure example of the circuit included in the semiconductor device.

FIG. 5A to FIG. 5D are circuit diagrams illustrating structure examples of a circuit included in a semiconductor device.

FIG. 6 is a circuit diagram illustrating a structure example of a circuit included in a semiconductor device.

FIG. 7 is a timing chart showing an operation example of a semiconductor device.

FIG. 8 is a circuit diagram illustrating a structure example of a circuit included in a semiconductor device.

FIG. 9 is a block diagram illustrating a structure example of a semiconductor device.

FIG. 10 is a block diagram illustrating a structure example of a circuit included in a semiconductor device.

FIG. 11 is a circuit diagram illustrating a structure example of a semiconductor device.

FIG. 12A and FIG. 12B are circuit diagrams illustrating structure examples of circuits included in a semiconductor device.

FIG. 13 is a block diagram illustrating a structure example of a semiconductor device.

FIG. 14 is a block diagram illustrating a structure example of a display apparatus.

FIG. 15 is a diagram illustrating a structure example of a display apparatus.

FIG. 16A and FIG. 16B are diagrams illustrating a hierarchical neural network.

FIG. 17 is a schematic cross-sectional view illustrating a structure example of a display apparatus.

FIG. 18A to FIG. 18D are schematic views illustrating structure examples of a light-emitting device.

FIG. 19 is a schematic cross-sectional view illustrating a structure example of a display apparatus.

FIG. 20A and FIG. 20B are schematic cross-sectional views illustrating structure examples of a display apparatus.

FIG. 21A and FIG. 21B are schematic cross-sectional views illustrating structure examples of a display apparatus.

FIG. 22A and FIG. 22B are schematic cross-sectional views illustrating structure examples of a display apparatus.

FIG. 23A and FIG. 23B are schematic cross-sectional views illustrating structure examples of a display apparatus.

FIG. 24A to FIG. 24F are cross-sectional views illustrating examples of a method for manufacturing a display apparatus.

FIG. 25A is a circuit diagram illustrating a structure example of a pixel circuit included in a display apparatus, and FIG. 25B is a schematic perspective view illustrating a structure example of the pixel circuit included in the display apparatus.

FIG. 26A to FIG. 26D are circuit diagrams illustrating structure examples of a pixel circuit included in a display apparatus.

FIG. 27A to FIG. 27D are circuit diagrams illustrating structure examples of pixel circuits included in a display apparatus.

FIG. 28A and FIG. 28B are plan views illustrating structure examples of a light-emitting device and a light-receiving device included in a display apparatus.

FIG. 29A to FIG. 29D are schematic cross-sectional views illustrating a structure example of a light-emitting device, a light-receiving device, and a connection electrode included in a display apparatus.

FIG. 30A to FIG. 30G are plan views illustrating examples of a pixel.

FIG. 31A to FIG. 31F are plan views illustrating examples of a pixel.

FIG. 32A to FIG. 32H are plan views illustrating examples of a pixel.

FIG. 33A to FIG. 33D are plan views illustrating examples of a pixel.

FIG. 34A to FIG. 34D are plan views illustrating examples of a pixel, and FIG. 34E is a cross-sectional view illustrating an example of a display apparatus.

FIG. 35A and FIG. 35B are diagrams illustrating a structure example of a display module.

FIG. 36A to FIG. 36F are diagrams illustrating structure examples of an electronic device.

FIG. 37A to FIG. 37D are diagrams illustrating structure examples of electronic devices.

FIG. 38A to FIG. 38C are diagrams illustrating structure examples of an electronic device.

### MODE FOR CARRYING OUT THE INVENTION

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be formed.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, some components might not be illustrated for clarity of the drawings.

In this specification, a plan view is sometimes used to explain a structure in each embodiment. A plan view is a diagram illustrating the appearance of a plane (section) of a structure cut in the horizontal direction, for example. Hidden lines (e.g., dashed lines) in a plan view can indicate the positional relation between a plurality of components included in a structure or the overlapping relation between the plurality of components. In this specification and the like, the term “plan view” can be replaced with the term “projection view”, “top view”, or “bottom view”. A plane (section) of a structure cut in a direction other than the horizontal direction may be referred to as a plan view depending on circumstances.

In this specification, a cross-sectional view is sometimes used to explain a structure in each embodiment. A cross-sectional view is a diagram illustrating the appearance of a plane (section) of a structure cut in the vertical direction, for example. In this specification and the like, the term “cross-sectional view” can be replaced with the term “front view” or “side view”. A plane (section) of a structure cut in a direction other than the vertical direction may be referred to as a cross-sectional view depending on circumstances.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes denoted without such identification signs in this specification and the like when the components do not need to be distinguished from each other.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes, values, or the like shown in the drawings. For example, variations in signal, voltage, or current due to noise, variations in signal, voltage, or current due to difference in timing, or the like can be included.

### Embodiment 1

In this embodiment, a semiconductor device of one embodiment of the present invention is described.

### Structure Example 1

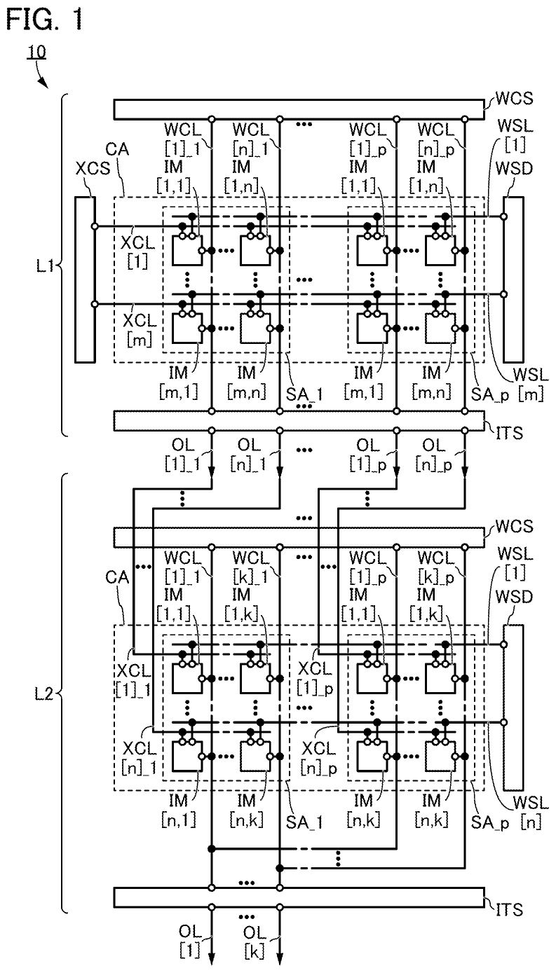

FIG. 1 is a block diagram illustrating a structure example of an arithmetic circuit which is the semiconductor device of one embodiment of the present invention. The arithmetic circuit has a function of performing product-sum operation of a plurality of pieces of first data and a plurality of pieces of second data and a function of performing function operation using the result of product-sum operation as an input value, for example. The product-sum arithmetic circuit has a function of performing arithmetic operation of a hierarchical neural network, for example.

An arithmetic circuit 10 illustrated in FIG. 1 includes a region L1 and a region L2, for example. The region L1 and the region L2 each include a cell array CA, a circuit WCS, a circuit WSD, and a circuit ITS, for example. The region L1 is different from the region L2 in that a circuit XCS is included.

In each of the region L1 and the region L2, a plurality of arithmetic cells are arranged in a matrix in the cell array CA, for example. The cell array CA is divided into a plurality of subarrays, for example. Specifically, the plurality of arithmetic cells arranged in the cell array CA are divided into regions of a subarray SA_1 to a subarray SA_p (p is an integer greater than or equal to 2) in each of the region L1 and the region L2, for example.

In the region L1, the subarray SA_1 to the subarray SA_p each include a plurality of cells IM that function as arithmetic cells, for example. In particular, in each of the subarray SA_1 to the subarray SA_p included in the region L1, the cells IM are arranged in a matrix of m rows and n columns (m is an integer greater than or equal to 1 and n is an integer greater than or equal to 1). Thus, in FIG. 1, m×n×p cells IM are provided in the cell array CA.

In the region L2, the subarray SA_1 to the subarray SA_p each include a plurality of cells IM that function as arithmetic cells, for example. In particular, in each of the subarray SA_1 to the subarray SA_p included in the region L2, the cells IM are arranged in a matrix of n rows and k columns (k is an integer greater than or equal to 1). Thus, in FIG. 1, n×k×p cells IM are provided in the cell array CA.

Here, k=n is satisfied so that the number of columns in the cell array CA in the region L1 is equal to the number of columns in the cell array CA in the region L2. When the arithmetic circuit 10 is viewed as a whole, it is possible to efficiently arrange the cells IM by making the number of columns in the cell array CA in the region L1 equal to the number of columns in the cell array CA in the region L2; thus, an area needed for forming the arithmetic circuit 10 can be reduced.

Note that the [,] added to the cell IM illustrated in FIG. 1 shows the address of the cell IM in the subarray; for example, the cell IM[x,y] shows that the cell IM[x,y] is positioned in the x-th row and the y-th column in the subarray.

In the region L1, the circuit WCS is electrically connected to a wiring WCL[1]_1 to a wiring WCL[n]_1 and a wiring WCL[1]_p to a wiring WCL[n]_p, for example. Although not illustrated in FIG. 1, when p is 3 or more, the circuit WCS is electrically connected to the wiring WCL[1] to the wiring WCL[n] in the subarray SA other than the subarray SA_1 and the subarray SA_p. The circuit ITS is electrically connected to the wiring WCL[1]_1 to the wiring WCL[n]_1 and the wiring WCL[1]_p to the wiring WCL[n]_p, for example. Although not illustrated in FIG. 1, when p is 3 or more, the circuit ITS is electrically connected to the wiring WCL[1] to the wiring WCL[n] in the subarray SA other than the subarray SA_1 and the subarray SA_p.

The wiring WCL[1]_1 to the wiring WCL[n]_1 are electrically connected to the cells IM included in the subarray SA_1. Specifically, the wiring WCL[1]_1 is electrically connected to a cell IM[1,1] to a cell IM[m,1] arranged in the first column in the subarray SA_1, and the wiring WCL[n]_1 is electrically connected to a cell IM[1,n] to a cell IM[m,n] arranged in the n-th column in the subarray SA_1. The wiring WCL[1]_p to the wiring WCL[n]_p are electrically connected to the cells IM included in the subarray SA_p. Specifically, the wiring WCL[1]_p is electrically connected to the cell IM[1,1] to the cell IM[m,1] arranged in the first column in the subarray SA_p, and the wiring WCL[n]_p is electrically connected to the cell IM[1,n] to the cell IM[m,n] arranged in the n-th column in the subarray SA_p.

In the region L1, the circuit XCS is electrically connected to a wiring XCL[1] to a wiring XCL[m], for example.

The wiring XCL[1] to the wiring XCL[m] are electrically connected to the cells IM included in the subarray SA_1 to the subarray SA_p. Specifically, the wiring XCL[1] is electrically connected to the cell IM[1,1] to the cell IM[1,n] arranged in the first row in each of the subarray SA_1 to the subarray SA_p. The wiring XCL[m] is electrically connected to the cell IM[m,1] to the cell IM[m,n] arranged in the m-th row in each of the subarray SA_1 to the subarray SA_p.

In the region L1, the circuit WSD is electrically connected a wiring WSL[1] to a wiring WSL[m], for example.

The wiring WSL[1] to the wiring WSL[m] are electrically connected to the cells IM included in the subarray SA_1 to the subarray SA_p. Specifically, the wiring WSL[1] is electrically connected to the cell IM[1,1] to the cell IM[1,n] arranged in the first row in each of the subarray SA_1 to the subarray SA_p. The wiring WSL[m] is electrically connected to the cell IM[m,1] to the cell IM[m,n] arranged in the m-th row in each of the subarray SA_1 to the subarray SA_p.

The circuit ITS included in the region L1 is electrically connected to a wiring OL[1]_1 to a wiring OL[n]_1 and a wiring OL[1]_p to a wiring OL[n]_p. Although not illustrated in FIG. 1, when p is 3 or more, the circuit ITS is electrically connected to a wiring OL[1]_s to a wiring OL[n]_s (here, s is an integer greater than or equal to 2 and less than or equal to p−1).

The wiring OL[1]_1 to the wiring OL[n]_1 included in the region L1 are, respectively, electrically connected to a wiring XCL[1]_1 to a wiring XCL[n]_1 included in the region L2 in a one-to-one correspondence, and the wiring OL[1]_p to the wiring OL[n]_p included in the region L1 are, respectively, electrically connected to a wiring XCL[1]_p to a wiring XCL[n]_p included in the region L2 in a one-to-one correspondence.

In the region L2, the circuit WCS is electrically connected to the wiring WCL[1]_1 to the wiring WCL[k]_1 and the wiring WCL[1]_p to the wiring WCL[k]_p, for example. Although not illustrated in FIG. 1, when p is 3 or more, the circuit WCS is electrically connected to the wiring WCL[1] to the wiring WCL[n] in the subarray SA other than the subarray SA_1 and the subarray SA_p.

The wiring WCL[1]_1 is electrically connected to the wiring WCL[1]_p. Although not illustrated in FIG. 1, in the case where p is 3 or more, a wiring WCL[1]_2 to a wiring WCL[1]_p−1 which extend in the first columns in different subarrays SA from each other are electrically connected to the wiring WCL[1]_1. The wiring WCL[k]_1 is electrically connected to the wiring WCL[k]_p. Although not illustrated, in the case where p is 3 or more, a wiring WCL[k]_2 to a wiring WCL[k]_p−1 which extend in the k-th columns in different subarrays SA from each other are electrically connected to the wiring WCL[k]_1.

The wiring WCL[1]_1 to the wiring WCL[k]_1 are electrically connected to the cells IM included in the subarray SA_1. Specifically, the wiring WCL[1]_1 is electrically connected to the cell IM[1,1] to the cell IM[n,1] arranged in the first column in the subarray SA_1, and the wiring WCL[k]_1 is electrically connected to a cell IM[1,k] to a cell IM[n,k] arranged in the k-th column in the subarray SA_1. The wiring WCL[1]_p to the wiring WCL[k]_p are electrically connected to the cells IM included in the subarray SA_p. Specifically, the wiring WCL[1]_p is electrically connected to the cell IM[1,1] to the cell IM[n,1] arranged in the first column in the subarray SA_p, and the wiring WCL[k]_p is electrically connected to the cell IM[1,k] to the cell IM[n,k] arranged in the k-th column in the subarray SA_p.

In the region L2, the wiring XCL[1]_1 to the wiring XCL[n]_1 are electrically connected to the cells IM included in the subarray SA_1. Specifically, the wiring XCL[1]_1 is electrically connected to the cell IM[1,1] to the cell IM[1,k] arranged in the first row in the subarray SA_1. The wiring XCL[n]_1 is electrically connected to the cell IM[n,1] to the cell IM[n,k] arranged in the n-th row in the subarray SA_1. The wiring XCL[1]_p to the wiring XCL[n]_p are electrically connected to the cells IM included in the subarray SA_p. Specifically, the wiring XCL[1]_p is electrically connected to the cell IM[1,1] to the cell IM[1,k] arranged in the first row in the subarray SA_p. The wiring XCL[n]_p is electrically connected to the cell IM[n,1] to the cell IM[n,k] arranged in the n-th row in the subarray SA_p.

In the region L2, the circuit WSD is electrically connected to the wiring WSL[1] to a wiring WSL[n], for example.

The wiring WSL[1] to the wiring WSL[n] are electrically connected to the cells IM included in the subarray SA_1 to the subarray SA_p. Specifically, the wiring WSL[1] is electrically connected to the cell IM[1,1] to the cell IM[1,k] arranged in the first row in each of the subarray SA_1 to the subarray SA_p. Additionally, the wiring WSL[n] is electrically connected to the cell IM[n,1] to the cell IM[n,k] arranged in the n-th row in each of the subarray SA_1 to the subarray SA_p.

In the region L2, the wiring WCL[1]_1 to the wiring WCL[k]_1 are electrically connected to the circuit ITS. The circuit ITS is electrically connected to a wiring OL[1] to a wiring OL[k].

Next, the cell IM, the circuit WCS, the circuit XCS, the circuit WSD, and the circuit ITS included in the arithmetic circuit 10 in FIG. 1 are described.

The cells IM included in the region L1 and the region L2 have a function of retaining the first data, for example. The cells IM have a function of outputting current with the amount corresponding to the product of the first data and the second data to the wiring WCL, in response to an input of a signal that serves as the second data.

The circuit WCS in the region L1 has a function of supplying a signal (e.g., one or both of current and voltage) corresponding to the first data to the wiring WCL[1]_1 to the wiring WCL[n]_1 and the wiring WCL[1]_p to the wiring WCL[n]_p, for example. Note that when p is 3 or more, the circuit WCS has a function of supplying a signal corresponding to the first data also to the wiring WCL[1] to the wiring WCL[n] in the subarray SA other than the subarray SA_1 and the subarray SA_p. The circuit WCS in the region L2 has a function of supplying a signal (e.g., one or both of current and voltage) corresponding to the first data to the wiring WCL[1]_1 to the wiring WCL[k]_1 and the wiring WCL[1]_p to the wiring WCL[k]_p, for example. That is, the circuit WCS has a function of supplying the first data to be stored in the cell IM when a writing transistor included in the cell IM is in an on state.

In the region L1, the circuit XCS has a function of supplying a signal (e.g., one or both of current and voltage) corresponding to the second data or reference data, which will be described later, to the wiring XCL[1] to the wiring XCL[m], for example. That is, in the arithmetic circuit 10 in FIG. 1, the circuit XCS has a function of supplying a signal (e.g., one or both of current and voltage) corresponding to the second data or the reference data to each of the cells IM included in the cell array CA in the region L1.

In the region L1, the circuit WSD has a function of selecting a row in the cell array CA to which the first data is to be written, by supplying a predetermined signal to the wiring WSL[1] to the wiring WSL[m] at the time of writing the first data to each of the cells included in the cell array CA, for example. For example, when the circuit WSD supplies the wiring WSL[1] with a high-level potential and supplies the wiring WSL[2] (not illustrated) to the wiring WSL[m] with a low-level potential, writing transistors whose gates are electrically connected to the wiring WSL[1] can be in an on state and writing transistors whose gates are electrically connected to the wiring WSL[2] to the wiring WSL[m] can be in an off state. In the region L2, the circuit WSD, like the circuit WSD included in the region L1, has a function of selecting a row in the cell array CA to which the first data is to be written, by supplying a predetermined signal to the wiring WSL[1] to the wiring WSL[n] at the time of writing the first data to each of the cells included in the cell array CA, for example.

In the region L1, the circuit ITS has a function of converting amounts of current input from the wiring WCL[1]_1 to the wiring WCL[n]_1 and the wiring WCL[1]_p to the wiring WCL[n]_p to voltage values, for example. Note that the amount of current flowing from the wiring WCL[1]_1 to the circuit ITS is the sum of the amounts of current output from the cell IM[1,1] to the cell IM[m,1] in the first column in the subarray SA_1, for example. That is, the sum of the amounts of current corresponds to the result of the product-sum operation of a plurality of pieces of the first data retained in the cell IM[1,1] to the cell IM[m,1] and a plurality of pieces of the second data input to the cell IM[1,1] to the cell IM[m,1]; thus, in the circuit ITS, a voltage value corresponding to the product-sum of the plurality of pieces of first data and the plurality of pieces of second data is generated from the sum of the amounts of current. The circuit ITS may have a function of converting the voltage value into a current amount.

The circuit ITS has a function of transmitting the voltage, current that is converted from the voltage value, or the like as a signal to the wiring OL[1]_1 to the wiring OL[n]_1 and the wiring OL[1]_p to the wiring OL[n]_p. Specifically, the circuit ITS has a function of outputting, to the wiring OL[1]_1, a signal corresponding to the amount of current input from the wiring WCL[1]_1. Similarly, the circuit ITS has a function of outputting, to the wiring OL[n]_1, the wiring OL[1]_p, and the wiring OL[n]_p, respectively, a signal corresponding to the current amount input from the wiring WCL[n]_1, a signal corresponding to the current amount input from the wiring WCL[1]_p, and a signal corresponding to the current amount input from the wiring WCL[n]_p.

In the region L2, the circuit ITS has a function of converting, to voltage values, amounts of current that are input from the wiring WCL[1]_1 to the wiring WCL[k]_1 and the wiring WCL[1]_p to the wiring WCL[k]_p, for example. Note that the amount of current flowing from the wiring WCL[1]_1 and the wiring WCL[1]_p to the circuit ITS is the sum of the amounts of current output from the cell IM[1,1] to the cell IM[n,1] in the first column in each of the subarray SA_1 to the subarray SA_p, for example. That is, the sum of the amounts of current corresponds to the result of the product-sum operation of a plurality of pieces of the first data retained in the cell IM[1,1] to the cell IM[n,1] in the subarray SA_1 to the subarray SA_p and a plurality of pieces of the second data input to the cell IM[1,1] to the cell IM[n,1] in the subarray SA_1 to the subarray SA_p; thus, in the circuit ITS, a voltage value corresponding to the product-sum of the plurality of pieces of first data and the plurality of pieces of second data is generated from the sum of the amounts of current. The circuit ITS may have a function of converting the voltage value into a current amount.

The circuit ITS has a function of transmitting the voltage, current that is converted from the voltage value, or the like as a signal to the wiring OL[1] to the wiring OL[k]. Specifically, the circuit ITS has a function of outputting a signal corresponding to the amount of current input from the wiring WCL[1]_1 to the wiring WCL[1]_p, to the wiring OL[1]. Similarly, the circuit ITS has a function of outputting a signal corresponding to the amount of current input from the wiring WCL[k]_1 to the wiring WCL[k]_p, to the wiring OL[k]_1.

In particular, in the region L1 and the region L2, the circuit ITS may have a function of performing function operation utilizing the product-sum of the plurality of pieces of first data and the plurality of pieces of second data as an input value. The circuit ITS may output the result of the function operation as a signal (e.g., one or both of current and voltage) to the wiring OL[1]_1 to the wiring OL[n]_1 and the wiring OL[1]_p to the wiring OL[n]_p (the wiring OL[1] to the wiring OL[k]). Note that as the above-described function, for example, a sigmoid function, a tanh function, a softmax function, a ReLU function, or a threshold function can be used.

As described above, the cell array CA included in the region L2 is divided into the subarray SA_1 to the subarray SA_p and a plurality of results calculated by the cell array CA and the circuit ITS included in the region L1 is input as a signal in the row direction of the subarray SA_1 to the subarray SA_p, whereby the cells IM can be efficiently arranged in the arithmetic circuit 10. In addition, when k=n is satisfied, the cells IM can be arranged more efficiently. Thus, when arithmetic operation is performed in the arithmetic circuit 10, the number of cells IM that are not used for arithmetic operation can be reduced, so that arithmetic efficiency per area of the arithmetic circuit 10 can be increased.

### Structure Example 2

Although the cells IM are illustrated as the arithmetic cells in the cell array CA in the arithmetic circuit 10 in FIG. 1, a cell other than the cell IM, such as a dummy arithmetic cell, a reference arithmetic cell, or the like may be necessary depending on the arithmetic method. Thus, in the arithmetic circuit 10 in FIG. 1, a dummy arithmetic cell or a reference arithmetic cell may be provided separately in accordance with the arithmetic method.

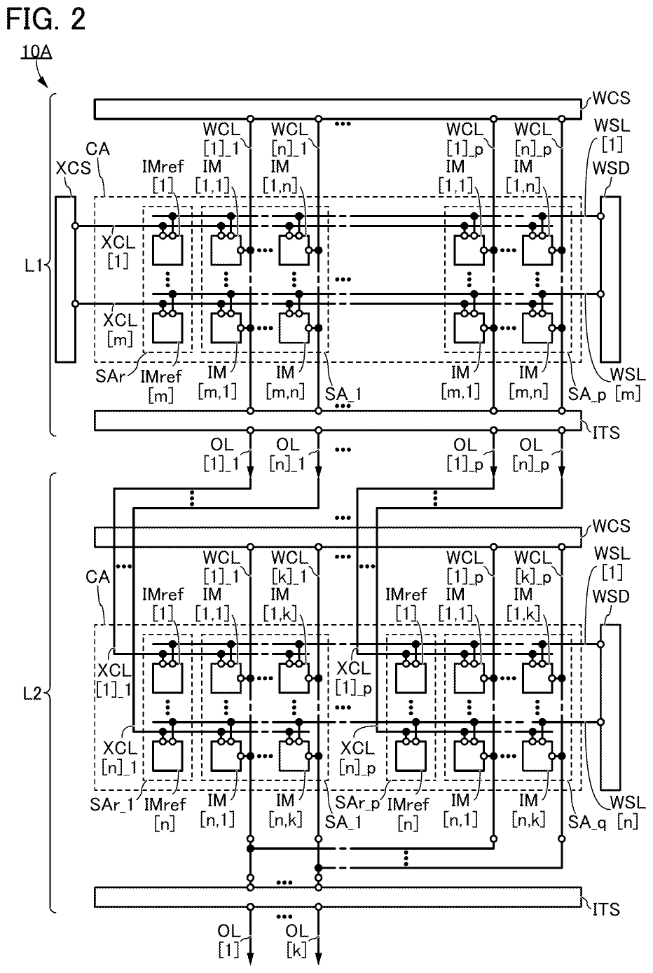

An arithmetic circuit 10A in FIG. 2 is a variation example of the arithmetic circuit 10 in FIG. 1 and a circuit structure of a case where a reference arithmetic circuit is necessary to perform product-sum operation.

In the region L1, the cell array CA includes a subarray SAr, in addition to the subarray SA_1 to the subarray SA_p, for example. The subarray SAr includes a cell IMref[1] to a cell IMref[m], for example.

The cell IMref[1] to the cell IMref[m] are, respectively, electrically connected to the wiring WSL[1] to the wiring WSL[m] in a one-to-one correspondence, for example. The cell IMref[1] to the cell IMref[m] are, respectively, electrically connected to the wiring XCL[1] to the wiring XCL[m] in a one-to-one correspondence, for example.

In the region L2, the cell array CA includes a subarray SAr_1 to a subarray SAr_p, in addition to the subarray SA_1 to the subarray SA_p, for example. The subarray SAr_1 to the subarray SAr_p each include the cell IMref[1] to a cell IMref[n], for example.

The cell IMref[1] to the cell IMref[n] included in the subarray SAr_1 are, respectively, electrically connected to the wiring WSL[1] to the wiring WSL[n] in a one-to-one correspondence, for example. The cell IMref[1] to the cell IMref[n] included in the subarray SAr_1 are, respectively, electrically connected to the wiring XCL[1]_1 to the wiring XCL[n]_1 in a one-to-one correspondence, for example. The cell IMref[1] to the cell IMref[n] included in the subarray SAr_p are, respectively, electrically connected to the wiring WSL[1] to the wiring WSL[n] in a one-to-one correspondence, for example. The cell IMref[1] to the cell IMref[n] included in the subarray SAr_p are, respectively, electrically connected to the wiring XCL[1]_p to the wiring XCL[m]_p in a one-to-one correspondence, for example.

Next, a specific structure example of the cell IM and the cell IMref is described.

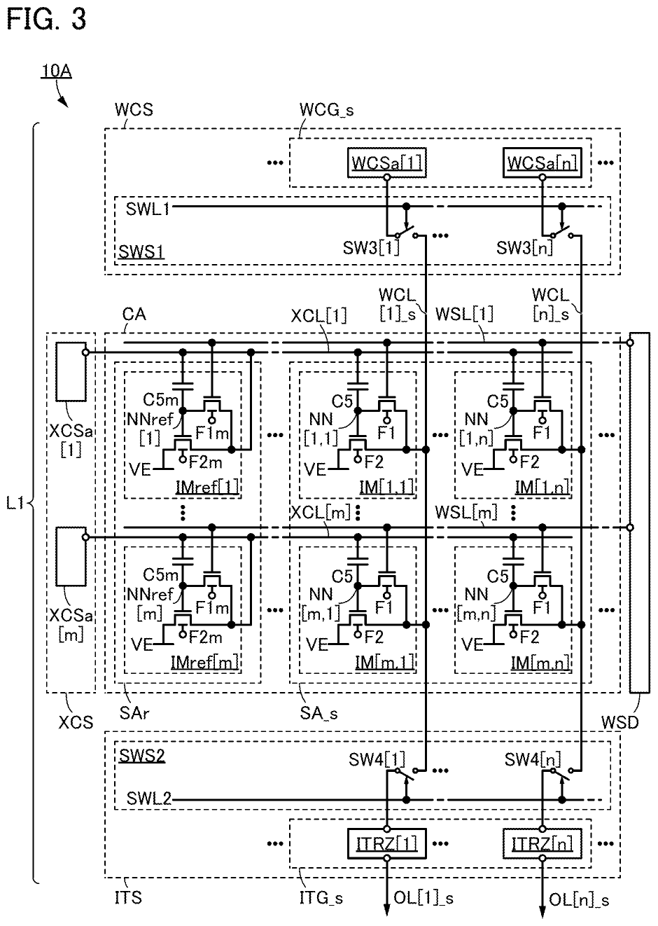

FIG. 3 is a circuit diagram illustrating a specific structure example of the cell IM and the cell IMref in the arithmetic circuit 10A in FIG. 2. Note that FIG. 3 selectively illustrates the subarray SAr and a subarray SA_s (s is an integer greater than or equal to 1 and less than or equal top). FIG. 3 selectively illustrates the circuit WCS, the circuit XCS, the circuit WSD, and the circuit ITS to show electrical connection to the cell array CA.

The cell IM[1,1] to the cell IM[m,n] each include a transistor F1, a transistor F2, and a capacitor C5, and the cell IMref[1] to the cell IMref[m] each include a transistor F1m, a transistor F2m, and a capacitor C5m, for example.

It is particularly preferable that the sizes of the transistors F1 (e.g., the channel lengths, the channel widths, and the transistor structures) included in the cell IM[1,1] to the cell IM[m,n] be equal to each other, and the sizes of the transistors F2 included in the cell IM[1,1] to the cell IM[m,n] be equal to each other. It is preferable that the sizes of the transistors F1m included in the cell IMref[1] to the cell IMref[m] be equal to each other, and the sizes of the transistors F2m included in the cell IMref[1] to the cell IMref[m] be equal to each other. It is also preferable that the sizes of the transistor F1 and the transistor F1m be equal to each other, and the sizes of the transistor F2 and the transistor F2m be equal to each other.

By making the transistors have the same size, the transistors can have substantially the same electrical characteristics. Thus, by making the transistors F1 included in the cell IM[1,1] to the cell IM[m,n] have the same size and the transistors F2 included in the cell IM[1,1] to the cell IM[m,n] have the same size, the cell IM[1,1] to the cell IM[m,n] can perform almost the same operation when being in the same conditions as each other. The same conditions here mean, for example, potentials of a source, a drain, a gate, and the like of the transistor F1, potentials of a source, a drain, a gate, and the like of the transistor F2, and potentials input to the cell IM[1,1] to the cell IM[m,n]. By making the transistors F1m included in the cell IMref[1] to the cell IMref[m] have the same size and the transistors F2m included in the cell IMref[1] to the cell IMref[m] have the same size, the cell IMref[1] to the cell IMref[m] can perform substantially the same operation and can have substantially the same result of the operation, for example. In the case of the same conditions, the cell IMref[1] to the cell IMref[m] can perform substantially the same operation. The same conditions here mean, for example, potentials of a source, a drain, a gate, and the like of the transistor F1m, potentials of a source, a drain, a gate, and the like of the transistor F2m, and potentials input to the cell IMref[1] to the cell IMref[m].

Unless otherwise specified, the transistor F1 and the transistor F1m in an on state may operate in a linear region in the end. In other words, the gate voltage, the source voltage, and the drain voltage of each of the above transistors may be appropriately biased to voltages in the range where the transistor operates in the linear region. However, one embodiment of the present invention is not limited thereto. For example, one or both of the transistor F1 and the transistor F1m in an on state may operate in a saturation region or may operate both in a linear region and in a saturation region.

Unless otherwise specified, the transistor F2 and the transistor F2m may operate in a subthreshold region (i.e., the gate-source voltage may be lower than the threshold voltage in the transistor F2 or the transistor F2m, further preferably, the drain current increases exponentially with respect to the gate-source voltage). In other words, the gate voltage, the source voltage, and the drain voltage of each of the above transistors may be appropriately biased to voltages in the range where the transistor operates in the subthreshold region. Thus, the transistor F2 and the transistor F2m may operate such that the off-state current (referred to as leakage current in some cases) flows between the source and the drain.

One or both of the transistor F1 and the transistor F1m are preferably an OS transistor, for example. In addition, it is further preferable that a channel formation region in one or both of the transistor F1 and the transistor F1m be an oxide containing at least one of indium, gallium, and zinc. Instead of the oxide, an oxide containing at least one of indium, an element M (as the element M, for example, one kind or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like can be given), and zinc may be used. It is further preferable that one or both of the transistor F1 and the transistor F1m have a structure of the transistor described in Embodiment 6, in particular.

With the use of an OS transistor as one or both of the transistor F1 and the transistor F1m, the leakage current of one or both of the transistor F1 and the transistor F1m can be inhibited, so that the power consumption of the arithmetic circuit can be reduced. Specifically, in the case where one or both of the transistor F1 and the transistor F1m are in the non-conducting state, the amount of leakage current from a retention node to a write word line can be extremely small and thus the frequency of refresh operation for the potential of the retention node can be reduced. By reducing the frequency of refresh operation, the power consumption of the arithmetic circuit can be reduced. An extremely low leakage current from the retention node to the wiring WCL or the wiring XCL allows cells to retain the potential of the retention node for a long time, increasing the arithmetic operation accuracy of the arithmetic circuit.

The use of an OS transistor also as one or both of the transistor F2 and the transistor F2m enables operation with a wide range of current in the subthreshold region, leading to a reduction in the current consumption. With the use of an OS transistor also as the transistor F2 and the transistor F2m, the transistor F2 and the transistor F2m can be manufactured concurrently with the transistor F1 and the transistor F1m; thus, the manufacturing process of the arithmetic circuit can sometimes be shortened. One or both of the transistor F2 and the transistor F2m can be, other than an OS transistor, a transistor containing silicon in its channel formation region (hereinafter referred to as a Si transistor). As the silicon, amorphous silicon (referred to as hydrogenated amorphous silicon in some cases), microcrystalline silicon, polycrystalline silicon, single crystal silicon, or the like can be used, for example.

When a semiconductor device and the like are highly integrated into a chip or the like, heat may be generated in the chip by driving of the circuit. This heat increases the temperature of a transistor to change the characteristics of the transistor; thus, the field-effect mobility thereof might change or the operation frequency thereof might decrease, for example. Since an OS transistor has a higher heat resistance than a Si transistor, a change in field-effect mobility and a decrease in operation frequency due to a temperature change do not easily occur. Even when having a high temperature, an OS transistor is likely to keep a property of the drain current increasing exponentially with respect to the gate-source voltage. With the use of an OS transistor, arithmetic operation can thus be easily performed even in a high temperature environment. To form a semiconductor device highly resistant to heat due to driving, an OS transistor is preferably used as its transistor.

In each of the cell IM[1,1] to the cell IM[m,n], a first terminal of the transistor F1 is electrically connected to a gate of the transistor F2. A first terminal of the transistor F2 is electrically connected to a wiring VE. A first terminal of the capacitor C5 is electrically connected to the gate of the transistor F2.

In each of the cell IMref[1] to the cell IMref[m], a first terminal of the transistor F1m is electrically connected to a gate of the transistor F2m. A first terminal of the transistor F2m is electrically connected to the wiring VE. A first terminal of the capacitor C5m is electrically connected to the gate of the transistor F2m.

In each of the transistor F1, the transistor F2, the transistor F1m, and the transistor F2m in FIG. 3, a back gate is illustrated but the connection structure of the back gate is not illustrated; however, a point to which the back gate is electrically connected can be determined at the design stage. For example, in a transistor including a back gate, a gate and the back gate may be electrically connected to each other to increase the on-state current of the transistor. For example, the gate and the back gate of the transistor F1 may be electrically connected to each other, and the gate and the back gate of the transistor F1m may be electrically connected to each other. Furthermore, for example, in a transistor including a back gate, a wiring electrically connecting the back gate of the transistor to an external circuit or the like may be provided and a potential may be supplied to the back gate of the transistor with the external circuit or the like to change the threshold voltage of the transistor or to reduce the off-state current of the transistor.

The transistor F1 and the transistor F2 illustrated in FIG. 3 have back gates; however, the semiconductor device of one embodiment of the present invention is not limited thereto. For example, the transistor F1 and the transistor F2 illustrated in FIG. 3 may each be a transistor having a structure not including a back gate, i.e., a single-gate structure. It is also possible that some transistors have a structure including a back gate and the other transistors have a structure not including a back gate.

The transistor F1 and the transistor F2 illustrated in FIG. 3 are n-channel transistors; however, the semiconductor device of one embodiment of the present invention is not limited thereto. For example, some or all of the transistors F1 and the transistors F2 may be replaced with p-channel transistors.

The above-described examples of changes in the structure and polarity of the transistor are not limited to the transistor F1 and the transistor F2. For example, the same applies to the transistor F1m and the transistor F2m, transistors described in other parts of this specification, and transistors illustrated in other drawings.

The wiring VE functions as a wiring for flowing current between the first terminal and a second terminal of the transistor F2 of each of the cell IM[1,1], the cell IM[m,1], the cell IM[1,n], and the cell IM[m,n] and a wiring for flowing current between the first terminal and the second terminal of the transistor F2 of each of the cell IMref[1] and the cell IMref[m]. The wiring VE functions as a wiring for supplying constant voltage, for example. The constant voltage can be, for example, a low-level potential, a ground potential, or the like.

In the cell IM[1,1], a second terminal of the transistor F1 is electrically connected to a wiring WCL[1]_s, and the gate of the transistor F1 is electrically connected to the wiring WSL[1]. The second terminal of the transistor F2 is electrically connected to the wiring WCL[1]_s, and a second terminal of the capacitor C5 is electrically connected to the wiring XCL[1]. In the cell IM[1,1] in FIG. 3, a connection portion of the first terminal of the transistor F1, the gate of the transistor F2, and the first terminal of the capacitor C5 is a node NN[1,1].

In the cell IM[m,1], the second terminal of the transistor F1 is electrically connected to the wiring WCL[1]_s, and the gate of the transistor F1 is electrically connected to the wiring WSL[m]. The second terminal of the transistor F2 is electrically connected to the wiring WCL[1]_s, and the second terminal of the capacitor C5 is electrically connected to the wiring XCL[m]. In the cell IM[m,1] in FIG. 3, a connection portion of the first terminal of the transistor F1, the gate of the transistor F2, and the first terminal of the capacitor C5 is a node NN[m,1].

In the cell IM[1,n], the second terminal of the transistor F1 is electrically connected to a wiring WCL[n]_s, and the gate of the transistor F1 is electrically connected to the wiring WSL[1]. The second terminal of the transistor F2 is electrically connected to the wiring WCL[n]_s, and the second terminal of the capacitor C5 is electrically connected to the wiring XCL[1]. In the cell IM[1,n] in FIG. 3, a connection portion of the first terminal of the transistor F1, the gate of the transistor F2, and the first terminal of the capacitor C5 is a node NN[1,n].

In the cell IM[m,n], the second terminal of the transistor F1 is electrically connected to the wiring WCL[n]_s, and the gate of the transistor F1 is electrically connected to the wiring WSL[m]. The second terminal of the transistor F2 is electrically connected to the wiring WCL[n]_s, and the second terminal of the capacitor C5 is electrically connected to the wiring XCL[m]. In the cell IM[m,n] in FIG. 3, a connection portion of the first terminal of the transistor F1, the gate of the transistor F2, and the first terminal of the capacitor C5 is a node NN[m,n].

In the cell IMref[1], a second terminal of the transistor F1m is electrically connected to the wiring XCL[1], and the gate of the transistor F1m is electrically connected to the wiring WSL[1]. A second terminal of the transistor F2m is electrically connected to the wiring XCL[1], and the second terminal of the capacitor C5 is electrically connected to a wiring XCL[1]_s. In the cell IMref[1] in FIG. 3, a connection portion of the first terminal of the transistor F1m, the gate of the transistor F2m, and the first terminal of the capacitor C5 is a node NNref[1].

In the cell IMref[m], the second terminal of the transistor F1m is electrically connected to a wiring XCL[m]_s, and the gate of the transistor F1m is electrically connected to the wiring WSL[m]. The second terminal of the transistor F2m is electrically connected to the wiring XCL[m], and the second terminal of the capacitor C5 is electrically connected to the wiring XCL[m]_s. In the cell IMref[m] in FIG. 3, a connection portion of the first terminal of the transistor F1m, the gate of the transistor F2m, and the first terminal of the capacitor C5 is a node NNref[m].

The node NN[1,1] to the node NN[m,n], and the node NNref[1] to the node NNref[m] function as retention nodes of the cells.

In the case where the transistor F1 is turned on in each of the cell IM[1,1] to the cell IM[m,n], for example, the transistor F2 is a diode-connected transistor. When constant voltage supplied from the wiring VE is a ground potential (GND), the transistor F1 is turned on, and current with a current amount I flows from the wiring WCL to the second terminal of the transistor F2, a potential of the gate of the transistor F2 (the node NN) is determined in accordance with the current amount I. Since the transistor F1 is in an on state, a potential of the second terminal of the transistor F2 is ideally equal to that of the gate of the transistor F2 (the node NN). Here, by turning off the transistor F1, the potential of the gate of the transistor F2 (the node NN) is retained. Accordingly, the transistor F2 can make the current with the current amount I corresponding to a ground potential of the first terminal of the transistor F2 and the potential of the gate of the transistor F2 (the node NN) flow between the source and the drain of the transistor F2. In this specification and the like, such operation is called “setting (programing) the amount of current flowing between the source and the drain of the transistor F2 in the cell IM to I”.

Next, a specific structure example of the circuit WCS, the circuit XCS, the circuit WSD, the circuit ITS, and the cell IMref is described.

### <<Circuit WCS>>

The circuit WCS includes a circuit SWS1 and a circuit WCG_s, for example. The circuit WCG_s includes a circuit WCSa[1] to a circuit WCSa[n], for example.

The circuit SWS1 includes a switch SW3[1] to a switch SW3[n], for example. A first terminal of the switch SW3[1] is electrically connected to the wiring WCL[1]_s, a second terminal of the switch SW3[1] is electrically connected to the circuit WCSa[1], and a control terminal of the switch SW3[1] is electrically connected to a wiring SWL1. A first terminal of the switch SW3[n] is electrically connected to the wiring WCL[n]_s, a second terminal of the switch SW3[n] is electrically connected the circuit WCSa[n], and a control terminal of the switch SW3[n] is electrically connected to the wiring SWL1.

The wiring SWL1 functions as a wiring for switching an on state and an off state of the switch SW3[1] to the switch SW3[n], for example. Accordingly, the wiring SWL1 is supplied with a high-level potential or a low-level potential.

As the switch SW3[1] to the switch SW3[n], an electrical switch such as an analog switch or a mechanical switch may be used, for example. As one of the electrical switches, a transistor that can be used as the transistor F1 or the transistor F2 may be used. In particular, an OS transistor is preferably used as the transistor, for example.

As described above, the circuit SWS1 functions as a circuit that establishes or breaks electrical continuity between the circuit WCG_s and each of the wiring WCL[1]_s to the wiring WCL[n]_s. In other words, the circuit SWS1 switches electrical continuity and discontinuity between the circuit WCG_s and each of the wiring WCL[1]_s to the wiring WCL[n]_s by using the switch SW3[1] to the switch SW3[n] as switching elements.

The circuit WCG_s has a function of supplying the wiring WCL[1]_s to the wiring WCL[n]_s with a signal with an amount corresponding to the first data. In other words, the circuit WCG_s supplies, when the switch SW3[1] to the switch SW3[n] are in an on state, the first data that is to be stored in the cells IM of the cell array CA. Note that in the case of the arithmetic circuit 10A in FIG. 3, the signal is preferably a current.

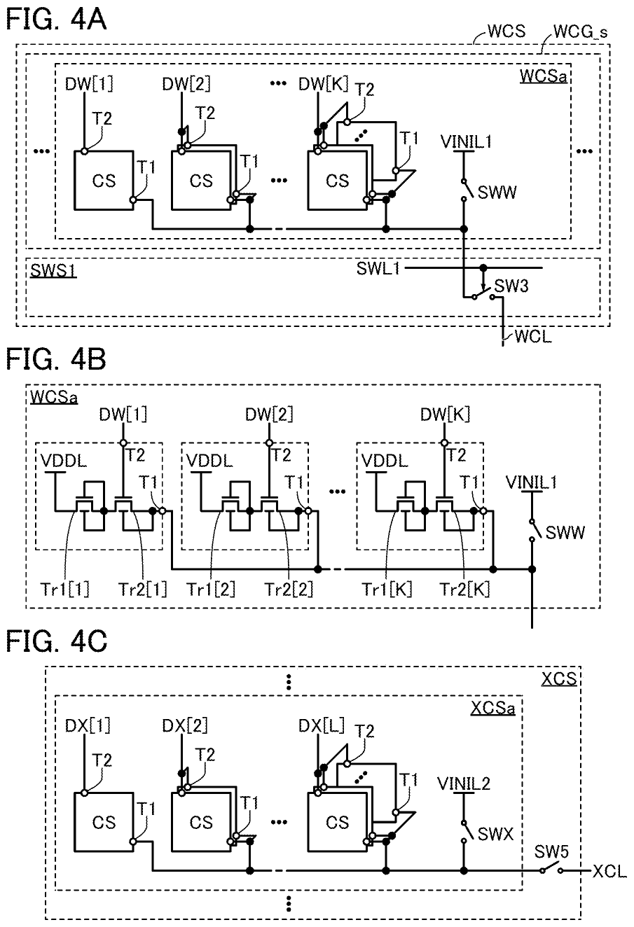

The circuit WCG_s can have a structure illustrated in FIG. 4A, for example. In FIG. 4A, to illustrate electrical connection between the circuit WCG_s and its peripheral circuits, the circuit SWS1, the switch SW3, the wiring SWL1, and the wiring WCL are also illustrated.

The circuit WCG_s includes the circuits WCSa the number which is the same as that of the columns in the subarray SA, for example. In other words, in the case of the arithmetic circuit 10A in FIG. 2 and FIG. 3, the circuit WCG_s includes n circuits WCSa.

The circuit SWS1 includes the switches SW3 the number of which is the same as that of the wirings WCL. In other words, the circuit SWS1 also includes n switches SW3.

Thus, the switch SW3 illustrated in FIG. 4A can be any one of the switch SW3[1] to the switch SW3[n] included in the arithmetic circuit 10A in FIG. 3. Similarly, the wiring WCL can be any one of the wiring WCL[1] to the wiring WCL[n] included in the arithmetic circuit 10A in FIG. 3.

Thus, the wiring WCL[1] to the wiring WCL[n] are electrically connected to the respective circuits WCSa through the respective switches SW3.

The circuit WCSa illustrated in FIG. 4A includes a switch SWW, for example. A first terminal of the switch SWW is electrically connected to the second terminal of the switch SW3, and a second terminal of the switch SWW is electrically connected to a wiring VINIL1. The wiring VINIL1 functions as a wiring supplying an initialization potential to the wiring WCL, and the initialization potential can be set to a ground potential (GND), a low-level potential, or a high-level potential. Note that the switch SWW is in an on state only when the initialization potential is supplied to the wiring WCL; otherwise, the switch is in an off state.

As the switch SWW, an electrical switch such as an analog switch or a transistor can be used, for example. When a transistor is used as the switch SWW, for example, the transistor can be a transistor having a structure similar to that of the transistor F1 or the transistor F2. Other than the electrical switch, a mechanical switch may be used.

The circuit WCSa in FIG. 4A includes a plurality of current sources CS, for example. Specifically, the circuit WCSa has a function of outputting K-bit first data (2^{K} values) (K is an integer greater than or equal to 1) as the current amount; in this case, the circuit WCSa includes 2^{K}−1 current sources CS. The circuit WCSa includes one current source CS that outputs information corresponding to the first bit value as current, two current sources CS that output information corresponding to the second bit value as current, and the 2^{K-1} current sources CS that output information corresponding to the K-th bit value as current, for example.

Each of the current sources CS in FIG. 4A includes a terminal T1 and a terminal T2. The terminal T1 of each of the current sources CS is electrically connected to the second terminal of the switch SW3 included in the circuit SWS1. The terminal T2 of the one current source CS is electrically connected to a wiring DW[1], the terminals T2 of the two current sources CS are electrically connected to a wiring DW[2], and the terminals T2 of the 2^{K-1} current sources CS are electrically connected to a wiring DW[K].

The plurality of current sources CS included in the circuit WCSa have a function of outputting the same constant currents I_{Wut} from the terminals T1. In practice, at the manufacturing stage of the arithmetic circuit 10A, the transistors included in the current sources CS may have different electrical characteristics; this may yield an error. The error in the constant currents I_{Wut} output from the terminals T1 of the plurality of current sources CS is thus preferably within 10%, further preferably within 5%, still further preferably within 1%. In this embodiment, the description is made on the assumption that there is no error in the constant currents I_{Wut} output from the terminals T1 of the plurality of current sources CS included in the circuit WCSa.

The wiring DW[1] to the wiring DW[K] function as wirings for transmitting control signals to make the current sources CS, which are electrically connected to the wiring DW[1] to the wiring DW[K], output the constant currents I_{Wut}. Specifically, for example, when a high-level potential is supplied to the wiring DW[1], the current source CS electrically connected to the wiring DW[1] supplies I_{Wut} as constant current to the second terminal of the switch SW3, and when a low-level potential is supplied to the wiring DW[1], the current source CS electrically connected to the wiring DW[1] does not output I_{Wut}. For example, when a high-level potential is supplied to the wiring DW[2], the two current sources CS electrically connected to the wiring DW[2] supply the sum of constant currents 2I_{Wut} to the second terminal of the switch SW3, and when a low-level potential is supplied to the wiring DW[2], the current sources CS electrically connected to the wiring DW[2] do not output the sum of constant currents 2I_{Wut}. For example, when a high-level potential is supplied to the wiring DW[K], the 2^{K-1} current sources CS electrically connected to the wiring DW[K] supply the sum of constant currents 2^{K-1}I_{Wut} to the second terminal of the switch SW3, and when a low-level potential is supplied to the wiring DW[K], the current sources CS electrically connected to the wiring DW[K] do not output the sum of constant currents 2^{K-1}I_{Wut}.

The current flowing from the one current source CS electrically connected to the wiring DW[1] corresponds to the value of the first bit, the current flowing from the two current sources CS electrically connected to the wiring DW[2] corresponds to the value of the second bit, and the amount of current flowing from the K current sources CS electrically connected to the wiring DW[K] corresponds to the value of the K-th bit. The circuit WCSa with K of 2 is considered. For example, when the value of the first bit is “1” and the value of the second bit is “0”, a high-level potential is supplied to the wiring DW[1], and a low-level potential is supplied to the wiring DW[2]. In this case, the constant current I_{Wut} flows to the second terminal of the switch SW3 of the circuit SWS1 from the circuit WCSa. For example, when the value of the first bit is “0” and the value of the second bit is “1”, a low-level potential is supplied to the wiring DW[1], and a high-level potential is supplied to the wiring DW[2]. In this case, the constant current 2I_{Wut} flows to the second terminal of the switch SW3 of the circuit SWS1 from the circuit WCSa. For example, when the value of the first bit is “1” and the value of the second bit is “1”, a high-level potential is supplied to the wiring DW[1] and the wiring DW[2]. In this case, the constant current 3I_{Wut} flows to the second terminal of the switch SW3 of the circuit SWS1 from the circuit WCSa. For example, when the value of the first bit is “0” and the value of the second bit is “0”, a low-level potential is supplied to the wiring DW[1] and the wiring DW[2]. In this case, the constant current does not flow from the circuit WCSa to the second terminal of the switch SW3 of the circuit SWS1.

FIG. 4A illustrates the circuit WCSa with K of an integer greater than or equal to 3; when K is 1, the current sources CS electrically connected to the wiring DW[2] to the wiring DW[K] are not provided in the circuit WCSa in FIG. 4A. When K is 2, the current sources CS electrically connected to the wiring DW[3] to the wiring DW[K] are not provided in the circuit WCSa in FIG. 4A.

Next, a specific structure example of the current source CS is described.

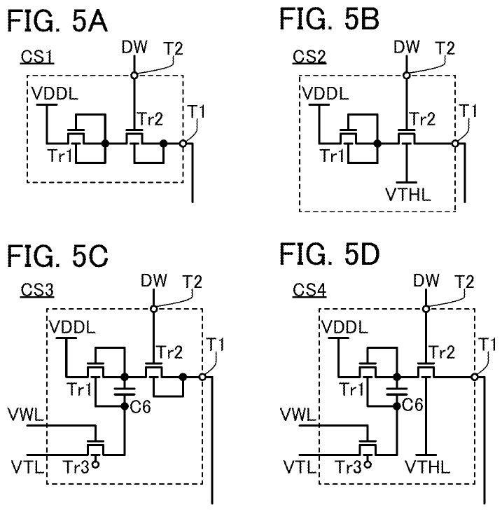

A current source CS1 illustrated in FIG. 5A is a circuit that can be used as the current source CS included in the circuit WCSa in FIG. 4A, and the current source CS1 includes a transistor Tr1 and a transistor Tr2.

A first terminal of the transistor Tr1 is electrically connected to a wiring VDDL, and a second terminal of the transistor Tr1 is electrically connected to a gate of the transistor Tr1, a back gate of the transistor Tr1, and a first terminal of the transistor Tr2. A second terminal of the transistor Tr2 is electrically connected to the terminal T1, and a gate of the transistor Tr2 is electrically connected to the terminal T2. The terminal T2 is electrically connected to the wiring DW.

The wiring DW is any one of the wiring DW[1] to the wiring DW[K] in FIG. 4A.

The wiring VDDL functions as a wiring for supplying constant voltage. The constant voltage can be a high-level potential, for example.

When constant voltage supplied from the wiring VDDL is set at a high-level potential, a high-level potential is input to the first terminal of the transistor Tr1. The potential of the second terminal of the transistor Tr is lower than the high-level potential. At this time, the first terminal of the transistor Tr functions as a drain, and the second terminal of the transistor Tr functions as a source. Since the gate of the transistor Tr is electrically connected to the second terminal of the transistor Tr1, the gate-source voltage of the transistor Tr is 0 V. When the threshold voltage of the transistor Tr is within an appropriate range, current in the current range of the subthreshold region (drain current) flows between the first terminal and the second terminal of the transistor Tr1. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, when the transistor Tr is an OS transistor. For example, the current is further preferably within a range where the current exponentially increases with respect to the gate-source voltage. That is, the transistor Tr functions as a current source for supplying current within a current range of the transistor Tr operating in the subthreshold region. The current corresponds to I_{Wut} described above or I_{Xut} described later.

The transistor Tr2 functions as a switching element. When the potential of the first terminal of the transistor Tr2 is higher than the potential of the second terminal of the transistor Tr2, the first terminal of the transistor Tr2 functions as a drain and the second terminal of the transistor Tr2 functions as a source. Since a back gate of the transistor Tr2 and the second terminal of the transistor Tr2 are electrically connected to each other, a back gate-source voltage becomes 0 V. Thus, when the threshold voltage of the transistor Tr2 is within an appropriate range and a high-level potential is input to the gate of the transistor Tr2, the transistor Tr2 is turned on; when a low-level potential is input to the gate of the transistor Tr2, the transistor Tr2 is turned off. Specifically, when the transistor Tr2 is in the on state, current within the current range of the subthreshold region flows from the second terminal of the transistor Tr to the terminal T1, and when the transistor Tr2 is in the off state, the current does not flow from the second terminal of the transistor Tr to the terminal T1.

The circuit that can be used as the current source CS included in the circuit WCSa in FIG. 4A is not limited to the current source CS1 in FIG. 5A. For example, the current source CS1 has a structure in which the back gate of the transistor Tr2 and the second terminal of the transistor Tr2 are electrically connected to each other; however, the back gate of the transistor Tr2 may be electrically connected to another wiring. Such a structure example is illustrated in FIG. 5B. In a current source CS2 illustrated in FIG. 5B, the back gate of the transistor Tr2 is electrically connected to a wiring VTHL. When the wiring VTHL of the current source CS2 is electrically connected to an external circuit or the like, the external circuit or the like supplies a predetermined potential to the wiring VTHL and the back gate of the transistor Tr2 can be supplied with the predetermined potential. This can change the threshold voltage of the transistor Tr2. In particular, the off-state current of the transistor Tr2 can be reduced by an increase in the threshold voltage of the transistor Tr2.

For example, the current source CS1 has a structure in which the back gate of the transistor Tr and the second terminal of the transistor Tr are electrically connected to each other; however, the voltage between the back gate and the second terminal of the transistor Tr2 may be retained with a capacitor. Such a structure example is illustrated in FIG. 5C. A current source CS3 illustrated in FIG. 5C includes a transistor Tr3 and a capacitor C6 in addition to the transistor Tr and the transistor Tr2. The current source CS3 is different from the current source CS1 in that the second terminal of the transistor Tr and the back gate of the transistor Tr are electrically connected to each other through the capacitor C6, and the back gate of the transistor Tr and a first terminal of the transistor Tr3 are electrically connected to each other. In the current source CS3, a second terminal of the transistor Tr3 is electrically connected to a wiring VTL, and a gate of the transistor Tr3 is electrically connected to a wiring VWL. In the current source CS3, the wiring VWL is supplied with a high-level potential to turn on the transistor Tr3, so that electrical continuity can be established between the wiring VTL and the back gate of the transistor Tr1. In this case, a predetermined potential can be input to the back gate of the transistor Tr from the wiring VTL. The wiring VWL is supplied with a low-level potential to turn off the transistor Tr3, so that voltage between the second terminal of the transistor Tr and the back gate of the transistor Tr can be retained with the capacitor C6. The threshold voltage of the transistor Tr can be changed when the voltage supplied to the back gate of the transistor Tr is determined by the wiring VTL, and the threshold voltage of the transistor Tr can be fixed with the transistor Tr3 and the capacitor C6.

For example, as the circuit that can be used as the current source CS included in the circuit WCSa in FIG. 4A, a current source CS4 illustrated in FIG. 5D may be used. The current source CS4 is different from the current source CS3 in FIG. 5C in that the back gate of the transistor Tr2 is electrically connected not to the second terminal of the transistor Tr2 but to the wiring VTHL. That is, the current source CS4 can change the threshold voltage of the transistor Tr2 with the potential supplied from the wiring VTHL, as in the current source CS2 in FIG. 5B.

When a high current flows between the first terminal and the second terminal of the transistor Tr in the current source CS4, the on-state current of the transistor Tr2 needs to be increased to supply the current from the terminal T1 to the outside of the current source CS4. In this case, in the current source CS4, the wiring VTHL is supplied with a high-level potential to decrease the threshold voltage of the transistor Tr2 and increase the on-state current of the transistor Tr2, whereby a high current flowing between the first terminal and the second terminal of the transistor Tr can be supplied from the terminal T1 to the outside of the current source CS4.

The use of the current source CS1 to the current source CS4 illustrated in FIG. 5A to FIG. 5D as the current sources CS included in the circuit WCSa in FIG. 4A enables the circuit WCSa to output current corresponding to the K-bit first data. The amount of the current can be the amount of current flowing between the first terminal and the second terminal of the transistor F1 in the range where the transistor F1 operates in the subthreshold region.

As the circuit WCSa in FIG. 4A, the circuit WCSa illustrated in FIG. 4B may be used. In the circuit WCSa in FIG. 4B, one current source CS in FIG. 5A is connected to each of the wiring DW[1] to the wiring DW[K]. When the channel width of a transistor Tr1[1] is w[1], the channel width of a transistor Tr1[2] is w[2], and the channel width of a transistor Tr1[K] is w[K], the ratio of the channel widths is w[1]:w[2]:w[K]=1:2:2^{K-1}. Since current flowing between a source and a drain of a transistor that operates in the subthreshold region is proportional to the channel width, the circuit WCSa illustrated in FIG. 4B can output current corresponding to the K-bit first data like the circuit WCSa in FIG. 4A.

As the transistor Tr (including the transistor Tr1[1] to the transistor Tr1[K]), the transistor Tr2 (including the transistor Tr2[1] to the transistor Tr2[K]), and the transistor Tr3, a transistor that can be used as the transistor F1 or the transistor F2 can be used, for example. In particular, as the transistor Tr (including the transistor Tr1[1] to the transistor Tr1[K]), the transistor Tr2 (including the transistor Tr2[1] to the transistor Tr2[K]), and the transistor Tr3, OS transistors are preferably used.

### <<Circuit XCS>>

The circuit XCS includes a circuit XCSa[1] to a circuit XCSa[m], for example.

In FIG. 3, the circuit XCSa[1] is electrically connected to the wiring XCL[1], for example, and the circuit XCSa[m] is electrically connected to the wiring XCL[m], for example.

The circuit XCSa has a function of supplying, to the wiring XCL[1]_s to a wiring XCL[n]_s, a signal with an amount corresponding to the second data. Note that in the case of the arithmetic circuit 10A in FIG. 3, the signal is preferably a current.

FIG. 4C is a block diagram illustrating an example of the circuit XCS that can be used as the arithmetic circuit 10A in FIG. 2 and FIG. 3. FIG. 4C also illustrates the wiring XCL to show electrical connection between the circuit XCS and its peripheral circuits.

The circuit XCS includes the circuits XCSa and switches SW5 the number of which is the same as that of the wirings XCL, for example. That is, the circuit XCS includes m circuits XCSa and m switches SW5.

Thus, the wiring XCL illustrated in FIG. 4C can be any one of the wiring XCL[1] to the wiring XCL[m] included in the arithmetic circuit 10A in FIG. 3. Thus, the first terminals of different switches SW5 are electrically connected to the wiring XCL[1] to the wiring XCL[m], and different circuits XCSa are electrically connected to the second terminals of the m switches SW5.

Depending on the circuit structure of the arithmetic circuit, the circuit XCS in FIG. 4C may have a structure not provided with the switch SW5.

The circuit XCSa illustrated in FIG. 4C includes a switch SWX, for example. A first terminal of the switch SWX is electrically connected to the wiring XCL, and a second terminal of the switch SWX is electrically connected to a wiring VINIL2. The wiring VINIL2 functions as a wiring for supplying an initialization potential to the wiring XCL, and the initialization potential can be set to a ground potential (GND), a low-level potential, or a high-level potential. The initialization potential supplied from the wiring VINIL2 can be the same as the potential supplied from the wiring VINIL1. The switch SWX is turned on only when the initialization potential is supplied to the wiring XCL; otherwise, the switch is turned off.

As the switch SWX, a switch that can be used as the switch SWW can be used, for example.

The circuit XCSa in FIG. 4C can have almost the same structure as that of the circuit WCSa in FIG. 4A. Specifically, the circuit XCSa has a function of outputting reference data as the current amount, and a function of outputting L-bit second data (2^{L} values) (L is an integer greater than or equal to 1) as the current amount; in this case, the circuit XCSa includes 2^{L}−1 current sources CS. The circuit XCSa includes one current source CS that outputs information corresponding to the first bit value as current, two current sources CS that output information corresponding to the second bit value as current, and 2^{L-1} current sources CS that output information corresponding to the L-th bit value as current.

The reference data output from the circuit XCSa as current can be information in which the first bit value is “1” and the second and subsequent bit values are “0”, for example.

In FIG. 4C, the terminal T2 of the one current source CS is electrically connected to the wiring DX[1], the terminals T2 of the two current sources CS are electrically connected to the wiring DX[2], and the terminals T2 of the 2^{L-1} current sources CS are electrically connected to the wiring DX[L].

The plurality of current sources CS included in the circuit XCSa has a function of outputting the same constant currents I_{Xut} from the terminals T1. The wiring DX[1] to the wiring DX[L] electrically connected to the current sources CS function as wirings for transmitting control signals to make the current sources CS output I_{Xut}. In other words, the circuit XCSa has a function of making current with the amount corresponding to the L-bit data transmitted from the wiring DX[1] to the wiring DX[L] flow to the wiring XCL.

Specifically, the circuit XCSa with L of 2 is considered here. For example, when the value of the first bit is “1” and the value of the second bit is “0”, a high-level potential is supplied to the wiring DX[1], and a low-level potential is supplied to the wiring DX[2]. In this case, the constant current I_{Xut} flows from the circuit XCSa to the circuit XCL. For example, when the value of the first bit is “0” and the value of the second bit is “1”, a low-level potential is supplied to the wiring DX[1], and a high-level potential is supplied to the wiring DX[2]. In this case, the constant current 2I_{Xut} flows from the circuit XCSa to the wiring XCL. For example, when the value of the first bit is “1” and the value of the second bit is “1”, a high-level potential is supplied to the wiring DX[1] and the wiring DX[2]. In this case, the constant current 3I_{Xut} flows from the circuit XCSa to the wiring XCL. For example, when the value of the first bit is “0” and the value of the second bit is “0”, a low-level potential is supplied to the wiring DX[1] and the wiring DX[2]. In this case, the constant current does not flow from the circuit XCSa to the wiring XCL. In this specification and the like, this case is sometimes rephrased as “current with the amount zero flows from the circuit XCSa to the wiring XCL”. The current amount zero, I_{Xut}, 2I_{Xut}, 3I_{Xut}, or the like output from the circuit XCSa can be the second data output from the circuit XCSa; particularly, the current amount I_{Xut} output from the circuit XCSa can be the reference data output from the circuit XCSa.

When the transistors in the current sources CS included in the circuit XCSa have different electrical characteristics and this yields errors, the errors in the constant currents I_{Xut} output from the terminals T1 of the plurality of current sources CS are preferably within 10%, further preferably within 5%, still further preferably within 1%. In this embodiment, the description is made on the assumption that there is no error in the constant currents I_{Xut} output from the terminals T1 of the plurality of current sources CS included in the circuit XCSa.

As the current source CS of the circuit XCSa, any of the current source CS1 to the current source CS4 in FIG. 5A to FIG. 5D can be used in a manner similar to that of the current source CS of the circuit WCSa. In that case, the wiring DW illustrated in FIG. 5A to FIG. 5D is replaced with the wiring DX. This allows the circuit XCSa to make current within the current range of the subthreshold region flow through the wiring XCL as the reference data or the L-bit second data.

The circuit XCSa in FIG. 4C can have a circuit structure similar to that of the circuit WCSa illustrated in FIG. 4B. In this case, the circuit WCSa illustrated in FIG. 4B is replaced with the circuit XCSa, the wiring DW[1] is replaced with the wiring DX[1], the wiring DW[2] is replaced with the wiring DX[2], the wiring DW[K] is replaced with the wiring DX[L], the switch SWW is replaced with the switch SWX, and the wiring VINIL1 is replaced with the wiring VINIL2.

### <<Circuit WSD>>

As described above, the circuit WSD has a function of selecting a row in the cell array CA to which the first data is written, by supplying a predetermined signal to the wiring WSL[1] to the wiring WSL[m] at the time of writing the first data to the cell IM[1,1] to the cell IM[m,n]. For example, when the circuit WSD supplies the wiring WSL[1] with a high-level potential and supplies the wiring WSL[2] (not illustrated) to the wiring WSL[m] with a low-level potential, the transistor F1 whose gate is electrically connected to the wiring WSL[1] can be turned on and the transistor F1 whose gate is electrically connected to the wiring WSL[2] to the wiring WSL[m] can be turned off, thus, the cell IM that is electrically connected to the wiring WSL[1] can be selected as the cell IM to which data is written.

### <<Circuit ITS>>

In FIG. 3, the circuit ITS includes a circuit SWS2 and a circuit ITG_s, for example. The circuit ITG_s includes a converter circuit ITRZ[1] to a converter circuit ITRZ[n], for example.

The circuit SWS2 includes a switch SW4[1] to a switch SW4[n], for example. A first terminal of the switch SW4[1] is electrically connected to the wiring WCL[1]_s, a second terminal of the switch SW4[1] is electrically connected to an input terminal of the converter circuit ITRZ[1], and a control terminal of the switch SW4[1] is electrically connected to a wiring SWL2. A first terminal of the switch SW4[n] is electrically connected to the wiring WCL[n]_s, a second terminal of the switch SW4[n] is electrically connected to an input terminal of the converter circuit ITRZ[n], and a control terminal of the switch SW4[n] is electrically connected to the wiring SWL2.

An output terminal of the converter circuit ITRZ[1] is electrically connected to the wiring OL[1]_s, and an output terminal of the converter circuit ITRZ[n] is electrically connected to the wiring OL[n]_s, for example.

The wiring SWL2 functions as a wiring for switching an on state and an off state of the switch SW4[1] to the switch SW4[n], for example. Accordingly, the wiring SWL2 is supplied with a high-level potential or a low-level potential.

As the switch SW4[1] to the switch SW4[n], it is possible to use, for example, switches usable as the switch SW3[1] to the switch SW3[n] or the like.

As described above, the circuit SWS2 has a function of establishing or breaking electrical continuity between the circuit ITG_s and each of the wiring WCL[1]_s to the wiring WCL[n]_s. In other words, the circuit SWS1 switches electrical continuity and discontinuity between the circuit ITS and each of the wiring WCL[1]_s to the wiring WCL[n]_s by using the switch SW4[1] to the switch SW4[n] as switching elements.

The converter circuit ITRZ[1] to the converter circuit ITRZ[n] each have a function of converting current input to the input terminal into voltage corresponding to the amount of current and outputting the voltage from the output terminal. The voltage can be, for example, analog voltage, digital voltage, and the like. The converter circuit ITRZ[1] to the converter circuit ITRZ[n] may each include an arithmetic circuit of a function system. In that case, for example, the arithmetic circuit may perform arithmetic operation of a function with the use of the converted voltage and may output the arithmetic operation results to the wiring OL[1]_s to the wiring OL[n]_s.

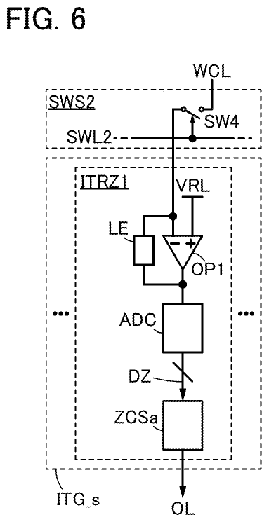

The converter circuit ITRZ1 illustrated in FIG. 6 is an example of a circuit that can be used as the converter circuit ITRZ[1] to the converter circuit ITRZ[n] in FIG. 3. FIG. 6 also illustrates the circuit SWS2, the wiring WCL, the wiring SWL2, the switch SW4, and the wiring OL to show electrical connection between the converter circuit ITRZ1 and its peripheral circuits. The wiring WCL is any one of the wiring WCL[1] to the wiring WCL[n] included in the arithmetic circuit 10A in FIG. 3, the switch SW4 is any one of the switch SW4[1] to the switch SW4[n] included in the arithmetic circuit 10A in FIG. 3, and the wiring OL is any one of the wiring OL[1]_s to the wiring OL[n]_s included in the arithmetic circuit 10A in FIG. 3.

The converter circuit ITRZ1 in FIG. 6 is electrically connected to the wiring WCL through the switch SW4. The converter circuit ITRZ1 is electrically connected to the wiring OL. The converter circuit ITRZ1 has a function of converting the amount of current flowing from the converter circuit ITRZ1 to the wiring WCL, or the amount of current flowing from the wiring WCL to the converter circuit ITRZ1 into analog voltage, converting the analog voltage into digital voltage and analog current in this order, and outputting the analog current to the wiring OL.

The converter circuit ITRZ1 in FIG. 6 includes a load LE, an operational amplifier OP1, an analog-digital converter circuit ADC, and a circuit ZCSa, for example.

An inverting input terminal of the operational amplifier OP1 is electrically connected to a first terminal of the load LE and a second terminal of the switch SW4. A non-inverting input terminal of the operational amplifier OP1 is electrically connected to a wiring VRL. An output terminal of the operational amplifier OP1 is electrically connected to a second terminal of the load LE and an input terminal of the analog-digital converter circuit ADC. An output terminal of the analog-digital converter circuit ADC is electrically connected to the circuit ZCSa through a wiring DZ. The circuit ZCSa is electrically connected to the wiring OL.

The wiring VRL functions as a wiring for supplying constant voltage. The constant voltage can be a ground potential (GND), a low-level potential, or the like, for example.

As the load LE, for example, a resistor, a diode, or a transistor can be used.

In the converter circuit ITRZ1, the amount of current flowing from the wiring WCL to the inverting input terminal of the operational amplifier OP1 and the first terminal of the load LE through the switch SW4 or the amount of current flowing from the inverting input terminal of the operational amplifier OP1 and the first terminal of the load LE to the wiring WCL through the switch SW4 can be converted into analog voltage owing to the structure of the operational amplifier OP1 and the load LE. The analog voltage is input to the input terminal of the analog-digital converter circuit ADC.

In particular, by setting the constant voltage supplied from the wiring VRL to a ground potential (GND), the inverting input terminal of the operational amplifier OP1 is virtually grounded, and the analog voltage output to the wiring OL can be voltage with reference to the ground potential (GND).

When analog voltage is input to the input terminal of the analog-digital converter circuit ADC, the analog-digital converter circuit ADC has a function of outputting digital voltage corresponding to the analog voltage to the wiring DZ, for example.

Note that here, the wiring DZ is one or more wirings. The number of wirings DZ, for example, can be determined by the resolution of the analog-digital converter circuit ADC. For example, when the resolution of the analog-digital converter circuit ADC is one bit, the number of wirings DZ can be one, and as another example, when the resolution of the analog-digital converter circuit ADC is eight bits, the number of wirings DZ can be eight.

The circuit ZCSa has a function of generating analog current on the basis of digital voltage that is input to the wiring DZ and outputting the analog current to the wiring OL, for example. Specifically, the circuit ZCSa can have a similar structure to the circuit WCSa in FIG. 4A, the circuit WCSa in FIG. 4B, or the circuit XCSa in FIG. 4C, for example. In the case where the circuit XCSa in FIG. 4C is used as the circuit ZCSa, the wiring DX[1] to a wiring DX[K] illustrated in FIG. 4C are replaced with the wiring DZ.

Furthermore, in the case where the circuit XCSa in FIG. 4C is used as the circuit ZCSa, an additional logic circuit (not illustrated) may be provided for the circuit ZCSa. In particular, it is preferable that the wirings DZ be electrically connected to an input terminal of the logic circuit and a control terminal of the switch SWX be electrically connected to an output terminal of the logic circuit. In addition, the logic circuit preferably outputs a signal for turning on the switch SWX to the output terminal of the logic circuit when a digital value input to the wiring DZ is “0” and preferably outputs a signal for turning off the switch SWX to the output terminal of the logic circuit when a digital value input to the wiring DZ is other than “0”. Thus, when a digital value input to the wiring DZ is “0”, the circuit ZCSa can output a potential corresponding to “0” (a potential supplied from the wiring VINIL2) to the wiring OL.

The analog-digital converter circuit ADC can be regarded as one of the above-described arithmetic circuits of a function system. Thus, in the case where different arithmetic circuits of a function system are used in the converter circuit ITRZ1, the analog-digital converter circuit ADC may be replaced with a circuit that performs a desired function operation. Note that the circuit performing the function operation preferably has a structure in which the input is analog voltage and the output is digital voltage.

Although FIG. 3 illustrates a circuit structure in the region L1 of the arithmetic circuit 10A, each circuit structure of the arithmetic circuit 10A described in FIG. 3 can be referred to for the circuit structure in the region L2 of the arithmetic circuit 10A in FIG. 2. That is, the circuit WCS in the region L2 can have a similar structure to the circuit WCS in the region L1, the circuit WSD in the region L2 can have a similar structure to the circuit WSD in the region L1, and the circuit ITS in the region L2 can have a similar structure to the circuit ITS in the region L1, for example. Furthermore, the subarray SAr_1 to the subarray SAr_p in the region L2 can have a similar structure to the subarray SAr in the region L1.

Current output from the circuit ITS in the region L1 is input to each of the wiring XCL[1]_1 to the wiring XCL[n]_1 and the wiring XCL[1]_p to the wiring XCL[n]_p that extend in the cell array CA in the region L2. With use of an operation result that is transmitted from the circuit ITS in the region L1 as the second data, product-sum operation of the first data transmitted from the circuit WCS in the region L2 and the second data can be performed in the region L2. Additionally, the circuit ITS in the region L2, using the result of the product-sum operation as an input value to perform function operation, can output to the wiring OL[1] to the wiring OL[k].

### Operation Example 1 of Arithmetic Circuit

Next, an operation example of the arithmetic circuit 10A illustrated in FIG. 3 is described.

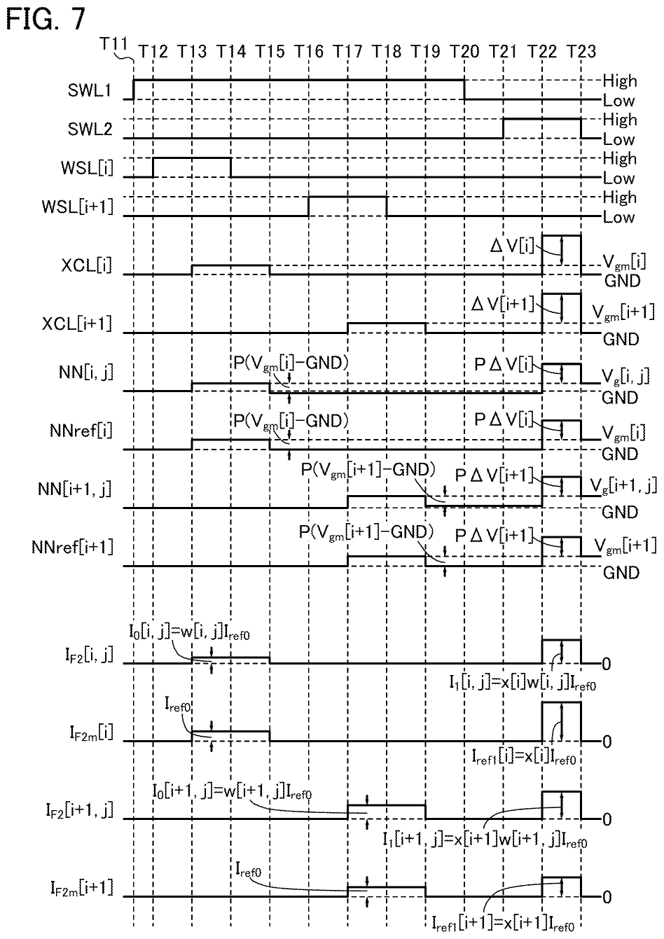

FIG. 7 is a timing chart showing an operation example of the arithmetic circuit 10A in FIG. 3. The timing chart in FIG. 7 shows changes in the potentials of the wiring SWL1, the wiring SWL2, the wiring WSL[i] (i is an integer greater than or equal to 1 and less than or equal to m−1), the wiring WSL[i+1], the wiring XCL[i], the wiring XCL[i+1], the node NN[i,j] (j is an integer greater than or equal to 1 and less than or equal to n−1), the node NN[i+1,j], the node NNref[i], and the node NNref[i+1] in the period from Time T11 to Time T23 and the vicinity thereof. The timing chart in FIG. 7 also shows changes in the amount of current I_{F2}[i,j] flowing between the first terminal and the second terminal of the transistor F2 included in the cell IM[i,j]; the amount of current I_{F2m}[i] flowing between the first terminal and the second terminal of the transistor F2m included in the cell IMref[i]; the amount of current I_{F2}[i+1,j] flowing between the first terminal and the second terminal of the transistor F2 included in the cell IM[i+1,j]; and the amount of current I_{F2m}[i+1] flowing between the first terminal and the second terminal of the transistor F2m included in the cell IMref[i+1].

The circuit WCS in FIG. 4A is used as the circuit WCS of the arithmetic circuit 10A, and the circuit XCS in FIG. 4C is used as the circuit XCS of the arithmetic circuit 10A. The circuit XCS may have a structure such that the switch SW5 is not provided; that is, the wiring XCL and the circuit XCSa may be directly electrically connected. Alternatively, in this operation example, the switch SW5 of the circuit XCS may always be on during operation.

Note that in this operation example, the potential of the wiring VE is a ground potential GND. Before Time T11, each potential of the node NN[i,j], the node NN[i+1,j], the node NNref[i], and the node NNref[i+1] is the ground potential GND. Specifically, for example, the initialization potential of the wiring VINIL1 in FIG. 4A is set to the ground potential GND, and the switch SWW, the switch SW3, and the transistor F1 included in each of the cell IM[i,j] and the cell IM[i+1,j] are turned on, whereby the potentials of the node NN[i,j] and the node NN[i+1,j] can be set to the ground potential GND. For example, the initialization potential of the wiring VINIL2 in FIG. 4C is set to the ground potential GND, and the switch SWX and the transistor F1m included in each of the cell IMref[i,j] and the cell IMref[i+1,j] are turned on, whereby the potentials of the node NNref[i,j] and the node NNref[i+1,j] can be set to the ground potential GND.

### <<From Time T11 to Time T12>>

In the period from Time T11 to Time T12, a high-level potential (shown as High in FIG. 7) is applied to the wiring SWL1, and a low-level potential (shown as Low in FIG. 7) is applied to the wiring SWL2. Accordingly, a high-level potential is applied to each of the control terminals of the switch SW3[1] to the switch SW3[n], so that the switch SW3[1] to the switch SW3[n] are turned on, and a low-level potential is applied to each of the gates of the switch SW4[1] to the switch SW4[n], so that the switch SW4[1] to the switch SW4[n] are turned off.

In the period from Time T11 to Time T12, a low-level potential is applied to the wiring WSL[i] and the wiring WSL[i+1]. Accordingly, in the i-th row in the cell array CA, a low-level potential is applied to the gates of the transistors F1 included in the cell IM[i,1] to the cell IM[i,n] and the gate of the transistor F1m included in the cell IMref[i] so that the transistors F1 and the transistor F1m are turned off. In addition, in the i+1-th row in the cell array CA, a low-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned off.

In the period from Time T11 to Time T12, the ground potential GND is applied to the wiring XCL[i] and the wiring XCL[i+1]. Specifically, for example, when the wiring XCL illustrated in FIG. 4C is the wiring XCL[i] and the wiring XCL[i+1], the initialization potential of the wiring VINIL2 is set to the ground potential GND, and the switch SWX is turned on, the potentials of the wiring XCL[i] and the wiring XCL[i+1] can be set to the ground potential GND.

In the period from Time T11 to Time T12, the first data is not input to the wiring DW[1] to the wiring DW[K] in the circuits WCSa in FIG. 4A, which are electrically connected to the wiring WCL[j]_s to the wiring WCL[n]_s through the respective switches SW3. In that case, the low-level potential is input to the wiring DW[1] to the wiring DW[K] in each of the circuits WCSa in FIG. 4A. In the period from Time T11 to Time T12, the second data is not input to the wiring DX[1] to the wiring DX[L] in the circuits XCSa in FIG. 4C, which are electrically connected to the wiring XCL[1] to the wiring XCL[m]. In that case, the low-level potential is input to the wiring DX[1] to the wiring DX[L] in each of the circuits XCSa in FIG. 4C.

In the period from Time T11 to Time T12, current does not flow through a wiring WCL[j]_s, the wiring XCL[i], and the wiring XCL[i+1]. Therefore, I_{F2}[i,j], I_{F2m}[i], I_{F2}[i+1,j], and I_{F2m}[i+1] are each 0.

### <<From Time T12 to Time T13>>

In the period from Time T12 to Time T13, a high-level potential is applied to the wiring WSL[i]. Accordingly, in the i-th row in the cell array CA, a high-level potential is applied to the gates of the transistors F1 included in the cell IM[i,1] to the cell IM[i,n] and the gate of the transistor F1m included in the cell IMref[i], so that the transistors F1 and the transistor F1m are turned on. Furthermore, in the period from Time T12 to Time T13, a low-level potential is applied to the wiring WSL[1] to the wiring WSL[m] other than the wiring WSL[i], and in the cell array CA, the transistors F1 included in the cell IM[1,1] to the cell IM[m,n] in the rows other than the i-th row and the transistors F1m included in the cell IMref[1] to the cell IMref[m] in the rows other than the i-th row are in the off state.

The ground potentials GND have been continuously applied to the wiring XCL[1] to the wiring XCL[m] since before Time T12.

### <<From Time T13 to Time T14>>

In the period from Time T13 to Time T14, current with a current amount I₀[i,j] flows as the first data from the circuit WCSa[j] to the wiring WCL[j]_s through the switch SW3[j]. Specifically, when the wiring WCL illustrated in FIG. 4A is the wiring WCL[j]_s, signals corresponding to the first data are input to the wiring DW[1] to the wiring DW[K], whereby the current I₀[i,j] flows from the circuit WCSa to the second terminal of the switch SW3[j]. That is, when the value of the K-bit signal input as the first data is α[i,j] (α[i,j] is an integer greater than or equal to 0 and less than or equal to 2^{K-1}), I₀[i,j] is equal to α[i,j]×I_{Wut}.

Since I₀[i,j] is equal to 0 when α[i,j] is 0, current does not flow from the circuit WCSa to the cell array CA through the switch SW3[j] in a strict sense, but in this specification and the like, the expression such as “current with I₀[i,j]=0 flows” is sometimes used.

In the period from Time T13 to Time T14, electrical continuity is established between the wiring WCL[j]_s and the first terminal of the transistor F1 included in the cell IM[i,j] in the i-th row in the cell array CA, and electrical continuity is not established between the wiring WCL[j]_s and the first terminals of the transistors F1 included in the cell IM[1,j] to the cell IM[m,j] in the rows other than the i-th row in the cell array CA; accordingly, current with the current amount I₀[i,j] flows from the wiring WCL[j] to the cell IM[i,j].

When the transistor F1 included in the cell IM[i,j] is turned on, the transistor F2 included in the cell IM[i,j] has a diode-connected structure. Therefore, when current flows from the wiring WCL[j]_s to the cell IM[i,j], the potentials of the gate of the transistor F2 and the second terminal of the transistor F2 are substantially equal to each other. The potentials are determined by the amount of current flowing from the wiring WCL[j] to the cell IM[i,j], the potential of the first terminal of the transistor F2 (here, GND), and the like. In this operation example, the current with the current amount I₀[i,j] flows from the wiring WCL[j] to the cell IM[i,j], whereby the potential of the gate of the transistor F2 (the node NN[i,j]) becomes V_{g}[i,j]. That is, the gate-source voltage of the transistor F2 is V_{g}[i,j]−GND, and the current with the amount I₀[i,j] is set as current flowing between the first terminal and the second terminal of the transistor F2.

Here, when the threshold voltage of the transistor F2 is Vth[i,j], the current with the amount I₀[i,j] in the case where the transistor F2 operates in the subthreshold region can be expressed by the following formula.

$$[ Formula 1 ]$$

$${I}_{0} [ i , j ] = {I}_{a} exp \{ J ( {V}_{g} [ i , j ] - {V}_{t h} [ i , j ] ) \} \qquad ( 1.1 )$$

Note that Iₐ is a drain current for the case where V_{g}[i,j] is Vth[i,j], and J is a correction coefficient determined by the temperature, the device structure, and the like.

In the period from Time T13 to Time T14, current with a current amount I_{ref0} flows as the reference data from the circuit XCS to the wiring XCL[i]. Specifically, when the wiring XCL illustrated in FIG. 4(C) is the wiring XCL[i], a high-level potential is input to the wiring DX[1], a low-level potential is input to the wiring DX[2] to the wiring DX[K], and the current I_{ref0} flows from the circuit XCSa to the wiring XCL[i]. In other words, I_{ref0} is equal to I_{Xut}.

In the period from Time T13 to Time T14, since electrical continuity is established between the first terminal of the transistor F1m included in the cell IMref[i] and the wiring XCL[i], the current with the current amount I_{ref0} flows from the wiring XCL[i] to the cell IMref[i].

As in the cell IM[i,j], when the transistor F1m included in the cell IMref[i] is turned on, the transistor F2m included in the cell IMref[i] has a diode-connected structure. Therefore, when current flows from the wiring XCL[i] to the cell IMref[i], the potentials of the gate of the transistor F2m and the second terminal of the transistor F2m are substantially equal to each other. The potentials are determined by the amount of current flowing from the wiring XCL[i] to the cell IMref[i], the potential of the first terminal of the transistor F2m (here, GND), and the like. In this operation example, the current with the current amount I_{ref0} flows from the wiring XCL[i] to the cell IMref[i], whereby the potential of the gate of the transistor F2 (the node NNref[i]) becomes V_{gm}[i]; at this time, the potential of the wiring XCL[i] is also V_{gm}[i]. That is, the gate-source voltage of the transistor F2m is V_{gm}[i]−GND, and the current with the amount I_{ref0} is set as current flowing between the first terminal and the second terminal of the transistor F2m.

Here, when the threshold voltage of the transistor F2m is Vₜₕₘ[i], the current with the amount I_{ref0} in the case where the transistor F2m operates in the subthreshold region can be expressed by the following formula.

$$[ Formula 2 ]$$

$$\begin{matrix}{I}_{ref 0} = {I}_{a} exp \{ J ( {V}_{g m} [ i ] - {V}_{t h m} [ i ] ) \} & ( 1.2 )\end{matrix}$$

Note that the correction coefficient J is the same as that of the transistor F2 included in the cell IM[i,j]. For example, the same device structure and the same size (channel length and channel width) are used for the transistors. Furthermore, although variations in manufacturing cause variations in the correction coefficient J among the transistors, the variations are suppressed to the extent that the argument described later can be made with sufficient precision for practical purposes.

Here, a weight coefficient w[i,j] that is the first data is defined as follows.

$$[ Formula 3 ]$$

$$\begin{matrix}w [ i , j ] = exp \{ J ( {V}_{g} [ i , j ] - {V}_{t h} [ i , j ] - {V}_{g m} [ i ] + {V}_{t h m} [ i ] ) \} & ( 1.3 )\end{matrix}$$

Thus, Formula (1.1) can be rewritten into the following formula with use of Formula (1.2), Formula (1.3), I₀[i,j]=α[i,j]×I_{Wut}, and I_{ref0}=I_{Xut}.

$$[ Formula 4 ]$$

$$\begin{matrix}{I}_{0} [ i , j ] = w [ i , j ] {I}_{ref 0} ↔ α [ i , j ] {I}_{W u t} = w [ i , j ] {I}_{X u t} & ( 1.4 )\end{matrix}$$

When the current I_{Wut} output from the current source CS of the circuit WCSa in FIG. 4A is equal to the current I_{Xut} output from the current source CS of the circuit XCSa in FIG. 4C, w[i,j] is equal to α[i,j]. That is, when I_{Wut} is equal to I_{Xut}, α[i,j] corresponds to the value of the first data; thus, I_{Wut} and I_{Xut} are preferably equal to each other.

### <<From Time T14 to Time T15>>

In the period from Time T14 to Time T15, a low-level potential is applied to the wiring WSL[i]. Accordingly, in the i-th row in the cell array CA, a low-level potential is applied to the gates of the transistors F1 included in the cell IM[i,1] to the cell IM[i,n] and the gate of the transistor F1m included in the cell IMref[i] so that the transistors F1 and the transistor F1m are turned off.

When the transistor F1 included in the cell IM[i,j] is turned off, V_{g}[i,j]−V_{gm}[i], which is a difference between the potential of the gate of the transistor F2 (the node NN[i,j]) and the potential of the wiring XCL[i], is retained in the capacitor C5. When the transistor F1 included in the cell IMref[i] is turned off, 0, which is a difference between the potential of the gate of the transistor F2m (the node NNref[i]) and the potential of the wiring XCL[i], is retained in the capacitor C5m. In the operation from Time T13 to Time T14, the voltage retained in the capacitor C5m might be voltage that is not 0 (for example, V_{ds} here) depending on the transistor characteristics of one or both of the transistor F1m and the transistor F2m. In this case, the potential of the node NNref[i] is regarded as a potential obtained by adding Vas to the potential of the wiring XCL[i].

### <<From Time T15 to Time T16>>

In the period from Time T15 to Time T16, GND is applied to the wiring XCL[i]. Specifically, for example, when the wiring XCL illustrated in FIG. 4C is the wiring XCL[i], the initialization potential of the wiring VINIL2 is set to the ground potential GND, and the switch SWX is turned on, the potential of the wiring XCL[i] can be set to the ground potential GND.

Thus, the potentials of the node NN[i,1] to the node NN[i,n] change because of capacitive coupling of the capacitors C5 included in the cell IM[i,1] to the cell IM[i,n] in the i-th row, and the potential of the node NNref[i] changes because of capacitive coupling of the capacitor C5m included in the cell IMref[i].

The amount of change in the potentials of the node NN[i,1] to the node NN[i,n] is a potential obtained by multiplying the amount of change in the potential of the wiring XCL[i] by a capacitive coupling coefficient determined by the structures of the cell IM[i,1] to the cell IM[i,n] included in the cell array CA. The capacitive coupling coefficient is calculated using the capacitance of the capacitor C5, the gate capacitance of the transistor F2, and the parasitic capacitance, for example. When the capacitive coupling coefficient due to the capacitor C5 is P in each of the cell IM[i,1] to the cell IM[i,n], the potential of the node NN[i,j] in the cell IM[i,j] decreases by P(V_{gm}[i]−GND) from the potential of the period from Time T14 to Time T15.

Similarly, when the potential of the wiring XCL[i] changes, the potential of the node NNref[i] also changes because of capacitive coupling of the capacitor C5m included in the cell IMref[i]. In the case where the capacitive coupling coefficient due to the capacitor C5m is p as with the capacitor C5, the potential of the node NNref[i] in the cell IMref[i] decreases by P(V_{gm}[i]−GND) from the potential of the period from Time T14 to Time T15.

In the timing chart in FIG. 7, P is equal to 1, for example. Thus, the potential of the node NNref[i] is GND in the period from Time T15 to Time T16.

Accordingly, the potential of the node NN[i,j] of the cell IM[i,j] decreases, so that the transistor F2 is turned off; similarly, the potential of the node NNref[i] of the cell IMref[i] decreases, so that the transistor F2m is also turned off. Therefore, I_{F2}[i,j] and I_{F2m}[i] are each 0 in the period from Time T15 to Time T16.

### <<From Time T16 to Time T17>>

In the period from Time T16 to Time T17, a high-level potential is applied to a wiring WSL[i+1]_s. Accordingly, in the i+1-th row in the cell array CA, a high-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned on. Furthermore, in the period from Time T16 to Time T17, a low-level potential is applied to a wiring WSL[1]_s to a wiring WSL[m]_s other than the wiring WSL[i+1]_s, and in the cell array CA, the transistors F1 included in the cell IM[1,1] to the cell IM[m,n] in the rows other than the i+1-th row and the transistors F1m included in the cell IMref[1] to the cell IMref[m] in the rows other than the i+1-th row are in an off state.

The ground potential GND has been continuously applied to the wiring XCL[1] to the wiring XCL[m] since before Time T16.

### <<From Time T17 to Time T18>>

In the period from Time T17 to Time T18, current with a current amount Jo[i+1,j] flows as the first data from the circuit WCS to the cell array CA through the switch SW3[j]. Specifically, when the wiring WCL illustrated in FIG. 4A is the wiring WCL[j]_s, signals corresponding to the first data are input to the wiring DW[1] to the wiring DW[K], whereby current with a current amount I₀[i+1,j] flows from the wiring WCSa to the second terminal of the switch SW3[j]. That is, when the value of the K-bit signal input as the first data is α[i+1,j] (α[i+1,j] is an integer greater than or equal to 0 and less than or equal to 2^{K-1}), I₀[i+1,j] is equal to α[i+1,j]×I_{Wut}.

Since I₀[i+1,j] is 0 when α[i+1,j] is 0, current does not flow from the circuit WCSa to the cell array CA through the switch SW3[j] in a strict sense, but in this specification and the like, the expression such as “current with I₀[i+1,j]=0 flows” is sometimes used, as in the case of I₀[i,j]=0.

At this time, electrical continuity is established between the wiring WCL[j]_s and the first terminal of the transistor F1 included in the cell IM[i+1,j] in the i+1-th row in the cell array CA, and electrical continuity is not established between the wiring WCL[j]_s and the first terminals of the transistors F1 included in the cell IM[1,j] to the cell IM[m,j] in the rows other than the i+1-th row in the cell array CA; accordingly, the current with the current amount I₀[i+1,j] flows from the wiring WCL[j]_s to the cell IM[i+1,j].

When the transistor F1 included in the cell IM[i+1,j] is turned on, the transistor F2 included in the cell IM[i+1,j] has a diode-connected structure. Therefore, when current flows from the wiring WCL[j]_s to the cell IM[i+1,j], the potentials of the gate of the transistor F2 and the second terminal of the transistor F2 are substantially equal to each other. The potentials are determined by the amount of current flowing from the wiring WCL[j]_s to the cell IM[i+1,j], the potential of the first terminal of the transistor F2 (here, GND), and the like. In this operation example, the current with the current amount I₀[i+1,j] flows from the wiring WCL[j] to the cell IM[i+1,j], whereby the potential of the gate of the transistor F2 (the node NN[i+1,j]) becomes V_{g}[i+1,j]. That is, the gate-source voltage of the transistor F2 is V_{g}[i+1,j]−GND, and the current amount I₀[i+1,j] is set as current flowing between the first terminal and the second terminal of the transistor F2.

Here, when the threshold voltage of the transistor F2 is Vth[i+1,j], the current amount I₀[i+1,j] in the case where the transistor F2 operates in the subthreshold region can be expressed by the following formula.

[Formula 5]

. . . (1.5)

Note that the correction coefficient is J, which is the same as those of the transistor F2 included in the cell IM[i,j] and the transistor F2m included in the cell IMref[i].

In the period from Time T17 to Time T18, the current with the current amount I_{ref0} flows as the reference data from the circuit XCS to the wiring XCL[i+1]. Specifically, as in the period from Time T13 to Time T14, when the wiring XCL illustrated in FIG. 4C is the wiring XCL[i+1], a high-level potential is input to the wiring DX[1], a low-level potential is input to the wiring DX[2] to the wiring DX[K], and the current I_{ref0}=I_{Xut} flows from the circuit XCSa to the wiring XCL[i+1].

In the period from Time T17 to Time T18, since electrical continuity is established between the first terminal of the transistor F1m included in the cell IMref[i+1] and the wiring XCL[i+1], the current with the current amount I_{ref0} flows from the wiring XCL[i+1] to the cell IMref[i+1].

As in the cell IM[i+1,j], when the transistor F1m included in the cell IMref[i+1] is turned on, the transistor F2m included in the cell IMref[i+1,j] has a diode-connected structure. Therefore, when current flows from the wiring XCL[i+1] to the cell IMref[i+1], the potentials of the gate of the transistor F2m and the second terminal of the transistor F2m are substantially equal to each other. The potentials are determined by the amount of current flowing from the wiring XCL[i+1] to the cell IMref[i+1], the potential of the first terminal of the transistor F2m (here, GND), and the like. In this operation example, the current with the current amount I_{ref0} flows from the wiring XCL[i+1] to the cell IMref[i+1], whereby the potential of the gate of the transistor F2m (the node NNref[i+1]) becomes V_{gm}[i+1]; at this time, the potential of the wiring XCL[i+1] is also V_{gm}[i+1]. That is, the gate-source voltage of the transistor F2m is V_{gm}[i+1]−GND, and the current amount I_{ref0} is set as current flowing between the first terminal and the second terminal of the transistor F2m.

Here, when the threshold voltage of the transistor F2m is Vₜₕₘ[i+1,j], the current amount I_{ref0} in the case where the transistor F2m operates in the subthreshold region can be expressed by the following formula.

$$[ Formula 6 ]$$

$${I}_{ref 0} = {I}_{a} exp \{ J ( {V}_{g m} [ i + 1 ] - {V}_{th m} [ i + 1 ] ) \} \qquad ( 1.6 )$$

Note that the correction coefficient J is the same as that of the transistor F2 included in the cell IM[i+1,j].

Here, a weight coefficient w[i+1,j] that is the first data is defined as follows.

$$[ Formula 7 ]$$

$$w [ i + 1 , j ] = exp \{ J ( {V}_{g} [ i + 1 , j ] - {V}_{th} [ i + 1 , j ] - {V}_{gm} [ i + 1 ] + {V}_{t h m} [ i + 1 ] ) \} \qquad ( 1.7 )$$

Thus, Formula (1.5) can be rewritten into the following formula with use of Formula (1.6), Formula (1.7), I₀[i+1,j]=α[i+1,j]×I_{Wut}, and I_{ref0}=I_{Xut}.

$$[ Formula 8 ]$$

$${I}_{0} [ i + 1 , j ] = w [ i + 1 , j ] {I}_{ref 0} ↔ α [ i + 1 , j ] {I}_{Wut} = w [ i + 1 , j ] {I}_{Xut} \qquad ( 1.8 )$$

When the current I_{Wut} output from the current source CS of the circuit WCSa in FIG. 4A is equal to the current I_{Xut} output from the current source CS of the circuit XCSa in FIG. 4C, w[i+1,j] is equal to α[i+1,j]. That is, when I_{Wut} is equal to I_{Xut}, α[i+1,j] corresponds to the value of the first data; accordingly, I_{Wut} and I_{Xut} are preferably equal to each other.

### <<From Time T18 to Time T19>>

In the period from Time T18 to Time T19, a low-level potential is applied to the wiring WSL[i+1]. Accordingly, in the i+1-th row in the cell array CA, a low-level potential is applied to the gates of the transistors F1 included in the cell IM[i+1,1] to the cell IM[i+1,n] and the gate of the transistor F1m included in the cell IMref[i+1] so that the transistors F1 and the transistor F1m are turned off.

When the transistor F1 included in the cell IM[i+1,j] is turned off, V_{g}[i+1,j]−V_{gm}[i+1], which is a difference between the potential of the gate of the transistor F2 (the node NN[i+1,j]) and the potential of the wiring XCL[i+1], is retained in the capacitor C5. When the transistor F1 included in the cell IMref[i+1] is turned off, 0, which is a difference between the potential of the gate of the transistor F2m (the node NNref[i+1]) and the potential of the wiring XCL[i+1], is retained in the capacitor C5m. In the operation from Time T18 to Time T19, the voltage retained in the capacitor C5m might be voltage that is not 0 (for example, Vas here) depending on the transistor characteristics of one or both of the transistor F1m and the transistor F2m. In this case, the potential of the node NNref[i+1] is regarded as a potential obtained by adding Vas to the potential of the wiring XCL[i+1].

### <<From Time T19 to Time T20>>

In the period from Time T19 to Time T20, the ground potential GND is applied to the wiring XCL[i+1]. Specifically, for example, when the wiring XCL illustrated in FIG. 4A is the wiring XCL[i+1], the potential of the wiring XCL[i+1] can be set to the ground potential GND by setting the initialization potential of the wiring VINIL2 to the ground potential GND and turning on the switch SWX.

Thus, the potentials of the node NN[i,1] to the node NN[i+1,n] change because of capacitive coupling of the capacitors C5 included in the cell IM[i+1,1] to the cell IM[i+1,n] in the i+1-th row, and the potential of the node NNref[i+1] changes because of capacitive coupling of the capacitor C5m included in the cell IMref[i+1].

The amount of change in the potentials of the node NN[i+1,1] to the node NN[i+1,n] is a potential obtained by multiplying the amount of change in the potential of the wiring XCL[i+1] by a capacitive coupling coefficient determined by the structures of the cell IM[i+1,1] to the cell IM[i+1,n] included in the cell array CA. The capacitive coupling coefficient is calculated using the capacitance of the capacitor C5, the gate capacitance of the transistor F2, the parasitic capacitance, and the like. In the case where the capacitive coupling coefficient due to the capacitor C5 in each of the cell IM[i+1,1] to the cell IM[i+1,n] is P, which is the same as the capacitive coupling coefficient due to the capacitor C5 in each of the cell IM[i,1] to the cell IM[i,n], the potential of the node NN[i+1,j] in the cell IM[i+1,j] decreases by P(V_{gm}[i+1]−GND) from the potential of the period from Time T18 to Time T19.

Similarly, when the potential of the wiring XCL[i+1] changes, the potential of the node NNref[i+1] also changes because of capacitive coupling of the capacitor C5m included in the cell IMref[i+1]. In the case where the capacitive coupling coefficient due to the capacitor C5m is P as with the capacitor C5, the potential of the node NNref[i+1] in the cell IMref[i+1] decreases by P(V_{gm}[i+1]−GND) from the potential of the period from Time T18 to Time T19.

In the timing chart in FIG. 7, P is equal to 1, for example. Thus, the potential of the node NNref[i+1] is GND in the period from Time T20 to Time T21.

Accordingly, the potential of the node NN[i+1,j] of the cell IM[i+1,j] decreases, so that the transistor F2 is turned off, similarly, the potential of the node NNref[i+1] of the cell IMref[i+1] decreases, so that the transistor F2m is also turned off. Therefore, I_{F2}[i+1,j] and I_{F2m}[i+1] are each 0 in the period from Time T19 to Time T20.

### <<From Time T20 to Time T21>>

In the period from Time T20 to Time T21, a low-level potential is applied to the wiring SWL1. Accordingly, a low-level potential is applied to each of the control terminals of the switch SW3[1] to the switch SW3[n], whereby the switch SW3[1] to the switch SW3[n] are turned off.

### <<From Time T21 to Time T22>>

In the period from Time T21 to Time T22, a high-level potential is applied to the wiring SWL2. Accordingly, a high-level potential is applied to each of the control terminals of the switch SW4[1] to the switch SW4[n], whereby the switch SW4[1] to the switch SW4[n] are turned on.

### <<From Time T22 to Time T23>>

In the period from Time T22 to Time T23, current x[i]I_{ref0}, which is x[i] times as high as the current with the amount I_{ref0}, flows as the second data from the circuit XCS to the wiring XCL[i]. Specifically, for example, when the wiring XCL illustrated in FIG. 4C is the wiring XCL[i], a high-level potential or a low-level potential is input to the wiring DX[1] to the wiring DX[K] in accordance with the value of x[i], and the current with the amount x[i]I_{ref0}=x[i]I_{Xut} flows from the circuit XCSa to the wiring XCL[i]. In this operation example, x[i] corresponds to the value of the second data. At this time, the potential of the wiring XCL[i] changes from 0 to V_{gm}[i]+ΔV[i].

When the potential of the wiring XCL[i] changes, the potentials of the node NN[i,1] to the node NN[i,n] also change because of the capacitive coupling of the capacitors C5 included in the cell IM[i,1] to the cell IM[i,n] in the i-th row in the cell array CA. Thus, the potential of the node NN[i,j] in the cell IM[i,j] becomes V_{g}[i,j]+PΔV[i].

Similarly, when the potential of the wiring XCL[i] changes, the potential of the node NNref[i] also changes because of capacitive coupling of the capacitor C5m included in the cell IMref[i]. Thus, the potential of the node NNref[i] in the cell IMref[i] becomes V_{gm}[i]+PΔV[i].

Accordingly, current with an amount I₁[i,j] that flows between the first terminal and the second terminal of the transistor F2 and current with an amount I_{ref1}[i,j] that flows between the first terminal and the second terminal of the transistor F2m in the period from Time T22 to Time T23 can be expressed as follows.

$$\begin{matrix}[ Formula 9 ] & \\ \begin{matrix}{I}_{1} [ i , j ] = {I}_{a} exp \{ J ( {V}_{g} [ i , j ] + P Δ V [ i ] - {V}_{t h} [ i , j ] ) \} \\ = {I}_{0} [ i , j ] exp ( JP Δ V [ i ] )\end{matrix} & ( 1.9 )\end{matrix}$$

$$\begin{matrix}[ Formula 10 ] & \\ \begin{matrix}{I}_{r e f 1} [ i ] = {I}_{a} exp \{ J ( {V}_{g m} [ i ] + P Δ V [ i ] - {V}_{t h m} [ i ] ) \} \\ = x [ i ] {I}_{ref 0}\end{matrix} & ( 1.1 )\end{matrix}$$

Note that x[i] is as expressed by the following formula.

$$[ Formula 11 ]$$

$$\begin{matrix}x [ i ] = exp ( JP Δ V [ i ] ) & ( 1.11 )\end{matrix}$$

Therefore, Formula (1.9) can be rewritten into the following formula with the use of Formula (1.4) and Formula (1.11).

$$[ Formula 12 ]$$

$$\begin{matrix}{I}_{1} [ i , j ] = x [ i ] w [ i , j ] {I}_{ref 0} & ( 1.12 )\end{matrix}$$

That is, the amount of current flowing between the first terminal and the second terminal of the transistor F2 included in the cell IM[i,j] is proportional to the product of the first data w[i,j] and the second data x[i].

In the period from Time T22 to Time T23, current x[i+1]I_{ref0}, which is x[i+1] times as high as the current with the amount I_{ref0}, flows as the second data from the circuit XCS to the wiring XCL[i+1]. Specifically, for example, when the wiring XCL illustrated in FIG. 4C is the wiring XCL[i+1], a high-level potential or a low-level potential is input to the wiring DX[1] to the wiring DX[K] in accordance with the value of x[i+1], and the current with the amount x[i+1]I_{ref0}=x[i+1]I_{Xut} flows from the circuit XCSa to the wiring XCL[i+1]. In this operation example, x[i+1] corresponds to the value of the second data. At this time, the potential of the wiring XCL[i+1] changes from 0 to V_{gm}[i+1]+ΔV[i+1].

When the potential of the wiring XCL[i+1] changes, the potentials of the node NN[i+1,1] to the node NN[i+1,n] also change because of the capacitive coupling of the capacitors C5 included in the cell IM[i+1,1] to the cell IM[i+1,n] in the i+1-th row in the cell array CA. Thus, the potential of the node NN[i+1,j] in the cell IM[i+1,j] becomes V_{g}[i+1,j]+PΔV[i+1].

Similarly, when the potential of the wiring XCL[i+1] changes, the potential of the node NNref[i+1] also changes because of capacitive coupling of the capacitor C5m included in the cell IMref[i+1]. Thus, the potential of the node NNref[i+1] in the cell IMref[i+1] becomes V_{gm}[i+1]+PΔV[i+1].

Accordingly, current with an amount I₁[i+1,j] that flows between the first terminal and the second terminal of the transistor F2 and current with an amount I_{ref1}[i+1,j] that flows between the first terminal and the second terminal of the transistor F2m in the period from Time T22 to Time T23 can be expressed as follows.

$$\begin{matrix}[ Formula 13 ] & \\ \begin{matrix}{I}_{1} [ i + 1 , j ] = {I}_{a} exp \{ J ( {V}_{g} [ i + 1 , j ] + P Δ V [ i + 1 ] - {V}_{t h} [ i + 1 , j ] ) \} \\ = {I}_{0} [ i + 1 , j ] exp ( JPΔV [ i + 1 ] )\end{matrix} & ( 1.13 )\end{matrix}$$

$$\begin{matrix}[ Formula 14 ] & \\ \begin{matrix}{I}_{ref 1} [ i + 1 ] = {I}_{a} exp \{ J ( {V}_{g m} [ i + 1 ] + P Δ V [ i + 1 ] - {V}_{thm} [ i + 1 ] ) \} \\ = x [ i + 1 ] {I}_{ref 0}\end{matrix} & ( 1.14 )\end{matrix}$$

Note that x[i+1] is as expressed by the following formula.

$$[ Formula 15 ]$$

$$x [ i + 1 ] = exp ( J P Δ V [ i + 1 ] ) \qquad ( 1.15 )$$

Therefore, Formula (1.13) can be rewritten into the following formula with the use of Formula (1.8) and Formula (1.15).

$$[ Formula 16 ]$$

$${I}_{1} [ i + 1 , j ] = x [ i + 1 ] w [ i + 1 , j ] {I}_{ref 0} \qquad ( 1.16 )$$

That is, the amount of current flowing between the first terminal and the second terminal of the transistor F2 included in the cell IM[i+1,j] is proportional to the product of the first data w[i+1,j] and the second data x[i+1].

Here, the sum of the amounts of current flowing from the converter circuit ITRZ[j] to the cell IM[i,j] and the cell IM[i+1,j] through the switch SW4[j] and the wiring WCL[j]_s is considered. According to Formula (1.12) and Formula (1.16), when the sum of the amounts of current is I_{S}[j], I_{S}[j] can be expressed by the following formula.

$$\begin{matrix}[ Formula 17 ] & \\ \begin{matrix}{I}_{S} [ j ] = {I}_{1} [ i , j ] + {I}_{1} [ i + 1 , j ] \\ = {I}_{r e f 0} ( x [ i ] w [ i , j ] + x [ i + 1 ] w [ i + 1 , j ] )\end{matrix} & ( 1.17 )\end{matrix}$$

Thus, the amount of current output from the converter circuit ITRZ[j] is the amount of current proportional to the sum of products of the weight coefficients w[i,j] and w[i+1,j] that are the first data and the values x[i] and x[i+1] of the signals of the neurons that are the second data.

Although the sum of the amounts of current flowing to the cell IM[i,j] and the cell IM[i+1 j] is described in the above-described operation example, the sum of the amounts of current flowing to a plurality of cells, the cell IM[1,j] to the cell IM[m,j], may be described. In this case, Formula (1.17) can be rewritten to the following formula.

$$\begin{matrix}[ Formula 18 ] & \\ {I}_{S} [ j ] = {I}_{ref 0} {\sum }_{i = 1}^{m} x [ i ] w [ i , j ] & ( 1.18 )\end{matrix}$$

Thus, even in the case of the arithmetic circuit 10A including the cell array CA with three or more rows and a plurality of columns, product-sum operation can be performed in the above-described manner. In the arithmetic circuit 10A of such a case, cells in one of the plurality of columns are used for retaining I_{ref0} and xI_{ref0} as the amount of current, whereby product-sum operations, the number of which corresponds to the number of the rest of the columns among the plurality of columns, can be executed concurrently. That is, when the number of columns in a memory cell array increases, a semiconductor device that achieves high-speed product-sum operation can be provided.

### Structure Example 3

The structures of the cell IM and the cell IMref that can be used in the arithmetic circuit 10A in FIG. 2 described in Structure example 2 are not limited to the cell IM and a cell IMr illustrated in the arithmetic circuit 10A in FIG. 3. The structure of the semiconductor device of one embodiment of the present invention may be changed in accordance with circumstances as long as an object of one embodiment of the present invention is achieved.

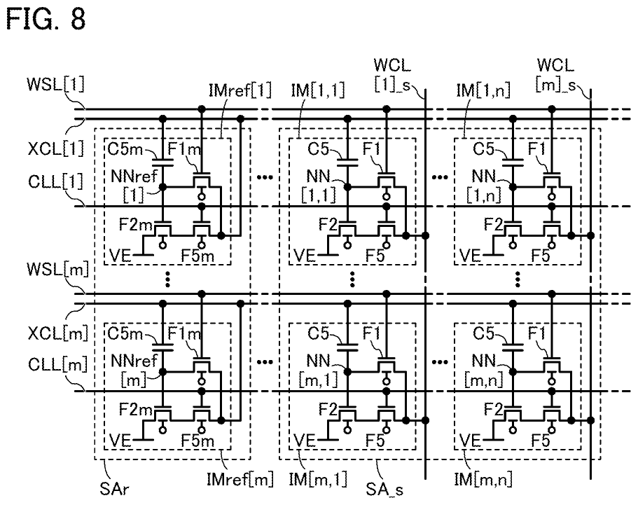

For example, the structures of the cell IM and cell IMref illustrated in FIG. 8 can be used as the cell IM and cell IMref in the arithmetic circuit 10A in FIG. 2. FIG. 8 illustrates the subarray SAr and the subarray SA_s included in the cell array CA in the region L1, for example. As in the arithmetic circuit 10A in FIG. 3, the subarray SAr includes the cell IMref[1] to the cell IMref[m] and the subarray SA_s includes the cell IM[1,1] to the cell IM[m,n].

In FIG. 8, the cell IM[1,1] to the cell IM[m,n] each include a transistor F5 in addition to circuit elements included in the cell IM[1,1] to the cell IM[m,n] in FIG. 3. In FIG. 8, the cell IMref[1] to the cell IMref[m] each include a transistor F5m in addition to circuit elements included in the cell IMref[1] to the cell IMref[m] in FIG. 3.

Note that as each of the transistor F5 and the transistor F5m, a transistor that can be used as the transistor F1, the transistor F2, the transistor F1m, or the transistor F2m can be used, for example. Thus, for the structures of the transistor F5 and the transistor F5, the above-described transistor F1, the transistor F2, the transistor F1m, and the transistor F2m are referred to.

In each of the cell IM[1,1] to the cell IM[m,n] in FIG. 8, the first terminal of the transistor F1 is electrically connected to the gate of the transistor F2. The first terminal of the transistor F2 is electrically connected to the wiring VE. The first terminal of the capacitor C5 is electrically connected to the gate of the transistor F2. The second terminal of the transistor F2 is electrically connected to a first terminal of the transistor F5. A second terminal of the transistor F5 is electrically connected to the second terminal of the transistor F1.

In each of the cell IMref[1] to the cell IMref[m] in FIG. 8, the first terminal of the transistor F1m is electrically connected to the gate of the transistor F2m. The first terminal of the transistor F2m is electrically connected to the wiring VE. The first terminal of the capacitor C5 is electrically connected to the gate of the transistor F2m. The second terminal of the transistor F2m is electrically connected to a first terminal of a transistor F5m. A second terminal of the transistor F5m is electrically connected to the second terminal of the transistor F1m.

In the cell IMref[1] and the cell IM[1,1] to the cell IM[1,n] that are arranged in the first row in the cell array CA, each of the gates of the transistor F5 and the transistor F5m is electrically connected to a wiring CLL[1]. In the cell IMref[m] and the cell IM[m,1] to the cell IM[m,n] that are arranged in the m-th row in the cell array CA, each of the gates of the transistor F5 and the transistor F5m is electrically connected to a wiring CLL[m].

Each of a wiring CCL[1] to a wiring CCL[m] functions as a wiring supplying a constant potential, for example. The constant potential can be, for example, a potential that is higher than 0 V or a potential that is higher than a ground potential.

In the case of the cell IM illustrated in FIG. 3, the transistor F2 is directly electrically connected to the wiring WCL; thus, when the amount of current flowing through the wiring WCL is changed, a potential of the second terminal of the transistor F2 is changed, in some cases. In the case of the cell IMref illustrated in FIG. 3, the transistor F2m is directly electrically connected to the wiring XCL; thus, when the amount of current flowing through the wiring XCL is changed, a potential of the second terminal of the transistor F2m is changed, in some cases. Accordingly, when the source-drain voltage of the transistor F2 or the transistor F2m is changed, the amount of current flowing through the transistor F2 or the transistor F2m is changed, in some cases.

By providing the transistor F5 in the cell IM as illustrated in FIG. 8, the second terminal of the transistor F2 is less likely to be directly affected by a change in a potential of the wiring WCL. Thus, a sudden change in the potential of the second terminal of the transistor F2 in response to the change in the potential of the wiring WCL can be prevented. In a similar manner, by providing the transistor F5m in the cell IM, the second terminal of the transistor F2m is less likely to be directly affected by a change in a potential of the wiring XCL. Thus, a sudden change in the potential of the second terminal of the transistor F2m in response to the change in the potential of the wiring XCL can be prevented.

That is, the transistor F5 has a function of fixing the potential of the second terminal of the transistor F2 or a function of preventing a sudden change in the potential of the second terminal of the transistor F2. In a similar manner, the transistor F5m has a function of fixing the potential of the second terminal of the transistor F2m or a function of preventing a sudden change in the potential of the second terminal of the transistor F2m.

Thus, when the cell IM and the cell IMref illustrated in FIG. 8 are used in the arithmetic circuit 10A in FIG. 2, operation of the arithmetic circuit 10A can be stabilized.

Although FIG. 8 illustrates a structure example of the cell array CA in the region L1, the structures of the cell IM and the cell IMref in FIG. 8 may be used as the cell IM and the cell IMref included in the cell array CA in the region L2.

### Structure Example 4

The structure of the arithmetic circuit 10A in FIG. 2 described in Structure example 2 may be changed in accordance with circumstances.

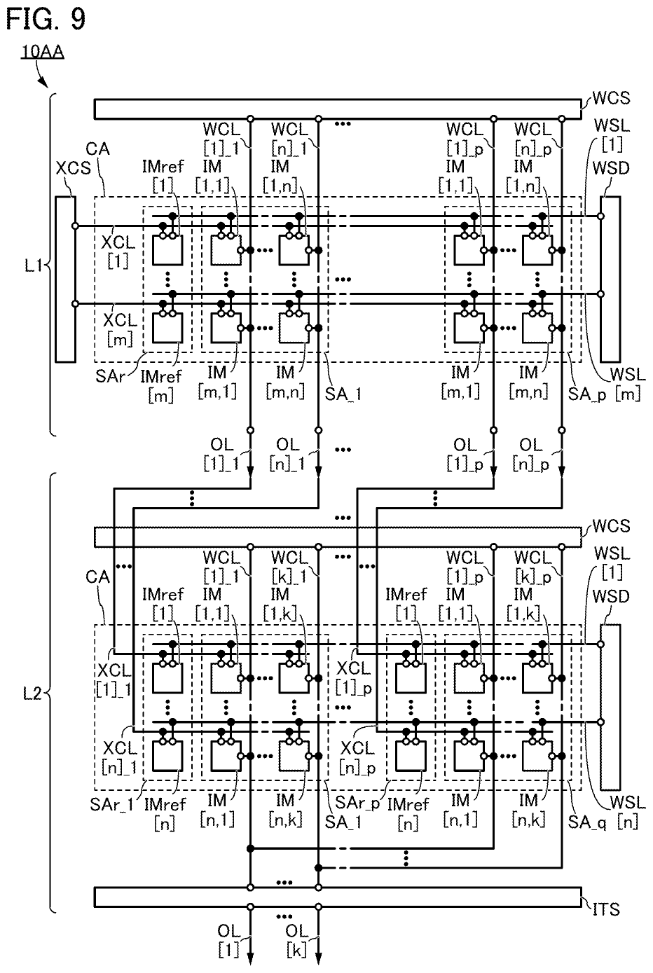

The structure of the arithmetic circuit 10A illustrated in FIG. 2 may be changed as illustrated in an arithmetic circuit 10AA in FIG. 9, for example. The circuit ITS of the arithmetic circuit 10A is not provided in the arithmetic circuit 10AA. That is, in the arithmetic circuit 10AA in FIG. 9, the wiring WCL[1]_1 to the wiring WCL[n]_1 are, respectively, directly electrically connected to the wiring OL[1]_1 to the wiring OL[n]_1 in a one-to-one correspondence, and the wiring WCL[1]_p to the wiring WCL[n]_p are, respectively, directly electrically connected to the wiring OL[1]_p to the wiring OL[n]_p, in a one-to-one correspondence. Although not illustrated in FIG. 9, when p is 3 or more, the wiring WCL[1] to the wiring WCL[n] in the subarray SA other than the subarray SA_1 and the subarray SA_p are electrically connected to the corresponding wirings OL.

With the arithmetic circuit 10AA illustrated in FIG. 9, current flowing from the wiring WCL[1]_1 to the wiring OL[1]_1, that is, the sum of the amounts of current output from the cell IM[1,1] to the cell IM[m,1], can flow directly to the wiring XCL[1]_1 in the region L2, for example. In addition, the wirings WCL other than the wiring WCL[1]_1 in the region L1 can be considered in a similar manner.

Since the circuit ITS is not provided in the arithmetic circuit 10AA in FIG. 9, the circuit area can be reduced compared with the arithmetic circuit 10A in FIG. 2. Furthermore, power consumption required for driving the circuit ITS can be reduced in the arithmetic circuit 10AA in FIG. 9 compared with the arithmetic circuit 10A in FIG. 2.

### Structure Example 5

Although the arithmetic circuit 10A in Structure example 2 illustrates a structure example of an arithmetic circuit that performs product-sum operation of positive or “0” first data and positive or “0” second data, the circuit structure of the arithmetic circuit 10A can be changed, whereby the arithmetic circuit can perform product-sum operation of positive, negative, or “0” first data and positive or “0” second data.

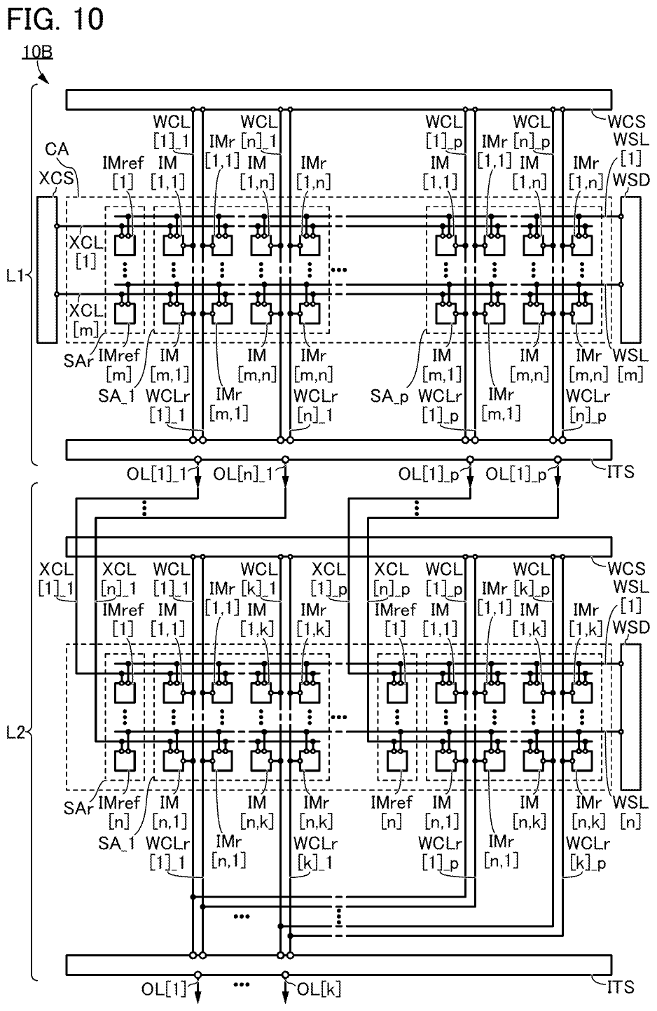

An arithmetic circuit 10 illustrated in FIG. 10 is an example of changes in the arithmetic circuit 10A in FIG. 2, and the arithmetic circuit 10B is different from the arithmetic circuit 10A in that, for example, a plurality of cells IMr are provided and a plurality of wirings WCLr are provided in each of the subarray SA_1 to the subarray SA_p in the region L1 and the region L2.

In each of the subarray SA_1 to the subarray SA_p in the region L1 and the region L2, a cell IMr[i,j] (not illustrated) in the i-th row and the j-th column is provided so as to be in a pair with the cell IM[i,j] (not illustrated), for example. Thus, in each of the subarray SA_1 to the subarray SA_p, arithmetic cells of the cell IM and the cell IMr are provided in a matrix of m rows and 2n columns. Note that in the arithmetic circuit 10B, one pair of the cell IM[i,j] and the cell IMr[i,j] retains one piece of first data.

In each of the subarray SA_1 to the subarray SA_p in the region L1 and the region L2, a wiring WCLr[j] (not illustrated) in the j-th column is provided so as to be in a pair with the wiring WCL[j] (not illustrated), for example. That is, the wiring WCL[1]_1 to the wiring WCL[n]_1 and a wiring WCLr[1]_1 to a wiring WCL[n]r_1 are extended in the column direction in the subarray SA_1, and the wiring WCL[1]_p to the wiring WCL[n]_p and a wiring WCLr[1]_p to a wiring WCL[n]r_p are extended in the column direction in the subarray SA_p, for example.

In the subarray SA_s in the region L1, the cell IMr[i,j] is electrically connected to the wiring XCL[i] and the wiring WSL[i]. The cell IMr[i,j] is electrically connected to a wiring WCLr[j]_s. In the subarray SA_s in the region L2, a cell IMr[j,h] (h is an integer greater than or equal to 1 and less than or equal to k) is electrically connected to a wiring XCL[j]_s and the wiring WSL[j]. The cell IMr[j,h] is electrically connected to the wiring WCLr[h]_s.

In the region L2, the wiring WCL[1]_1 is electrically connected to the wiring WCL[1]_p, as in the arithmetic circuit 10A in FIG. 2. Although not illustrated, in the case where p is 3 or more, the wiring WCL[1]_2 to a wiring WCL[1]_(p−1) which extend in the first columns in different subarrays SA from each other are electrically connected to the wiring WCL[1]_1. The wiring WCL[k]_1 is electrically connected to the wiring WCL[k]_p. Although not illustrated, in the case where p is 3 or more, the wiring WCL[k]_2 to a wiring WCL[k]_(p−1) which extend in the k-th columns in different subarrays SA from each other are electrically connected to the wiring WCL[k]_1.

Furthermore, in the region L2, the wiring WCLr[1]_1 is electrically connected to the wiring WCLr[1]_p. Although not illustrated, in the case where p is 3 or more, a wiring WCLr[1]_2 to a wiring WCLr[1]_(p−1) which extend in the first columns in different subarrays SA from each other are electrically connected to the wiring WCLr[1]_1. A wiring WCLr[k]_1 is electrically connected to the wiring WCLr[k]_p. Although not illustrated, in the case where p is 3 or more, a wiring WCLr[k]_2 to a wiring WCLr[k]_(p−1) which extend in the k-th columns in different subarrays SA from each other are electrically connected to the wiring WCLr[k]_1.

In the subarray SA_s in the region L1, the circuit ITS has a function of obtaining a difference between the amount of current flowing through the wiring WCL[j]_s and the amount of current flowing through the wiring WCLr[j]_s and outputting information corresponding to the difference (e.g., one or both of current and voltage) to the wiring OL[j]_s. Furthermore, in the region L2, the circuit ITS has a function of obtaining the sum of the amounts of current flowing through the wiring WCL[j]_1 to the wiring WCL[j]_p positioned in the j-th column in each of the subarrays SA and the sum of the amounts of current flowing through the wiring WCLr[j]_1 to the wiring WCLr[j]_p positioned in the j-th column in each of the subarrays SA and outputting information corresponding to the difference (e.g., one or both of current and voltage) to the wiring OL[j].

The cells IM can have a structure similar to that of the cell IM[1,1] to the cell IM[m,n] included in the cell array CA in the arithmetic circuit 10A in FIG. 2, for example.

Next, a structure example of the cell IM, the cell IMr, the cell IMref, and the like that can be used for the arithmetic circuit 10B in FIG. 10 is described.

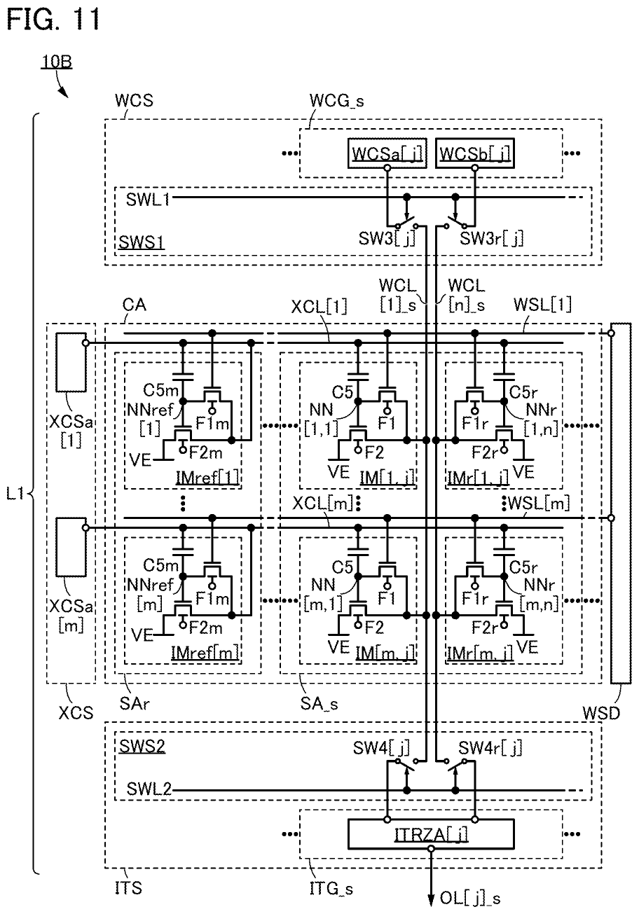

FIG. 11 is a circuit diagram illustrating a specific structure example of the cell IM, the cell IMr, the cell IMref, the circuit WCS, and the circuit ITS of the arithmetic circuit 10B in FIG. 10. Note that FIG. 11 selectively illustrates the subarray SAr and the subarray SA_s. FIG. 11 also illustrates the circuit WCS and the circuit WSD to show electrical connection to the cell array CA.

The cells IMr can have a structure similar to that of the cells IM. FIG. 11 illustrates the cells IMr having a structure similar to that of the cells IM, for example. To distinguish the transistors, the capacitors, and the like included in the cells IM and the cells IMr, “r” is added to the reference numerals representing the transistors and the capacitors included in the cells IMr.

Specifically, the cells IMr each include a transistor Fir, a transistor F2r, and a capacitor C5r. The transistor Fir corresponds to the transistor F1 in the cell IM, the transistor F2r corresponds to the transistor F2 in the cell IM, and the capacitor C5r corresponds to the capacitor C5 in the cell IM. Thus, for the electrical connection structure between the transistor Fir, the transistor F2r, and the capacitor C5r, refer to the description of IM[1,1] to the cell IM[m,n] described above.

In the cell IMr, a connection portion of a first terminal of the transistor Fir, a gate of the transistor F2r, and a first terminal of the capacitor C5r is a node NNr.

In the cell IM[1,j], the second terminal of the capacitor C5 is electrically connected to the wiring XCL[1], the gate of the transistor F1 is electrically connected to the wiring WSL[1], and the second terminal of the transistor F1 and the second terminal of the transistor F2 are electrically connected to the wiring WCL[j]_s. In a cell IMr[1,j], a second terminal of the capacitor C5r is electrically connected to the wiring XCL[1], a gate of the transistor Fir is electrically connected to the wiring WSL[1], and a second terminal of the transistor Fir and a second terminal of the transistor F2r are electrically connected to the wiring WCLr[j]_s.

Similarly, in the cell IM[m,j], the second terminal of the capacitor C5 is electrically connected to the wiring XCL[m], the gate of the transistor F1 is electrically connected to the wiring WSL[m], and the second terminal of the transistor F1 and the second terminal of the transistor F2 are electrically connected to the wiring WCL[j]_s. In a cell IMr[m,j], the second terminal of the capacitor C5r is electrically connected to the wiring XCL[m], the gate of the transistor Fir is electrically connected to the wiring WSL[m], and the second terminal of the transistor Fir and the second terminal of the transistor F2r are electrically connected to the wiring WCLr[j].

The wiring WCL[j] and the wiring WCLr[j] function as, for example, wirings that supply current from the circuit WCS to the cells IM and the cells IMr, like the wiring WCL[1] to the wiring WCL[n] in FIG. 2. As another example, the wiring WCL[j] and the wiring WCLr[j] function as wirings that supply current from the circuit ITS to the cell IM and the cell IMr.

In the arithmetic circuit 10B in FIG. 11, the circuit SWS1 includes the switch SW3[j] and a switch SW3r[j]. A first terminal of the switch SW3[j] is electrically connected to the wiring WCL[j], a second terminal of the switch SW3[j] is electrically connected to the circuit WCSa[j] included in the circuit WCG_s to be described later, and a control terminal of the switch SW3[j] is electrically connected to the wiring SWL1. A first terminal of the switch SW3r[j] is electrically connected to the wiring WCLr[j], a second terminal of the switch SW3r[j] is electrically connected to a circuit WCSb[j] included in the circuit WCG_s to be described later, and a control terminal of the switch SW3r[j] is electrically connected to the wiring SWL1.

The circuit WCG_s of the circuit WCS in FIG. 11 includes the circuit WCSa[j] and the circuit WCSb[j], for example. As the circuit WCSa[j] and the circuit WCSb[j] in FIG. 11, the circuit WCSa illustrated in FIG. 4A, FIG. 4B, or the like can be used, for example.

In the arithmetic circuit 10B in FIG. 11, the circuit SWS2 includes the switch SW4[j] and a switch SW4r[j]. A first terminal of the switch SW4[j] is electrically connected to the wiring WCL[j], a second terminal of the switch SW4[j] is electrically connected to a converter circuit ITRZA[j] described later, and a control terminal of the switch SW4[j] is electrically connected to the wiring SWL2. A first terminal of the switch SW4r[j] is electrically connected to the wiring WCLr[j], a second terminal of the switch SW4r[j] is electrically connected to the converter circuit ITRZA[j] described later, and a control terminal of the switch SW4r[j] is electrically connected to the wiring SWL2.

The circuit ITG_s of the circuit ITS in FIG. 11 includes the converter circuit ITRZA[j], for example. The converter circuit ITRZA[j] is a circuit corresponding to the converter circuit ITRZ[j] in the arithmetic circuit 10A in FIG. 2; for example, the converter circuit ITRZA[j] has a function of generating voltage corresponding to the difference between the amount of current flowing from the converter circuit ITRZA[j] to the wiring WCL[j] and the amount of current flowing from the converter circuit ITRZA[j] to the wiring WCLr[j] and outputting the voltage to the wiring OL[j]_s.

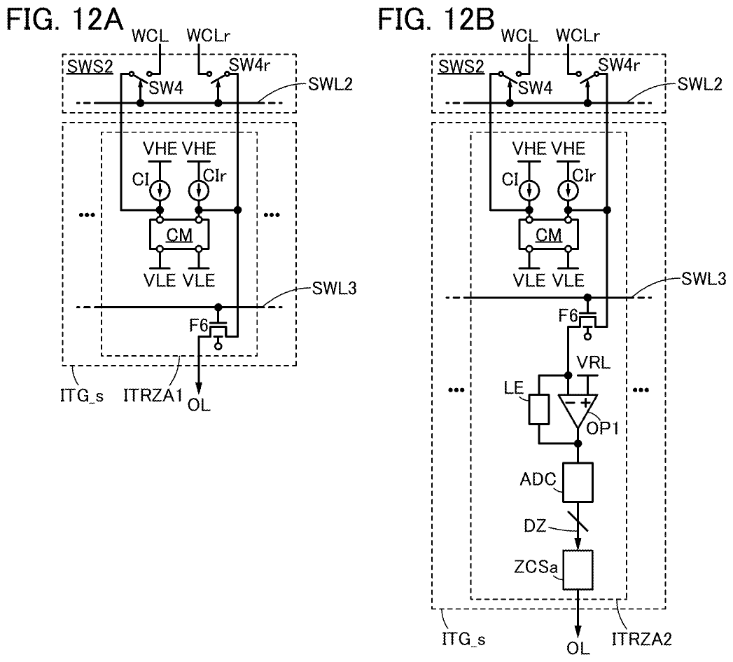

FIG. 12A illustrates a specific structure example of the converter circuit ITRZA[j]. A converter circuit ITRZA1 illustrated in FIG. 12A is an example of a circuit that can be used as the converter circuit ITRZA[j] in FIG. 11. FIG. 12A also illustrates the circuit SWS2, the wiring WCL, the wiring WCLr, the wiring SWL2, the switch SW4, and the switch SW4r to show electrical connection between the converter circuit ITRZA1 and its peripheral circuits. The wiring WCL and the wiring WCLr can be the wiring WCL[j] and the wiring WCLr[j] included in the arithmetic circuit 10B in FIG. 11, respectively, for example, and the switch SW4 and the switch SW4r can be the switch SW4[j] and the switch SW4r[j] included in the arithmetic circuit 10B in FIG. 11, respectively, for example.

The converter circuit ITRZA1 in FIG. 12A is electrically connected to the wiring WCL through the switch SW4. The converter circuit ITRZA1 is electrically connected to the wiring WCLr through the switch SW4r. The converter circuit ITRZA1 is electrically connected to the wiring OL. The converter circuit ITRZA1 has a function of obtaining the difference current between one of the amount of current flowing from the converter circuit ITRZA1 to the wiring WCL through the switch SW4 and the amount of current flowing from the wiring WCL to the converter circuit ITRZA1 through the switch SW4, and one of the amount of current flowing from the converter circuit ITRZA1 to the wiring WCLr through the switch SW4r and the amount of current flowing from the wiring WCLr to the converter circuit ITRZA1 through the switch SW4r. The converter circuit ITRZA1 has a function of making the difference current flow between the converter circuit ITRZA1 and the wiring OL.

The converter circuit ITRZA1 in FIG. 12A includes, for example, a transistor F6, a current source CI, a current source CIr, and a current mirror circuit CM.

The second terminal of the switch SW4 is electrically connected to a first terminal of the current mirror circuit CM and an output terminal of the current source CI, and the second terminal of the switch SW4r is electrically connected to a second terminal of the current mirror circuit CM, an output terminal of the current source CIr, and a first terminal of the transistor F6. An input terminal of the current source CI is electrically connected to a wiring VHE, and an input terminal of the current source CIr is electrically connected to the wiring VHE. A third terminal of the current mirror circuit CM is electrically connected to a wiring VSE, and a fourth terminal of the current mirror circuit CM is electrically connected to the wiring VSE.

A second terminal of the transistor F6 is electrically connected to the wiring OL and a gate of the transistor F6 is electrically connected to a wiring SWL3.

The current mirror circuit CM has, for example, a function of making current with an amount corresponding to the potential of the first terminal of the current mirror circuit CM flow between the first terminal and the third terminal of the current mirror circuit CM and between the second terminal and the fourth terminal of the current mirror circuit CM.

The wiring VHE functions as a wiring for supplying constant voltage, for example. Specifically, the constant voltage can be a high-level potential or the like, for example.

The wiring VSE functions as a wiring for supplying constant voltage, for example. Specifically, the constant voltage can be, for example, a low-level potential, a ground potential, or the like.

The wiring SWL3 functions as, for example, a wiring for transmitting a signal to switch the on state and the off state of the transistor F6. Specifically, for example, a high-level potential or a low-level potential is input to the wiring SWL3.

The current source CI has a function of making constant current flow between the input terminal and the output terminal of the current source CI. The current source CIr has a function of making constant current flow between the input terminal and the output terminal of the current source CIr. The amount of current flowing from the current source CI and the amount of current flowing from the current source CIr are preferably equal to each other in the converter circuit ITRZA1 in FIG. 12A.

An operation example of the converter circuit ITRZA1 in FIG. 12A is described here.

First, the amount of current flowing from the converter circuit ITRZA1 to the wiring WCL through the switch SW4 is set to I_{S}, and the amount of current flowing from the converter circuit ITRZA1 to the wiring WCLr through the switch SW4r is set to I_{Sr}. The amount of current flowing from each of the current source CI and the current source CIr is set to I₀.

In the arithmetic circuit 10B in FIG. 11, I_{S} is the sum of the amounts of current flowing through the cell IM[1,j] to the cell IM[m,j] positioned in the j-th column, for example. In the arithmetic circuit 10B in FIG. 11, I_{Sr} is the sum of the amounts of current flowing through the cell IMr[1,j] to the cell IMr[m,j] positioned in the j-th column, for example.

When a high-level potential is input to the wiring SWL2, the switch SW4 and the switch SW4r are turned on. Accordingly, the amount of current flowing from the first terminal to the third terminal of the current mirror circuit CM becomes I₀−I_{S}. Due to the current mirror circuit CM, the current with the amount I₀−I_{S} flows from the second terminal to the second terminal of the current mirror circuit CM.

Next, a high-level potential is input to the wiring SWL3 to turn on the transistor F6. When the amount of current flowing through the wiring OL is Iₒᵤₜ, Iₒᵤₜ is I₀−(I₀−I_{S})−I_{Sr}=I_{S}−I_{Sr}.

Here, in the arithmetic circuit 10B in FIG. 11, description is made on the case where product-sum operation of positive, negative, or “0” first data and positive or “0” second data is performed. Note that for retention of the first data in the cell IM, the above example of retaining the first data is referred to.

That is, to retain the positive first data in the cell IM[i,j] and the cell IMr[i,j], the cell IM[i,j] is set such that the current with the amount corresponding to the absolute value of the positive first data flows between the first terminal and the second terminal of the transistor F2 in the cell IM[i,j], and the cell IMr[i,j] is set such that current does not flow between the first terminal and the second terminal of the transistor F2r in the cell IMr[i,j]. To retain the negative first data in a circuit CES[i,j], the cell IM[i,j] is set such that current does not flow between the first terminal and the second terminal of the transistor F2 in the cell IM[i,j], and the cell IMr[i,j] is set such that the current with the amount corresponding to the absolute value of the negative first data flows between the first terminal and the second terminal of the transistor F2r in the cell IMr[i,j]. To retain the “0” first data in the circuit CES[i,j], the cell IM[i,j] is set such that current does not flow between the first terminal and the second terminal of the transistor F2 in the cell IM[i,j], and the cell IMr[i,j] is set such that current does not flow between the first terminal and the second terminal of the transistor F2r in the cell IMr[i,j].

Here, in the case where the second data is input to each of the wiring XCL[1] to the wiring XCL[m] of the arithmetic circuit 10B in FIG. 11, the current with the amount flowing between the first terminal and the second terminal of the transistor F2 in the cell IM[i,j] and the current with the amount flowing between the first terminal and the second terminal of the transistor F2 in the cell IMr[i,j] are each proportional to the second data.

I_{S} is the sum of the amounts of current flowing through the cell IM[1,j] to the cell IM[m,j] positioned in the j-th column. Thus, I_{S} can be expressed by Formula (2.1) shown below, for example. That is, I_{S} corresponds to the result of product-sum operation of the absolute value of the positive first data and the second data. I_{Sr} is the sum of the amounts of current flowing through the cell IMr[1,j] to the cell IMr[m,j] positioned in the j-th column. Thus, I_{Sr} is the sum of the amounts of current flowing through the cells IMr and can be expressed similarly by Formula (2.2) shown below, for example. That is, I_{Sr} corresponds to the result of product-sum operation of the absolute value of the negative first data and the second data.

$$\begin{matrix}[ Formula 19 ] & \\ {I}_{S} [ j ] = {I}_{ref 0} {\sum }_{i = 1}^{m} x [ i ] w [ i , j ] & ( 1.19 )\end{matrix}$$

$${I}_{S r} [ j ] = {I}_{ref 0} {\sum }_{i = 1}^{m} x [ i ] {w}_{r} [ i , j ] \qquad ( 1.2 )$$

Thus, the current with the amount Iₒᵤₜ=I_{S}−I_{Sr} flowing to the wiring OL corresponds to the difference between the result of the product-sum operation of the absolute value of the positive first data and the second data and the result of the product-sum operation of the absolute value of the negative first data and the second data. That is, Iₒᵤₜ=I_{S}−I_{Sr} corresponds to the result of the product-sum operation of the negative, “0”, or positive first data retained in the cell IM[1,j] to the cell IM[m,j] and the cell IMr[1,j] to the cell IMr[m,j] and the second data input to each of the wiring XCL[1] to the wiring XCL[m].

When the sum of the amounts of current flowing through the cell IM[1,j] to the cell IM[m,j] is larger than the sum of the amounts of current flowing through the cell IMr[1,j] to the cell IMr[m,j], i.e., I_{S} is larger than I_{Sr}, Iₒᵤₜ is the current amount larger than 0 and flows from the converter circuit ITRZA1 to the wiring OL. By contrast, when the sum of the amounts of current flowing through the cell IM[1,j] to the cell IM[m,j] is smaller than the sum of the amounts of current flowing through the cell IMr[1,j] to the cell IMr[m,j], i.e., I_{S} is smaller than I_{Sr}, current does not flow from the wiring OL to the converter circuit ITRZA1 in some cases. That is, when I_{S} is smaller than I_{Sr}, Iₒᵤₜ can be approximately 0. Therefore, the converter circuit ITRZA1 can be regarded as a ReLU function, for example.

The hierarchical neural network will be described in Embodiment 5.

As the converter circuit ITRZA of the arithmetic circuit 10 in FIG. 11, a converter circuit ITRZA2 illustrated in FIG. 12B may be used. The converter circuit ITRZA2 has a circuit structure in which the converter circuit ITRZA1 in FIG. 12A and the converter circuit ITRZ1 in FIG. 6 are combined with each other. Thus, current with an amount corresponding to the result of the product-sum operation of the first data and the second data, which flows between the first terminal and the second terminal of the transistor F6, is converted into analog voltage by a current-voltage converter circuit formed of the load LE and the operational amplifier OP1. The analog voltage is converted into digital voltage by an analog-digital converter circuit, and the digital voltage is converted into analog current by the circuit ZCSa. Thus, unlike the converter circuit ITRZA1, the converter circuit ITRZA2 can perform current-voltage conversion, analog-digital conversion, and analog current conversion; as a result, a difference in the amount of current output to the wiring OL can be made smaller than that of the converter circuit ITRZA1.

### Structure Example 6

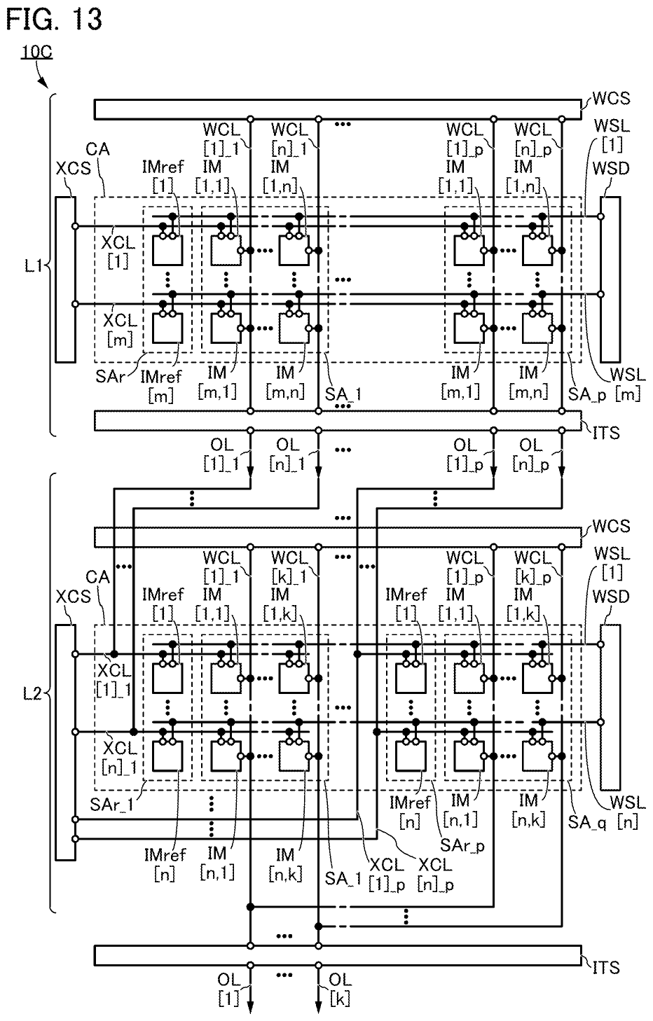

The arithmetic circuit 10A in FIG. 2 described in Structure example 2 may be changed to an arithmetic circuit 10C in FIG. 13. The arithmetic circuit 10C in FIG. 13 is different from the arithmetic circuit 10A in that the circuit XCS is provided in the region L2.

In the region L2, the circuit XCS is electrically connected to the wiring XCL[1]_1 to the wiring XCL[n]_1 and the wiring XCL[1]_ₚ to the wiring XCL[n]_p.

The circuit XCS in the region L2 of the arithmetic circuit 10C outputs the current amount I_{ref0} to the wiring XCL at the time of writing the first data to the cell IM in the cell array CA, for example. That is, in the period from Time T13 to Time T15, Time T17 to Time 19, or the like in the timing chart in FIG. 7, the circuit XCS outputs the current amount I_{ref0} to the wiring XCL, whereby the potential of the wiring XCL is V_{gm}.

In addition, the circuit XCS in the region L2 of the arithmetic circuit 10C stops the output of current to the wiring XCL when arithmetic operation is performed by the cell array CA. Specifically, in the circuit XCS in FIG. 4C, the switch SW5 is turned off. Instead, current corresponding to the result of the arithmetic operation performed by the cell array CA in the region L1 is input to the wiring XCL. That is, in the period from Time T22 to Time T23 or the like in FIG. 7, current is supplied from the circuit ITS in the region L1 to the wiring XCL in the region L2.

With the arithmetic circuit 10C, the circuit XCS in the region L2 can make current for reference flow to the wiring XCL at the time of writing the first data to the cell array CA in the region L2, as described above. By making the current for reference flow to the wiring XCL at the time of writing the first data, arithmetic operation of the first data and the second data can be performed with high accuracy when current corresponding to the result of the arithmetic operation performed by the cell array CA in the region L1 is input to the wiring XCL.

Although the circuit WCS for writing the first data is provided in each of the region L1 and the region L2 in the above-described arithmetic circuit 10, the arithmetic circuit 10A, the arithmetic circuit 10B, and the arithmetic circuit 10C, a structure may be employed in which the first data is written to the cell IM or the like included in the cell array CA in the region L2 with use of the circuit WCS in the region L1, for example. That is, a structure may be employed in which the circuit WCS in the region L2 is not provided in the above-described arithmetic circuit 10, the arithmetic circuit 10A, the arithmetic circuit 10B, and the arithmetic circuit 10C, and the circuit WCS in the region L1 is electrically connected to a plurality of wirings WCL extended in the cell array CA in the region L2.

At least part of the structure examples, the drawings corresponding thereto, and the like described in this embodiment as examples can be combined with the other structure examples, the other drawings, and the like as appropriate.

Note that this embodiment can be combined with any of the other embodiments described in this specification as appropriate.

### Embodiment 2

In this embodiment, structure examples of a display apparatus combining the semiconductor device of one embodiment of the present invention with a display portion are described.

### Structure Example 1

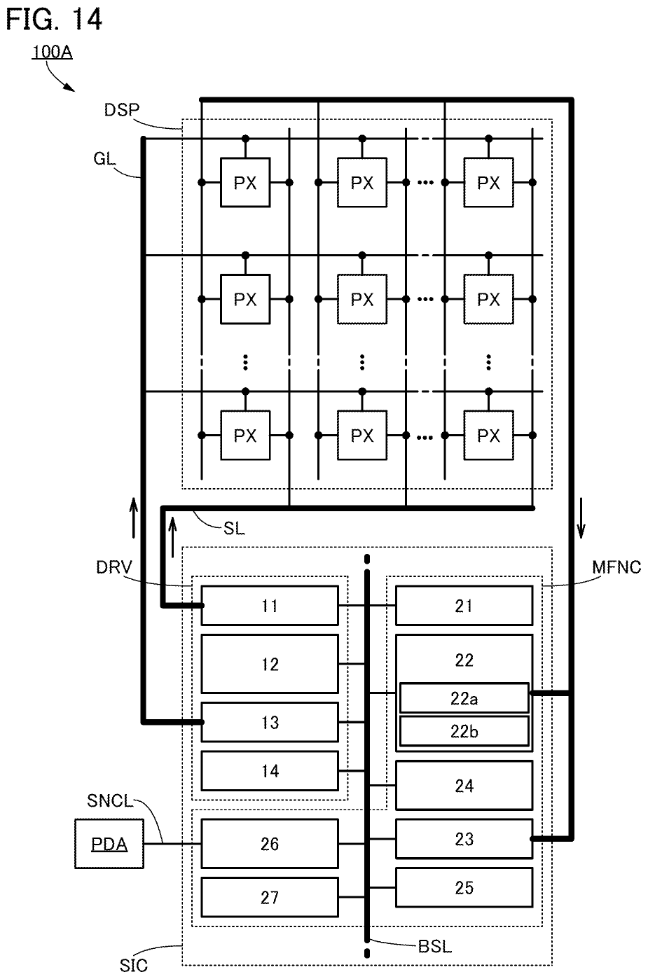

FIG. 14 illustrates a structure example of a display apparatus combining the semiconductor device described in the above embodiment with a display portion. A display apparatus 100A illustrated in FIG. 14 includes a display portion DSP and a circuit portion SIC, for example. A sensor PDA illustrated in FIG. 14 may be positioned inside or outside the display apparatus 100A.

Note that in FIG. 14, the thick lines denote a plurality of wirings or a plurality of bus wirings.

In FIG. 14, a plurality of pixel circuits PX are arranged in a matrix in the display portion DSP, for example. The pixel circuit PX can be, for example, a pixel that includes a liquid crystal display apparatus, a light-emitting device including an organic EL material, or a light-emitting device including a light-emitting diode such as a micro LED. Note that in the description in this embodiment, the pixel circuit PX in the display portion DSP includes a light-emitting device containing an organic EL material. In particular, the luminance of the light emitted from a light-emitting device capable of emitting light with high luminance can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m². Note that a circuit applicable to the display portion DSP, the pixel circuit PX, and the like will be described in detail in Embodiment 4.

In FIG. 14, the circuit portion SIC includes a peripheral circuit DRV and a functional circuit MFNC.

The peripheral circuit DRV functions as a peripheral circuit for driving the display portion DSP, for example. Specifically, the peripheral circuit DRV includes, for example, a source driver circuit 11, a digital-analog converter circuit 12, a gate driver circuit 13, and a level shifter 14.

The functional circuit MFNC can be provided with, for example, a memory device storing image data to be displayed on the display portion DSP, a decoder for restoring encoded image data, a GPU (Graphic Processing Unit) for processing image data, a power supply circuit, a correction circuit, and a CPU. In FIG. 14, the functional circuit MFNC includes, for example, a memory device 21, a GPU (AI accelerator) 22, an EL correction circuit 23, a timing controller 24, a CPU (NoffCPU (registered trademark)) 25, a sensor controller 26, and a power supply circuit 27.

In the display apparatus 100A in FIG. 14, for example, the bus wiring BSL is electrically connected to each of the circuits included in the peripheral circuit DRV and each of the circuits included in the functional circuit MFNC.

The source driver circuit 11 has a function of transmitting image data to the pixel circuit PX included in the display portion DSP, for example. Thus, the source driver circuit 11 is electrically connected to the pixel circuit PX through the wiring SL.

The digital-analog converter circuit 12 has a function of, for example, converting image data that has been digitally processed by a GPU described later, a correction circuit described later, or the like, into analog data. The image data converted into analog data is transmitted to the display portion DSP via the source driver circuit 11. Note that the digital-analog converter circuit 12 may be included in the source driver circuit 11, or the image data may be transmitted to the source driver circuit 11, the digital-analog converter circuit 12, and the display portion DSP in this order.

The gate driver circuit 13 has a function of selecting the pixel circuit PX to which image data is to be transmitted in the display portion DSP, for example. Thus, the gate driver circuit 13 is electrically connected to the pixels PX through the wiring GL.

The level shifter 14 has a function of converting signals to be input to the source driver circuit 11, the digital-analog converter circuit 12, the gate driver circuit 13, and the like into signals having appropriate levels, for example.

The memory device 21 has a function of storing image data to be displayed on the display portion DSP, for example. Note that the memory device 21 can be configured to store the image data as digital data or analog data.

In the case where the memory device 21 stores image data, the memory device 21 is preferably a nonvolatile memory. In that case, a NAND memory or the like can be used as the memory device 21, for example.

In the case where the memory device 21 stores temporary data generated in the GPU 22, the EL correction circuit 23, the CPU 25, or the like, the memory device 21 is preferably a volatile memory. In that case, an SRAM (Static Random Access Memory), a DRAM (Dynamic Random Access Memory), or the like can be used as the memory device 21, for example.

The GPU 22 has a function of performing processing for rendering image data read from the memory device 21 on the display portion DSP, for example. Specifically, the GPU 22 is configured to perform pipeline processing in parallel and thus can perform high-speed processing of image data to be displayed on the display portion DSP. The GPU 22 can also function as a decoder for restoring an encoded image.

The functional circuit MFNC may include a plurality of circuits that can improve the display quality of the display portion DSP. As such circuits, for example, correction (dimming and toning) circuits that detect color irregularity of an image displayed on the display portion DSP and correct the color irregularity to obtain an optimal image may be provided. In the case where light-emitting devices (also referred to as organic EL elements in some cases) utilizing organic EL materials are used in the pixels in the display portion DSP, the functional circuit MFNC may be provided with an EL correction circuit for correcting a variation in luminance of light emitted from a plurality of organic EL elements. Note that because the description in this embodiment is made on the assumption that light-emitting devices containing organic EL materials are used in the pixel circuit PX in the display portion DSP, the functional circuit MFNC is provided with the EL correction circuit 23, for example.

The above-described image correction may be performed using artificial intelligence. For example, current flowing in a display apparatus included in a pixel (or voltage applied to the display apparatus) may be monitored and acquired, an image displayed on the display portion DSP may be acquired with an image sensor or the like, the current (or voltage) and the image may be used as input data in arithmetic operation of the artificial intelligence (e.g., arithmetic operation of an artificial neural network), and the output result may be used to determine whether the image should be corrected.

Such an arithmetic operation of artificial intelligence can be applied to not only image correction but also upconversion processing (downconversion processing) of image data. Accordingly, upconversion processing (down-conversion processing) of low-definition image data can be performed in accordance with the definition of the display portion DSP, which enables a high-display-quality image to be displayed on the display portion DSP.

Note that the above-described arithmetic operation of artificial intelligence can be performed using the GPU 22 included in the functional circuit MFNC. That is, the GPU 22 can be used to perform arithmetic operations for various kinds of correction. Examples of arithmetic operations for various kinds of correction include color irregularity correction and upconversion processing (downconversion processing). The GPU 22 may include a circuit 22a for color irregularity correction and a circuit 22b for upconversion as illustrated in FIG. 14.

Note that in this specification and the like, a GPU performing an arithmetic operation of artificial intelligence is referred to as an AI accelerator. That is, the GPU included in the functional circuit MFNC may be replaced with an AI accelerator in the description in this specification and the like.

As an arithmetic circuit included in the AI accelerator, for example, the arithmetic circuit 10, the arithmetic circuit 10A, the arithmetic circuit 10B, or the like that is the semiconductor device of the above embodiment can be used.

The timing controller 24 has a function of freely setting the frame rate at which an image is displayed on the display portion DSP, for example. For example, the display apparatus 100A can be driven at a frame rate decreased by the timing controller 24 in the case where the display portion DSP displays a still image; for another example, the display apparatus 100A can be driven at a frame rate increased by the timing controller 24 in the case where the display portion DSP displays a moving image. In other words, when the timing controller 24 is provided in the display apparatus 100A, a frame rate can be changed depending on which of a still image and a moving image is displayed. Specifically, since the frame rate when the display portion DSP displays a still image can be decreased, the power consumption of the display apparatus 100A can be reduced.

The CPU 25 has a function of performing general-purpose processing such as execution of an operating system, control of data, and execution of various kinds of arithmetic operations and programs, for example. In the display apparatus 100A, the CPU 25 has a function of, for example, giving an instruction for writing operation or reading operation of image data in the memory device 21, operation for correcting image data, operation for a later-described sensor, or the like. Furthermore, the CPU 25 may have a function of, for example, transmitting a control signal to at least one of circuits included in the functional circuit MFNC, such as a memory device, a GPU, a correction circuit, a timing controller, and a high frequency circuit.

The CPU 25 may include a circuit for temporarily backing up data (hereinafter referred to as a backup circuit). The backup circuit is preferably capable of retaining the data even after supply of power supply voltage is stopped. For example, in the case where the display portion DSP displays a still image, the CPU 25 can cease to work until an image different from the currently displayed still image is displayed. Accordingly, the data under processing by the CPU 25 is temporarily backed up in the backup circuit and then supply of power supply voltage to the CPU 25 is stopped to stop the CPU 25, whereby dynamic power consumption by the CPU 25 can be reduced. In this specification and the like, a CPU including a backup circuit is referred to as an NoffCPU.

The sensor controller 26 has a function of controlling the sensor PDA, for example. FIG. 14 illustrates a wiring SNCL as a wiring for electrically connecting the sensor PDA to the sensor controller 26.

The sensor PDA can be, for example, a touch sensor that can be provided above or below the display portion DSP, or inside the display portion DSP.

Alternatively, the sensor PDA can be an illuminance sensor, for example. Specifically, the illuminance sensor acquiring the intensity of the external light with which the display portion DSP is irradiated makes it possible to change the brightness (luminance) of an image displayed on the display portion DSP in accordance with the external light. For example, under bright external light, the luminance of an image displayed on the display portion DSP can be increased to enhance the viewability of the image. By contrast, under dark external light, the luminance of an image displayed on the display portion DSP can be lowered to reduce the power consumption.

Alternatively, the sensor PDA can be an image sensor, for example. For example, by acquiring an image or the like with the image sensor, the image can be displayed on the display portion DSP.

The power supply circuit 27 has a function of, for example, generating voltages to be supplied to the circuits included in the peripheral circuit DRV, the circuits included in the functional circuit MFNC, the pixels included in the display portion DSP, and the like. Note that the power supply circuit 27 may have a function of selecting a circuit to which voltage is to be supplied. The power supply circuit 27 can stop supply of voltage to the CPU 25, the GPU 22, and the like during a period in which the display portion DSP displays a still image so that the power consumption of the whole display apparatus 100A is reduced, for example.

### Structure Example 2

Here, a structure example is described in which the sensor PDA of the above display apparatus 100A is an image sensor for acquiring images of one or both of the eyes and their surroundings of the user looking at an image displayed by the display apparatus 100A. Note that the eyes of the user mean one or both of the eyeballs and the pupils, and the surroundings of the eyes of the user mean one or more selected from the eyelids, the glabella, and the inner and outer corners of the eyes, for example.

The sensor PDA can capture images of one or both of the eyes and their surroundings of the user looking at an image displayed by the display apparatus 100A, for example. The images of one or both of the user's eyes and their surroundings that have been captured by the sensor PDA are transmitted to the GPU 22 (AI accelerator). The GPU 22 can perform inference processing based on an artificial neural network from the transmitted images.

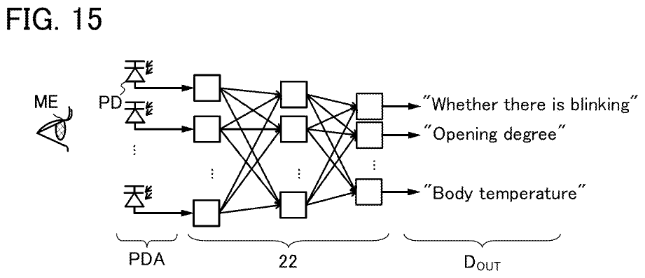

FIG. 15 illustrates an operation example in which the sensor PDA captures images of one or both the user's eyes and their surroundings and the inference processing based on a neural network is performed using the captured images. Specifically, FIG. 15 illustrates an example in which a plurality of light-receiving elements PD included in the sensor PDA capture images of the user's eye ME and its surroundings and the captured images are transmitted to the GPU 22.

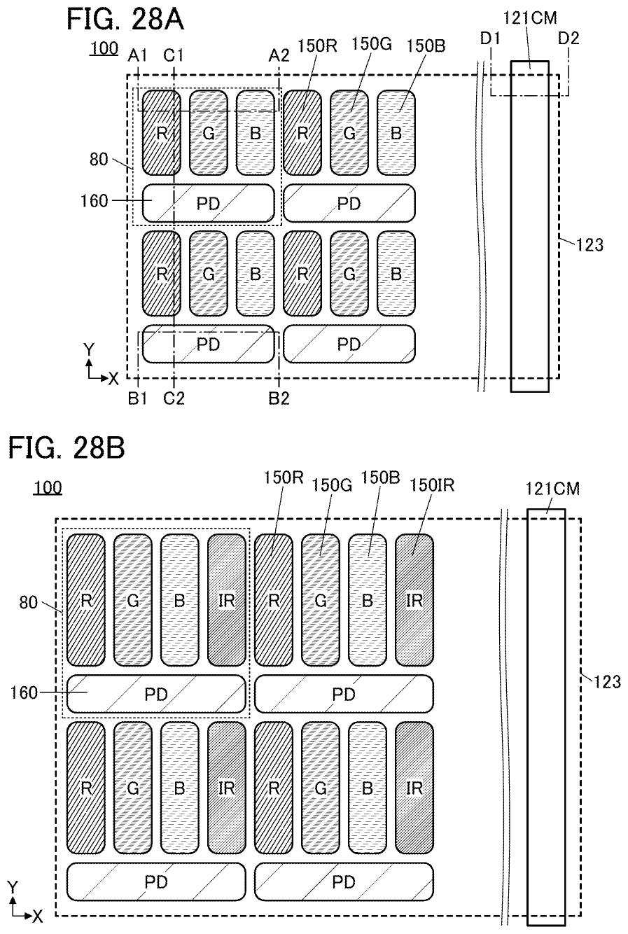

Note that for the sensor PDA illustrated in FIG. 15, the light-receiving elements PD illustrated in FIG. 28A or FIG. 28B described later in Embodiment 4 can be used, for example.

As described above, the GPU 22 performs inference processing based on an artificial neural network. Specifically, such inference processing based on an artificial neural network can be performed when the GPU 22 performs product-sum operation of a captured image and a weight coefficient set in advance by learning and arithmetic operation of an activation function using the result of the product-sum operation. Accordingly, as output data D_{OUT} obtained in the GPU 22, “whether there is blinking”, “opening degree”, and “body temperature” can be inferred from the user's eye ME and its surroundings, for example.

Note that this embodiment can be combined with any of the other embodiments described in this specification as appropriate.

### Embodiment 3

A hierarchical neural network is described in this embodiment. Arithmetic operation of a hierarchical neural network can be performed using the semiconductor device described in the above embodiments.

### <Hierarchical Neural Network>

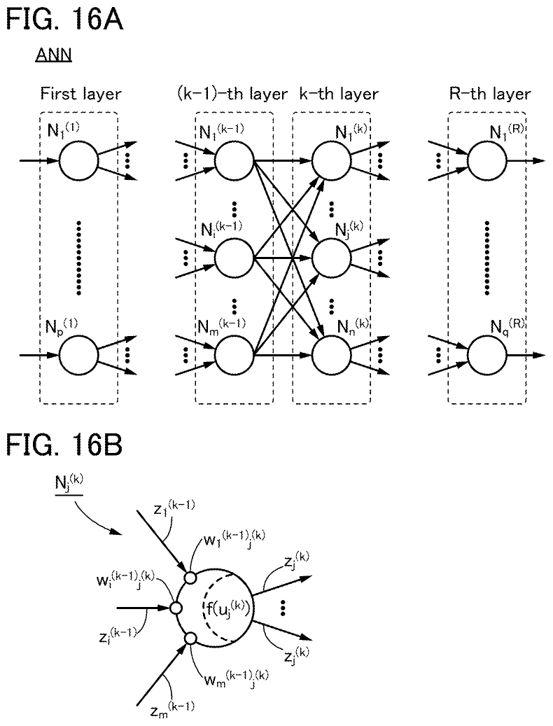

A hierarchical neural network includes one input layer, one or a plurality of intermediate layers (hidden layers), and one output layer, for example, and is configured with a total of at least three layers. A hierarchical neural network ANN illustrated in FIG. 16A is one example, and the neural network ANN includes a first layer to an R-th layer (here, R can be an integer greater than or equal to 4). Specifically, the first layer corresponds to the input layer, the R-th layer corresponds to the output layer, and the other layers correspond to the intermediate layers. Note that FIG. 16A illustrates the (k−1)-th layer and the k-th layer (here, k is an integer greater than or equal to 3 and less than or equal to R−1) as the intermediate layers, and does not illustrate the other intermediate layers.

Each of the layers of the neural network ANN includes one or a plurality of neurons. In FIG. 16A, the first layer includes a neuron N₁⁽¹⁾ to a neuron Nₚ⁽¹⁾ (here, p is an integer greater than or equal to 1); the (k−1)-th layer includes a neuron N₁^{(k-1)} to a neuron Nₘ^{(k-1)} (here, m is an integer greater than or equal to 1); the k-th layer includes a neuron N₁^{(k)} to a neuron Nₙ^{(k)} (here, n is an integer greater than or equal to 1); and the R-th layer includes a neuron N₁^{(R)} to a neuron N_{q}^{(R)} (here, q is an integer greater than or equal to 1).

FIG. 16A illustrates a neuron Nᵢ^{(k-1)} (here, i is an integer greater than or equal to 1 and less than or equal to m) in the (k−1)-th layer and a neuron Nⱼ^{(k)} (here, j is an integer greater than or equal to 1 and less than or equal to n) in the k-th layer, in addition to the neuron N₁⁽¹⁾, the neuron Nₚ⁽¹⁾, the neuron N₁^{(k-1)}, the neuron Nₘ^{(k-1)}, the neuron N₁^{(k)}, the neuron Nₙ^{(k)}, the neuron N₁^{(R)}, and the neuron N_{q}^{(R)}; the other neurons are not illustrated.

Next, signal transmission from a neuron in one layer to a neuron in the subsequent layer and signals input to and output from the neurons are described. Note that description here is made focusing on the neuron Nⱼ^{(k)} in the k-th layer.

FIG. 16B illustrates the neuron Nⱼ^{(k)} in the k-th layer, signals input to the neuron Nⱼ^{(k)}, and a signal output from the neuron Nⱼ^{(k)}.

Specifically, z₁^{(k-1)} to zₘ^{(k-1)} that are output signals from the neuron N₁^{(k-1)} to the neuron Nₘ^{(k-1)} in the (k−1)-th layer are output to the neuron Nⱼ^{(k)}. Then, the neuron Nⱼ^{(k)} generates zⱼ^{(k)} in accordance with z₁^{(k-1)} to zₘ^{(k-1)}, and outputs zⱼ^{(k)} as the output signal to the neurons in the (k+1)-th layer (not illustrated).

The efficiency of transmitting a signal input from a neuron in one layer to a neuron in the subsequent layer depends on the connection strength (hereinafter referred to as a weight coefficient) of the synapse that connects the neurons to each other. In the neural network ANN, a signal output from a neuron in one layer is multiplied by the corresponding weight coefficient and then is input to a neuron in the subsequent layer. When i is an integer greater than or equal to 1 and less than or equal to m and the weight coefficient of the synapse between the neuron Nᵢ^{(k-1)} in the (k−1)-th layer and the neuron Nⱼ^{(k)} in the k-th layer is wᵢ^{(k-1)}ⱼ^{(k)}, a signal input to the neuron Nⱼ^{(k)} in the k-th layer can be expressed by Formula (3.1).

$$[ Formula 20 ]$$

$${{w}_{i}^{( k - 1 )}}_{j}^{( k )} \cdot {z}_{i}^{( k - 1 )} \qquad ( 3.1 )$$

That is, when the signals are transmitted from the neuron N₁^{(k-1)} to the neuron Nₘ^{(k-1)} in the (k−1)-th layer to the neuron Nⱼ^{(k)} in the k-th layer, the signals z₁^{(k-1)} to zₘ^{(k-1)} are multiplied by the respective weight coefficients (w₁^{(k-1)}ⱼ^{(k)} to wₘ^{(k-1)}ⱼ^{(k)}). Then, w₁^{(k-1)}ⱼ^{(k)}·z₁^{(k-1)} to wₘ^{(k-1)}ⱼ^{(k)}·zₘ^{(k-1)} are input to the neuron Nⱼ^{(k)} in the k-th layer. At this time, the total sum uⱼ^{(k)} of the signals input to the neuron Nⱼ^{(k)} in the k-th layer is expressed by Formula (3.2).

$$\begin{matrix}[ Formula 21 ] & \\ {u}_{j}^{( k )} = {\sum }_{i = 1}^{m} {{w}_{i}^{( k - 1 )}}_{j}^{( k )} \cdot {z}_{i}^{( k - 1 )} & ( 3.2 )\end{matrix}$$

In addition, a bias may be added to the result of the product-sum operation of the weight coefficients w₁^{(k-1)}ⱼ^{(k)} to wₘ^{(k-1)}ⱼ^{(k)} and the signals z₁^{(k-1)} to zₘ^{(k-1)} of the neurons. When the bias is denoted by b, Formula (3.2) can be rewritten to the following formula.

$$\begin{matrix}[ Formula 22 ] & \\ {u}_{j}^{( k )} = {\sum }_{i = 1}^{m} {{w}_{i}^{( k - 1 )}}_{j}^{( k )} \cdot {z}_{i}^{( k - 1 )} + b & ( 3.3 )\end{matrix}$$

The neuron Nⱼ^{(k)} generates the output signal zⱼ^{(k)} in accordance with uⱼ^{(k)}. Here, the output signal zⱼ^{(k)} from the neuron Nⱼ^{(k)} is defined by the following formula.

$$[ Formula 23 ]$$

$$\begin{matrix}{z}_{j}^{( k )} = f ( {u}_{j}^{( k )} ) & ( 3.4 )\end{matrix}$$

A function ƒ(uⱼ^{(k)}) is an activation function in a hierarchical neural network, and a step function, a linear ramp function, a sigmoid function, or the like can be used. Note that the activation function may be the same or different among all neurons. In addition, the neuron activation function may be the same or different between the layers.

Signals output from the neurons in the layers, the weight coefficients w, or the bias b may be an analog value or a digital value. For example, a binary or ternary digital value may be used. A value having a larger number of bits may be used. In the case of an analog value, for example, a linear ramp function or a sigmoid function is used as the activation function. In the case of a binary digital value, for example, a step function with an output of −1 or 1 or an output of 0 or 1 is used. Alternatively, the neurons in the layers may each output a ternary or higher-level signal; in this case, a step function with an output of three or more values, for example, an output of −1, 0, or 1 or an output of 0, 1, or 2 is used as an activation function. Furthermore, as an activation function for outputting five values, a step function with an output of −2, −1, 0, 1, or 2 may be used, for example. Using a digital value as at least one of the signals output from the neurons in the layers, the weight coefficients w, and the bias b enables a reduction in the circuit scale, a reduction in power consumption, or an increase in operation speed, for example. Furthermore, the use of an analog value as at least one of the signals output from the neurons in the layers, the weight coefficients w, and the bias b can improve the arithmetic operation accuracy.

The neural network ANN performs operation in which by input of an input signal to the first layer (the input layer), output signals are sequentially generated in the layers from the first layer (the input layer) to the last layer (the output layer) according to Formula (3.1), Formula (3.2) (or Formula (3.3)), and Formula (3.4) on the basis of the signals input from the previous layers, and the output signals are output to the subsequent layers. The signal output from the last layer (the output layer) corresponds to the calculation results of the neural network ANN.

In the case where a circuit included in the region L1 of the arithmetic circuit 10 described in Embodiment 1 is used as the above-described hidden layer, the weight coefficient w_{s[k-1]}^{(k-1)}_{s[k]}^{(k)} (s[k−1] is an integer greater than or equal to 1 and less than or equal to m, and s[k] is an integer greater than or equal to 1 and less than or equal to n) is used as the first data, the current amount corresponding to the first data is stored in the cells IM in the same column sequentially, the output signal z_{s[k-1]}^{(k-1)} from the neuron N_{s[k-1]}^{(k-1)} in the (k−1)-th layer is used as the second data, and the current with the amount corresponding to the second data is made to flow from the circuit XCS to the wiring XCL in each row, so that the product-sum of the first data and the second data can be obtained from the current amount I_{S} input to the converter circuit ITRZ. In addition, the value of the activation function is obtained using the value of the sum of products, so that the value of the activation function can be the output signal z_{s[k]}^{(k)} of the neuron N_{s[k]}^{(k)} in the k-th layer.

In the case where a circuit included in the region L2 of the arithmetic circuit 10 described in Embodiment 1 is used as the above-described output layer, the weight coefficient w_{s[R-1]}^{(R-1)}_{s[R]}^{(R)} (s[R−1] is an integer greater than or equal to 1, and s[R] is an integer greater than or equal to 1 and less than or equal to q) is used as the first data, the current amount corresponding to the first data is stored in the cells IM in the same column sequentially, the output signal z_{s[R-1]}^{(R-1)} from the neuron N_{s[R-1]}^{(R-1)} in the (R−1)-th layer is used as the second data, and the current with the amount corresponding to the second data is made to flow from the circuit XCS to the wiring XCL in each row, so that the sum of products of the first data and the second data can be obtained from the current amount I_{S} input to the converter circuit ITRZ. In addition, the value of the activation function is obtained using the value of the sum of products, so that the value of the activation function can be the output signal z_{s[R]}^{(R)} of the neuron N_{s[R]}^{(R)} in the R-th layer.

Note that the input layer described in this embodiment may function as a buffer circuit that outputs an input signal to the second layer.

Note that this embodiment can be combined with any of the other embodiments described in this specification as appropriate.

### Embodiment 4

In this embodiment, a display apparatus that can be provided in an electronic device of one embodiment of the present invention is described with reference to drawings. Note that the display apparatus described in this embodiment can be used in the display portion DSP described in the above embodiment.

### Structure Example of Display Apparatus

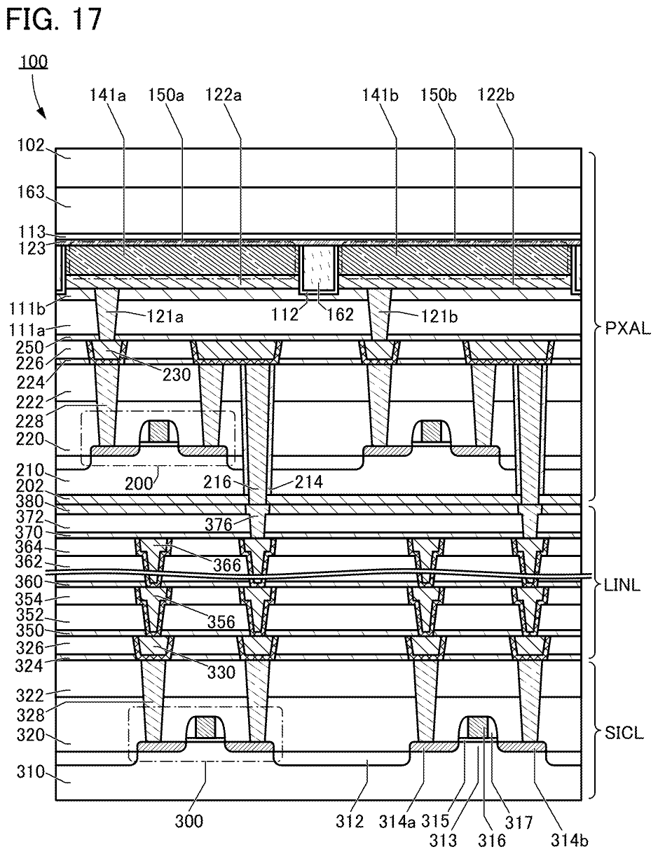

FIG. 17 is a cross-sectional view illustrating an example of a display apparatus of one embodiment of the present invention. A display apparatus 100 illustrated in FIG. 17 has a structure where a pixel circuit, a driver circuit, and the like are provided over a substrate 310, for example.

Specifically, the display apparatus 100 includes, for example, a circuit layer SICL, a wiring layer LINL, and a pixel layer PXAL. The circuit layer SICL includes the substrate 310, for example, and a transistor 300 is formed over the substrate 310. The wiring layer LINL is provided above the transistor 300, and the wiring layer LINL includes a wiring that electrically connects the transistor 300, a transistor 200 to be described later, a light-emitting device 150a and a light-emitting device 150b to be described later, and the like. The pixel layer PXAL is provided above the wiring layer LINL, and the pixel layer PXAL includes, for example, the transistor 200 and a light-emitting device 150 (the light-emitting device 150a and the light-emitting device 150b in FIG. 17).

As the substrate 310, a semiconductor substrate (e.g., a single crystal substrate) containing silicon or germanium as a material can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. Examples of the glass substrate include barium borosilicate glass, aluminoborosilicate glass, and soda lime glass. As examples of the flexible substrate, the attachment film, and the base material film, the following can be given. Examples include plastics typified by polyethylene terephthalate (PET), polyethylene naphthalate (PEN), polyether sulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus 100 involves heat treatment, a highly heat-resistant material is preferably selected for the substrate 310.

In the description of this embodiment, the substrate 310 is a semiconductor substrate containing silicon as a material.

The transistor 300 is provided on the substrate 310 and includes an element isolation layer 312, a conductor 316, an insulator 315, an insulator 317, a semiconductor region 313 that is part of the substrate 310, and a low-resistance region 314a and a low-resistance region 314b that function as source region and a drain region. Thus, the transistor 300 is a Si transistor. Although FIG. 17 illustrates a structure where one of the source and the drain of the transistor 300 is electrically connected to a conductor 330, a conductor 356, and a conductor 366, which are described later, through a conductor 328 described later, the electrical connection in the semiconductor device of one embodiment of the present invention is not limited thereto. The semiconductor device of one embodiment of the present invention may have a structure where, for example, a gate of the transistor 300 is electrically connected to the conductor 330, the conductor 356, and the conductor 366 through the conductor 328.

The transistor 300 can be a fin type when, for example, the top surface of the semiconductor region 313 and the side surface thereof in the channel width direction are covered with the conductor 316 with the insulator 315 functioning as a gate insulating film therebetween. The effective channel width can be increased in the fin-type transistor 300, so that the on-state characteristics of the transistor 300 can be improved. In addition, contribution of the electric field of the gate electrode can be increased, so that the off-state characteristics of the transistor 300 can be improved.

Note that the transistor 300 may be either a p-channel transistor or an n-channel transistor. Alternatively, a plurality of transistors 300 may be provided and both the p-channel transistor and the n-channel transistor may be used.

A region of the semiconductor region 313 where a channel is formed, a region in the vicinity thereof, the low-resistance region 314a and the low-resistance region 314b functioning as the source region and the drain region, and the like preferably contain a silicon-based semiconductor, and preferably contain single crystal silicon, in particular. Each of the above regions may be formed using a material containing germanium (Ge), silicon germanium (SiGe), gallium arsenide (GaAs), gallium aluminum arsenide (GaAlAs), gallium nitride (GaN), or the like. Each of the above regions may employ a structure where silicon whose effective mass is controlled by applying stress to the crystal lattice and thereby changing the lattice spacing is used. Alternatively, the transistor 300 may be an HEMT (High Electron Mobility Transistor) containing gallium arsenide and aluminum gallium arsenide, for example.

For the conductor 316 functioning as a gate electrode, a semiconductor material such as silicon containing an element that imparts n-type conductivity, such as arsenic or phosphorus, or an element that imparts p-type conductivity, such as boron, or a conductive material such as a metal material, an alloy material, or a metal oxide material can be used.

Note that since the work function of a conductor is depends on the material of the conductor, the threshold voltage of the transistor can be adjusted by selecting the material of the conductor. Specifically, one or both of titanium nitride and tantalum nitride are preferably used as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Note that the transistor 300 illustrated in FIG. 17 is an example and the structure is not limited thereto; an appropriate transistor is used in accordance with a circuit structure, a driving method, or the like. For example, the transistor 300 may have a planar structure instead of a fin-type structure.

Over the transistor 300 illustrated in FIG. 17, an insulator 320, an insulator 322, an insulator 324, and an insulator 326 are stacked in this order from the substrate 310 side.

For the insulator 320, the insulator 322, the insulator 324, and the insulator 326, one or more selected from silicon oxide, silicon oxynitride, silicon nitride oxide, silicon nitride, aluminum oxide, aluminum oxynitride, aluminum nitride oxide, and aluminum nitride can be used, for example.

The insulator 322 may have a function of a planarization film for eliminating a level difference caused by the transistor 300 or the like covered with the insulator 320 and the insulator 322. For example, the top surface of the insulator 322 may be planarized by planarization treatment using a chemical mechanical polishing (CMP) method or the like to have improved planarity.

For the insulator 324, it is preferable to use a barrier insulating film preventing diffusion of impurities such as water and hydrogen from the substrate 310 or the transistor 300 to a region above the insulator 324 (e.g., the region where the transistor 200, the light-emitting device 150a, the light-emitting device 150b, and the like are provided). Accordingly, for the insulator 324, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 324, it is preferable to use an insulating material having a function of inhibiting diffusion of impurities such as a nitrogen atom, a nitrogen molecule, a nitrogen oxide molecule (N₂O, NO, NO₂, or the like), and a copper atom (through which the above-described impurities are less likely to pass). In addition, it is preferable that the insulator 324 have a function of inhibiting diffusion of oxygen (e.g., one or both of an oxygen atom and an oxygen molecule).

For the film having a barrier property against hydrogen, silicon nitride deposited by a CVD (Chemical Vapor Deposition) method can be used, for example.

The amount of released hydrogen can be analyzed by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. The dielectric constant of the insulator 326 is, for example, preferably 0.7 times or less, further preferably 0.6 times or less the dielectric constant of the insulator 324. When a material with a low permittivity is used for an interlayer film, the parasitic capacitance generated between wirings can be reduced.

In addition, the conductor 328 and the conductor 330 that are connected to the light-emitting devices and the like provided above the insulator 326 are embedded in the insulator 320, the insulator 322, the insulator 324, and the insulator 326. Note that the conductor 328 and the conductor 330 each function as a plug or a wiring. A plurality of conductors each functioning as a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of plugs and wirings (the conductor 328 and the conductor 330), a single layer or stacked layers of one or more conductive materials selected from a metal material, an alloy material, a metal nitride material, and a metal oxide material can be used. It is preferable to use a high-melting-point material having both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

A wiring layer may be provided over the insulator 326 and the conductor 330. For example, in FIG. 17, an insulator 350, an insulator 352, and an insulator 354 are provided to be stacked in this order above the insulator 326 and the conductor 330. Furthermore, the conductor 356 is formed in the insulator 350, the insulator 352, and the insulator 354. The conductor 356 has a function of a plug or a wiring that is connected to the transistor 300. Note that the conductor 356 can be provided using a material similar to those for the conductor 328 and the conductor 330.

Note that for example, like the insulator 324, the insulator 350 is preferably formed using an insulator having a barrier property against hydrogen, oxygen, and water. Like the insulator 326, the insulator 352 and the insulator 354 are preferably formed using an insulator having a relatively low dielectric constant to reduce parasitic capacitance generated between wirings. The insulator 362 and the insulator 364 each have functions of an interlayer insulating film and a planarization film. Furthermore, the conductor 356 preferably includes a conductor having a barrier property against hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300 while the conductivity of a wiring is kept. In this case, a tantalum nitride layer having a barrier property against hydrogen is preferably in contact with the insulator 350 having a barrier property against hydrogen.

An insulator 360, an insulator 362, and an insulator 364 are stacked in this order over the insulator 354 and the conductor 356.

Like the insulator 324 or the like, the insulator 360 is preferably formed using an insulator having a barrier property against impurities such as water and hydrogen. Thus, the insulator 360 can be formed using any of the materials usable for the insulator 324 or the like, for example.

The insulator 362 and the insulator 364 each have functions of an interlayer insulating film and a planarization film. Like the insulator 324, the insulator 362 and the insulator 364 are preferably formed using an insulator having a barrier property against impurities such as water or hydrogen. Thus, one or both of the insulator 362 and the insulator 364 can be formed using any of the materials usable for the insulator 324.

An opening portion is provided in regions of the insulator 360, the insulator 362, and the insulator 364 that overlap with part of the conductor 356, and the conductor 366 is provided to fill the opening portion. The conductor 366 is also formed over the insulator 362. The conductor 366 has a function of a plug or a wiring connected to the transistor 300, for example. Note that the conductor 366 can be provided using a material similar to those for the conductor 328 and the conductor 330.

An insulator 370 and an insulator 372 are stacked in this order over the insulator 364 and the conductor 366.

Like the insulator 324 or the like, the insulator 370 is preferably formed using an insulator having a barrier property against impurities such as water and hydrogen. Thus, the insulator 370 can be formed using any of the materials usable for the insulator 324 or the like, for example.

The insulator 372 has functions of an interlayer insulating film and a planarization film. For example, like the insulator 324, the insulator 372 is preferably formed using an insulator having a barrier property against impurities such as water and hydrogen. Thus, the insulator 372 can be formed using any of the materials usable for the insulator 324.

An opening portion is formed in regions of the insulator 370 and the insulator 372 that overlap with part of the conductor 366, and a conductor 376 is provided to fill the opening portion. The conductor 376 is also formed over the insulator 372. After that, the conductor 376 is patterned into a form of a wiring, a terminal, or a pad by etching treatment or the like.

For example, copper, aluminum, tin, zinc, tungsten, silver, platinum, or gold can be used for the conductor 376. The material used for the conductor 376 preferably contains the same component as the material used for a later-described conductor 216 included in the pixel layer PXAL.

Then, the insulator 380 is deposited to cover the insulator 372 and the conductor 376 and is subsequently subjected to planarization treatment by a chemical mechanical polishing (CMP) method or the like until the conductor 376 is exposed. In this manner, the conductor 376 serving as a wiring, a terminal, or a pad can be formed over the substrate 310.

Like the insulator 324, the insulator 380 is preferably formed using a film having a barrier property that prevents diffusion of impurities such as water and hydrogen, for example. In other words, the insulator 380 is preferably formed using any of the materials usable for the insulator 324. Like the insulator 326, the insulator 380 may be formed using an insulator having a relatively low dielectric constant to reduce the parasitic capacitance generated between wirings, for example. In other words, the insulator 380 may be formed using any of the materials usable for the insulator 326.

The pixel layer PXAL is provided with a substrate 210, the transistor 200, the light-emitting device 150 (the light-emitting device 150a and the light-emitting device 150b in FIG. 17), and a substrate 102. Moreover, the pixel layer PXAL is provided with an insulator 220, an insulator 222, an insulator 226, an insulator 250, an insulator 111a, an insulator 111b, an insulator 112, an insulator 113, an insulator 162, and a resin layer 163, for example. Furthermore, the pixel layer PXAL is provided with the conductor 216, a conductor 228, a conductor 230, a conductor 121 (a conductor 121a and a conductor 121b in FIG. 17), a conductor 122, and a conductor 123, for example.

An insulator 202 in FIG. 17 functions as a bonding layer together with the insulator 380, for example. The insulator 202 preferably contains, for example, the same component as the material used for the insulator 380.

The substrate 210 is provided above the insulator 202. In other words, the insulator 202 is provided on the bottom surface of the substrate 210. The substrate 210 is preferably a substrate usable as the substrate 310, for example. Note that in the description of the display apparatus 100 in FIG. 17, the substrate 310 is a semiconductor substrate containing silicon as a material.

On the substrate 210, the transistor 200 is formed, for example. Being formed on the substrate 210 that is a semiconductor substrate containing silicon as a material, the transistor 200 functions as a Si transistor. Note that the description of the transistor 300 can be referred to for the structure of the transistor 200.

Above the transistor 200, the insulator 220 and the insulator 222 are provided. Like the insulator 320, the insulator 220 has functions of an interlayer insulating film and a planarization film, for example. Like the insulator 322, the insulator 222 has functions of an interlayer insulating film and a planarization film, for example.

A plurality of opening portions are provided in the insulator 220 and the insulator 222. The plurality of opening portions are formed in regions overlapping with a source and a drain of the transistor 200, a region overlapping with the conductor 376, and the like. The conductor 228 is formed in each of the opening portions formed in the regions overlapping with the source and the drain of the transistor 200, among the plurality of opening portions. An insulator 214 is formed on the side surface of the opening portion formed in the region overlapping with the conductor 376, among the other opening portions, and the conductor 216 is formed in the opening portion. The conductor 216 is sometimes particularly referred to as a through silicon via (TSV).

For the conductor 216 or the conductor 228, any of the materials usable for the conductor 328 can be used, for example. In particular, the conductor 216 is preferably formed using the same material as the conductor 376.

The insulator 214 has a function of electrically insulating the substrate 210 and the conductor 216 from each other, for example. Note that the insulator 214 is preferably formed using, for example, any of the materials usable for the insulator 320 and the insulator 324.

The insulator 380 and the conductor 376 that are formed over the substrate 310 are bonded to the insulator 202 and the conductor 216 that are formed on the substrate 210 by a bonding step, for example.

Before the bonding step, for example, planarization treatment is performed to make surfaces of the insulator 380 and the conductor 376 level with each other on the substrate 310 side. In a similar manner, planarization treatment is performed to make surfaces of the insulator 202 and the conductor 216 level with each other on the substrate 210 side.

In the case where bonding of the insulator 380 and the insulator 202, i.e., bonding of insulating layers, is performed in the bonding step, a hydrophilic bonding method or the like can be employed in which, after high planarity is obtained by polishing or the like, the surfaces subjected to hydrophilicity treatment with oxygen plasma or the like are brought into contact to be bonded to each other temporarily, and then dehydrated by heat treatment to perform final bonding. The hydrophilic bonding method can also cause bonding at an atomic level; thus, mechanically excellent bonding can be obtained.

When bonding of the conductor 376 and the conductor 216, i.e., bonding of the conductors, is performed, for example, a surface activated bonding method can be used in which an oxide film, a layer adsorbing impurities, and the like on the surface are removed by sputtering treatment or the like and the cleaned and activated surfaces are brought into contact to be bonded to each other. Alternatively, a diffusion bonding method in which the surfaces are bonded to each other by using temperature and pressure together can be used, for example. Both methods cause bonding at an atomic level, and therefore not only electrically but also mechanically excellent bonding can be obtained.

Through the above-described bonding step, the conductor 376 on the substrate 310 side can be electrically connected to the conductor 216 on the substrate 210 side. In addition, mechanically strong connection can be established between the insulator 380 on the substrate 310 side and the insulator 202 on the substrate 210 side.

In the case where the substrate 310 and the substrate 210 are bonded to each other, the insulating layers and the metal layers coexist on their bonding surfaces; therefore, the surface activated bonding method and the hydrophilic bonding method are performed in combination, for example. For example, it is possible to use a method in which the surfaces are made clean after polishing, the surfaces of the metal layers are subjected to antioxidant treatment and hydrophilicity treatment, and then bonding is performed. Furthermore, hydrophilicity treatment may be performed on the surfaces of the metal layers being hardly oxidizable metal such as gold.

Note that the substrate 310 and the substrate 210 may be bonded by a bonding method other than the above-described methods. For example, as the bonding method of the substrate 310 and the substrate 210, flip-chip bonding may be employed. In the case of employing flip-chip bonding, a connection terminal such as a bump may be provided above the conductor 376 on the substrate 310 side or below the conductor 216 on the substrate 210 side. Flip-chip bonding can be performed by, for example, injecting a resin containing anisotropic conductive particles between the insulator 380 and the insulator 202 and between the conductor 376 and the conductor 216, or by using a Sn—Ag solder. Alternatively, ultrasonic wave bonding can be employed in the case where the bump and a conductor connected to the bump are each gold. To reduce physical stress such as an impact and thermal stress, the above-described flip-chip bonding may be combined with injection of an underfill agent between the insulator 380 and the insulator 202 and between the conductor 376 and the conductor 216. Furthermore, a die bonding film may be used in bonding of the substrate 310 and the substrate 210, for example.

An insulator 224 and the insulator 226 are stacked in this order over the insulator 222, the insulator 214, the conductor 216, and the conductor 228.

Like the insulator 324, the insulator 224 is preferably a barrier insulating film inhibiting diffusion of impurities such as water and hydrogen to the region above the insulator 224. Thus, the insulator 224 is preferably formed using any of the materials usable for the insulator 324, for example.

Like the insulator 326, the insulator 226 is preferably an interlayer film with a low permittivity. Thus, the insulator 226 is preferably formed using any of the materials usable for the insulator 326, for example.

In the insulator 224 and the insulator 226, the conductor 230 electrically connected to the transistor 200, the light-emitting device 150, and the like is embedded. Note that the conductor 230 has a function of a plug or a wiring. Note that the conductor 230 can be formed using, any of the materials usable for the conductor 328, the conductor 330, and the like, for example.

Over the insulator 224 and the insulator 226, the insulator 250, the insulator 111a, and the insulator 111b are stacked in this order.

Like the insulator 324, the insulator 250 is preferably formed using an insulator having a barrier property against impurities such as water and hydrogen. Thus, the insulator 250 can be formed using any of the materials usable for the insulator 324 or the like, for example.

As each of the insulator 111a and the insulator 111b, a variety of inorganic insulating films, such as an oxide insulating film, a nitride insulating film, an oxynitride insulating film, and a nitride oxide insulating film, can be suitably used. For example, as the insulator 111a, an oxide insulating film or an oxynitride insulating film, such as a silicon oxide film, a silicon oxynitride film, or an aluminum oxide film, is preferably used. For example, as the insulator 111b, a nitride insulating film, such as a silicon nitride film or a silicon nitride oxide film, is preferably used. For another example, as the insulator 111b, a nitride oxide insulating film is preferably used, for example. More specifically, it is preferred that a silicon oxide film be used as the insulator 111a and a silicon nitride film be used as the insulator 111b. The insulator 111b preferably functions as an etching protective film. Alternatively, a nitride insulating film or a nitride oxide insulating film may be used for the insulator 111a, and an oxide insulating film or an oxynitride insulating film may be used for the insulator 111b. Although this embodiment illustrates an example in which a depressed portion is provided in the insulator 111b, a depressed portion is not necessarily provided in the insulator 111b.

An opening portion is formed in regions of the insulator 250, the insulator 111a, and the insulator 111b that overlap with part of the conductor 230, and the conductor 121 is provided to fill the opening portion. Note that in this specification and the like, the conductor 121a and the conductor 121b illustrated in FIG. 17 are collectively referred to as the conductor 121. Note that the conductor 121 can be provided using a material similar to those for the conductor 328 and the conductor 330.

A pixel electrode described in this embodiment contains a material that reflects visible light, and a counter electrode contains a material that transmits visible light, for example.

The display apparatus 100 has a top emission structure. Light from the light-emitting device is emitted toward the substrate 102. For the substrate 102, a material having a high visible-light-transmitting property is preferably used.

The light-emitting device 150a is provided above the conductor 121a, and the light-emitting device 150b is provided above the conductor 121b.

Here, the light-emitting device 150a and the light-emitting device 150b are described.

The light-emitting device described in this embodiment refers to a self-luminous light-emitting device such as an organic EL element (also referred to as an organic light-emitting diode (OLED)). The light-emitting device electrically connected to the pixel circuit can be a self-luminous light-emitting device such as an LED (Light Emitting Diode), a micro LED, a QLED (Quantum-dot Light-Emitting Diode), or a semiconductor laser.

The conductor 122a and the conductor 122b can be formed in such a manner that, for example, a conductive film is deposited over the insulator 111b, the conductor 121a, the conductor 121b, and the like and then a photolithography method or an electron beam lithography method is used for the conductive film.

The conductor 122a to the conductor 122b function respectively as anodes of the light-emitting device 150a and the light-emitting device 150b included in the display apparatus 100, for example.

Indium tin oxide (sometimes referred to as ITO) or the like can be used for the conductor 122a and the conductor 122b, for example.

Each of the conductor 122a and the conductor 122b may have a stacked-layer structure of two or more layers instead of a single-layer structure. For example, a conductor having a high visible-light reflectance can be used for the first-layer conductor and a conductor having a high light-transmitting property can be used for the uppermost-layer conductor. Examples of a conductor having a high visible-light reflectance include silver, aluminum, and an alloy film of silver (Ag), palladium (Pd), and copper (Cu) (Ag—Pd—Cu (APC) film). Examples of a conductor having a high light-transmitting property include indium tin oxide described above. The conductor 122a and the conductor 122b can each be formed using a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order), for example.

An EL layer 141a is provided over the conductor 122a. An EL layer 141b is provided over the conductor 122b.

The EL layer 141a and the EL layer 141b preferably include light-emitting layers emitting light of different colors. For example, the EL layer 141a includes a light-emitting layer emitting light of any one of red (R), green (G), and blue (B), and the EL layer 141b includes a light-emitting layer emitting light of one of the other two colors. Although not illustrated in FIG. 17, in the case where an EL layer different from the EL layer 141a and the EL layer 141b is provided, the EL layer can include a light-emitting layer emitting light of the remaining one color. Thus, the display apparatus 100 may have a structure (an SBS structure) in which light-emitting layers for respective colors are provided over a plurality of pixel electrodes (the conductor 121a and the conductor 121b in FIG. 17).

Note that the combination of colors of light emitted by the light-emitting layers included in the EL layer 141a and the EL layer 141b is not limited to the above, and a color such as cyan, magenta, or yellow may also be used, for example. The number of colors of light emitted by the light-emitting devices 150 included in the display apparatus 100, which is three in the above example, may be two, three, or four or more.

The EL layer 141a and the EL layer 141b may each include one or more of an electron-injection layer, an electron-transport layer, a hole-injection layer, and a hole-transport layer in addition to the layer containing a light-emitting organic compound (the light-emitting layer).

Specifically, the EL layer 141a and the EL layer 141b can be formed, for example, by an evaporation method (a vacuum evaporation method or the like), a coating method (e.g., a dip coating method, a die coating method, a bar coating method, a spin coating method, or a spray coating method), or a printing method (e.g., an ink-jet method, a screen printing (stencil) method, an offset printing (planography) method, a flexography (relief printing) method, a gravure printing method, or a micro-contact printing method).

In the case where the coating method or the printing method is employed as the deposition method, a high molecular compound (e.g., an oligomer, a dendrimer, or a polymer), a middle molecular compound (a compound between a low molecular compound and a high molecular compound with a molecular weight of 400 to 4000), or an inorganic compound (e.g., a quantum dot material) can be used as the material to be deposited. As the quantum dot material, a colloidal quantum dot material, an alloyed quantum dot material, a core-shell quantum dot material, or a core quantum dot material can be used.

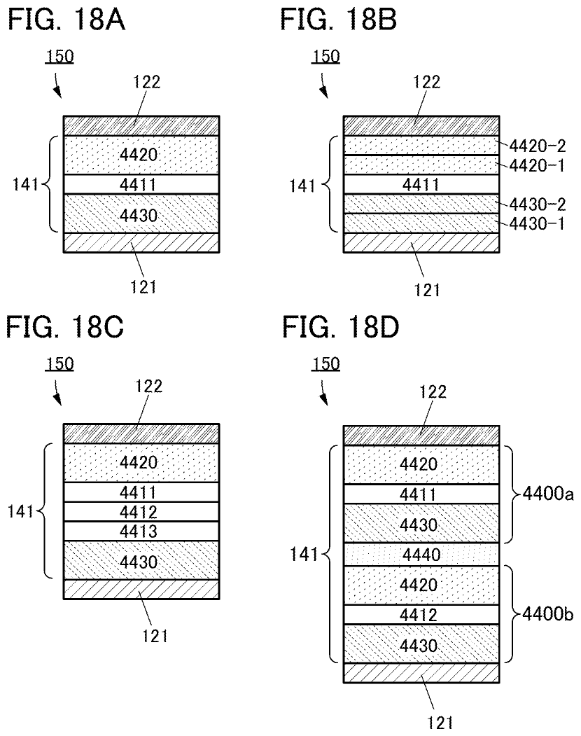

Like the light-emitting device 150 illustrated in FIG. 18A, the light-emitting device 150a and the light-emitting device 150b in FIG. 17 can be formed of a plurality of layers such as a light-emitting layer 4411 and a layer 4430.

A layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes (the conductor 121 and the conductor 122 described later), can function as a single light-emitting unit, and the structure in FIG. 18A is referred to as a single structure in this specification and the like.

FIG. 18B is a variation example of the EL layer 141 included in the light-emitting device 150 illustrated in FIG. 18A. Specifically, the light-emitting device 150 illustrated in FIG. 18B includes a layer 4430-1 over the conductor 121, a layer 4430-2 over the layer 4430-1, the light-emitting layer 4411 over the layer 4430-2, a layer 4420-1 over the light-emitting layer 4411, a layer 4420-2 over the layer 4420-1, and the conductor 122 over the layer 4420-2. For example, when the conductor 121 functions as an anode and the conductor 122 functions as a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the conductor 121 functions as a cathode and the conductor 122 functions as an anode, the layer 4430-1 functions as an electron-injection layer, the layer 4430-2 functions as an electron-transport layer, the layer 4420-1 functions as a hole-transport layer, and the layer 4420-2 functions as the hole-injection layer. With such a layered structure, carriers can be efficiently injected to the light-emitting layer 4411, and the efficiency of the recombination of carriers in the light-emitting layer 4411 can be enhanced.

The structure where a plurality of light-emitting layers (the light-emitting layer 4411, a light-emitting layer 4412, and a light-emitting layer 4413) are provided between the layer 4420 and the layer 4430 as illustrated in FIG. 18C is another variation of the single structure.

A stack including a plurality of layers such as the layer 4420, the light-emitting layer 4411, and the layer 4430 is sometimes referred to as a light-emitting unit. A plurality of light-emitting units can be connected in series with an intermediate layer (a charge generation layer) therebetween. Specifically, a light-emitting unit 4400a and a light-emitting unit 4400b, which are a plurality of light-emitting units, can be connected in series with an intermediate layer (a charge generation layer) 4440 therebetween as illustrated in FIG. 18D. Note that such a structure is referred to as a tandem structure in this specification. A tandem structure may be rephrased as, for example, a stack structure in this specification and the like. Note that a light-emitting device capable of high-luminance light emission can be obtained when the light-emitting device has a tandem structure. When a light-emitting device has a tandem structure, increased emission efficiency of the light-emitting device, an extended lifetime of the light-emitting device, and the like can be expected. In the case where the light-emitting device 150 of the display apparatus 100 in FIG. 17 has a tandem structure, the EL layer 141 can include, for example, the layer 4420, the light-emitting layer 4411, and the layer 4430 that are included in the light-emitting unit 4400a, the intermediate layer 4440, and the layer 4420, the light-emitting layer 4412, and the layer 4430 that are included in the light-emitting unit 4400b.

In displaying white, the aforementioned SBS structure consumes lower power than the aforementioned single structure and tandem structure. To reduce power consumption, the SBS structure is thus preferably used. Meanwhile, the single structure and the tandem structure are preferable in that the manufacturing cost is low or the manufacturing yield is high because the manufacturing processes of the single structure and the tandem structure are simpler than that of the SBS structure.

The emission color of the light-emitting device 150 can be red, green, blue, cyan, magenta, yellow, white, or the like depending on the material that constitutes the EL layer 141. Furthermore, the color purity can be further increased when the light-emitting device 150 has a microcavity structure.

The light-emitting device that emits white light preferably contains two or more kinds of light-emitting substances in the light-emitting layer. To obtain white light emission, for example, two light-emitting substances are selected such that their emission colors are complementary colors. To obtain white light emission, for example, light-emitting substances are selected such that an emission color of one light-emitting substance selected from three or more light-emitting substances and an emission color obtained by combining emissions of the other light-emitting substances are complementary colors.

The light-emitting layer preferably contains two or more kinds of light-emitting substances each of which emits light of R (red), G (green), B (blue), Y (yellow), O (orange), or the like. Alternatively, the light-emitting layer preferably contains two or more kinds of light-emitting substances that emit light containing two or more kinds of spectral components of R, G, and B.

As illustrated in FIG. 17, there is a gap between two EL layers of adjacent light-emitting devices. Specifically, in FIG. 17, a depressed portion is formed between the adjacent light-emitting devices, and the insulator 112 is provided to cover the side surfaces (side surfaces of the conductor 121a, the conductor 122a, and the EL layer 141a and the side surfaces of the conductor 121b, the conductor 122b, and the EL layer 141b) and the bottom surface (a region in the insulator 111b) of the depressed portion. The insulator 162 is formed over the insulator 112 to fill the depressed portion. In this manner, the EL layer 141a and the EL layer 141b are preferably provided so as not to be in contact with each other. This suitably prevents unintentional light emission (also referred to as crosstalk) from being caused by current flowing through two adjacent EL layers (also referred to as a lateral leakage current or a side leakage current). As a result, the contrast can be increased to achieve a display apparatus with high display quality. Furthermore, with the structure with an extremely low lateral leakage current between light-emitting devices, the display apparatus can perform black display with as little light leakage or the like as possible (such display is also referred to as completely black display).

As the formation method of the EL layer 141a and the EL layer 141b, a method with photolithography can be given. For example, the EL layer 141a and the EL layer 141b can be formed in such a manner that an EL film to be the EL layer 141a and the EL layer 141b is deposited over the conductor 122 and then subjected to patterning by a photolithography method. Accordingly, a gap can be provided between two EL layers of adjacent light-emitting devices.

The insulator 112 can be an insulating layer containing an inorganic material. As the insulator 112, an inorganic insulating film such as an oxide insulating film, a nitride insulating film, an oxynitride insulating film, or a nitride oxide insulating film can be used, for example. The insulator 112 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. An aluminum oxide film is particularly preferable because it has high selectivity with respect to the EL layer in the etching step and has a function of protecting the EL layer during formation of the insulator 162 described later. In particular, when an inorganic insulating film such as an aluminum oxide film, a hafnium oxide film, or a silicon oxide film formed by an ALD (Atomic Layer Deposition) method is used as the insulator 112, the insulator 112 having a small number of pin holes and an excellent function of protecting the EL layer can be formed.

Note that in this specification and the like, oxynitride refers to a material that contains more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition.

The insulator 112 can be formed by a sputtering method, a CVD method, a PLD method, an ALD method, or the like. The insulator 112 is preferably formed by an ALD method achieving good coverage.

The insulator 162 provided over the insulator 112 has a planarization function for the depressed portion of the insulator 112, which is formed between the adjacent light-emitting devices. In other words, the insulator 162 has an effect of improving the planarity of the formation surface of the conductor 123 to be described later. As the insulator 162, an insulating layer containing an organic material can be favorably used. For example, as the insulator 162, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used. For the insulator 162, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. Moreover, for the insulator 162, a photosensitive resin can be used, for example. A photoresist may be used as the photosensitive resin, for example. As the photosensitive resin, a positive photosensitive material or a negative photosensitive material can be used.

A difference between the top surface level of the insulator 162 and the top surface level of the EL layer 141a or the EL layer 141b is preferably less than or equal to 0.5 times, further preferably less than or equal to 0.3 times the thickness of the insulator 162. The insulator 162 may be provided, for example, such that the top surface of the EL layer 141a or the EL layer 141b is at a higher level than the top surface of the insulator 162. Alternatively, the insulator 162 may be provided, for example, such that the top surface of the insulator 162 is at a higher level than the top surface of the light-emitting layer included in the EL layer 141a or the EL layer 141b.

The conductor 123 is provided over the EL layer 141a, the EL layer 141b, the insulator 112, and the insulator 162. The insulator 113 is provided over the light-emitting device 150a and the light-emitting device 150b.

The conductor 123 functions as, for example, a common electrode for the light-emitting device 150a and the light-emitting device 150b. The conductor 122 preferably contains a conductive material having a light-transmitting property so that light emitted by the light-emitting device 150 can be extracted to above the display apparatus 100.

The conductor 123 is preferably a light-transmitting and light-reflective material having high conductivity (sometimes referred to as a semi-transmissive and semi-reflective electrode). For example, an alloy of silver and magnesium, or indium tin oxide can be used as the conductor 122.

The insulator 113 is referred to as a protective layer in some cases, and the insulator 113 provided above the light-emitting device 150a and the light-emitting device 150b can increase the reliability of the light-emitting devices. That is, the insulator 113 functions as, for example, a passivation film that protects the light-emitting device 150a and the light-emitting device 150b. Thus, the insulator 113 is preferably formed using a material that prevents entry of water and the like. Any of the materials usable for the insulator 111a or the insulator 111b can be used as the insulator 113, for example. Specifically, aluminum oxide, silicon nitride, silicon nitride oxide, or the like can be used for the insulator 113.

The resin layer 163 is provided over the insulator 113. The substrate 102 is provided over the resin layer 163.

As the substrate 102, a substrate having a light-transmitting property is preferably used, for example. Using a substrate having a light-transmitting property as the substrate 102 enables extraction of light emitted from the light-emitting device 150a and the light-emitting device 150b to above the substrate 102.

Note that the structure of the display apparatus of one embodiment of the present invention is not limited to that of the display apparatus 100 illustrated in FIG. 17. The structure of the display apparatus of one embodiment of the present invention may be changed as appropriate as long as an object of one embodiment of the present invention is achieved.

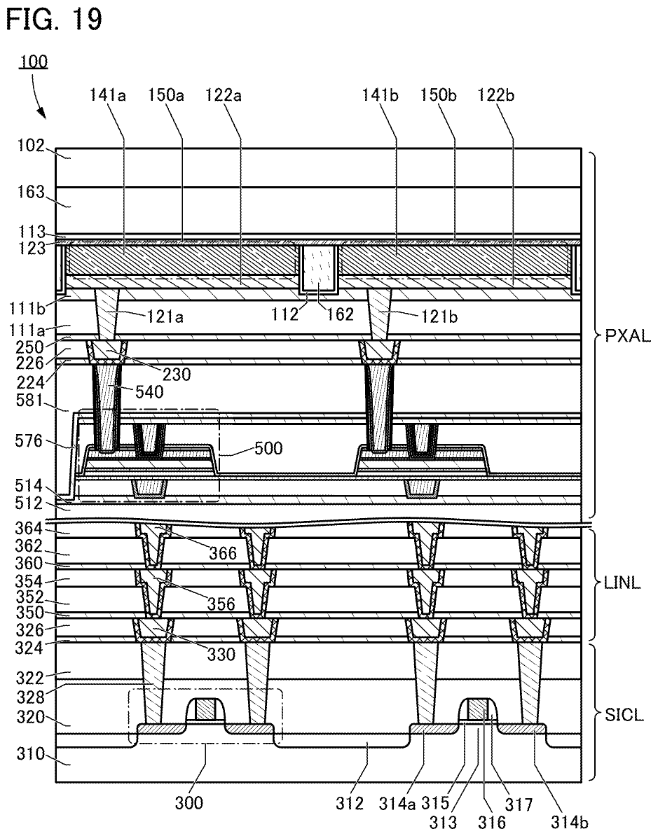

For example, the transistor 200 included in the pixel layer PXAL in the display apparatus 100 in FIG. 17 may be a transistor including a metal oxide in a channel formation region (hereinafter referred to as an OS transistor). The display apparatus 100 illustrated in FIG. 19 has a structure where the light-emitting device 150 and a transistor 500 (an OS transistor), instead of the transistor 200 in the display apparatus 100 in FIG. 17, are provided above the circuit layer SICL and the wiring layer LINL.

In FIG. 19, the transistor 500 is provided over an insulator 512. The insulator 512 is provided above the insulator 364 and the conductor 366, and the insulator 512 is preferably formed using a substance having a barrier property against oxygen and hydrogen, for example. Specifically, the insulator 512 is formed using, for example, silicon oxide, silicon oxynitride, silicon nitride oxide, silicon nitride, aluminum oxide, aluminum oxynitride, aluminum nitride oxide, or aluminum nitride.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 300. The film that inhibits hydrogen diffusion is specifically a film from which a small amount of hydrogen is released.

A material similar to that for the insulator 320 can be used for the insulator 512, for example. When a material with a relatively low permittivity is used for these insulators, parasitic capacitance generated between wirings can be reduced. A silicon oxide film or a silicon oxynitride film can be used as the insulator 512, for example.

An insulator 514 is provided over the insulator 512, and the transistor 500 is provided over the insulator 514. An insulator 576 is formed over the insulator 512 so as to cover the transistor 500. An insulator 581 is formed over the insulator 576 to cover the insulator 576.

As the insulator 514, it is preferable to use a film having a barrier property that prevents diffusion of impurities such as water and hydrogen from the substrate 310, a region where the circuit element or the like below the insulator 512 is provided, or the like into a region where the transistor 500 is provided. Thus, silicon nitride deposited by a CVD method can be used for the insulator 514, for example.

The transistor 500 illustrated in FIG. 19 is an OS transistor that includes a metal oxide in a channel formation region, as described above. As the metal oxide, for example, a metal oxide such as In-M-Zn oxide containing indium, the element M, and zinc (the element Mis one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like) can be used. Specifically, an oxide containing indium, gallium, and zinc (referred to as IGZO in some cases) may be used as the metal oxide, for example. Alternatively, an oxide containing indium, aluminum, and zinc (referred to as IAZO in some cases) may be used as the metal oxide, for example. Alternatively, an oxide containing indium, aluminum, gallium, and zinc (referred to as IAGZO in some cases) may be used as the metal oxide, for example. Alternatively, besides the above, an In—Ga oxide, an In—Zn oxide, or an indium oxide may be used as the metal oxide.

In particular, the metal oxide functioning as a semiconductor preferably has a band gap of 2 eV or more, preferably 2.5 eV or more. With the use of a metal oxide having such a wide band gap, the off-state current of the transistor can be reduced.

In particular, as a driving transistor included in a pixel circuit, a transistor having a sufficiently low off-state current even when the source-drain voltage is high, for example, an OS transistor, is preferably used. With the use of an OS transistor as the driving transistor, the amount of off-state current flowing through the light-emitting device when the driving transistor is in an off state can be reduced, whereby the luminance of light emitted from the light-emitting device through which an off-state current flows can be sufficiently reduced. Thus, in the case where a driving transistor having a high off-state current and a driving transistor having a low off-state current are compared, a pixel circuit including the driving transistor having a low off-state current can have lower emission luminance than a pixel circuit including the driving transistor having a high off-state current when black display is performed by the pixel circuits. That is, the use of an OS transistor can inhibit black blurring when black display is performed by the pixel circuit.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, a high voltage can be applied between the source and the drain of the OS transistor, so that the amount of current flowing through the light-emitting device can be increased and the emission luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting device can be controlled minutely. Therefore, the emission luminance of the light-emitting device can be controlled minutely (the number of gray levels in the pixel circuit can be increased).

Regarding saturation characteristics of current flowing when the transistor operates in a saturation region, the OS transistor can feed constant current (saturation current) more stably than the Si transistor even when the source-drain voltage gradually increases. Thus, by using an OS transistor as the driving transistor, a stable constant current can be fed through a light-emitting device that contains an EL material even when the current-voltage characteristics of the light-emitting device vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black floating”, “increase in emission luminance”, “increase in gray level”, “inhibition of variation in light-emitting devices”, and the like. Therefore, a display apparatus including the pixel circuit can display a clear and smooth image; as a result, any one or more of the image clearness (image sharpness) and a high contrast ratio can be observed. Note that image clearness (image sharpness) sometimes refers to one or both of the state where motion blur is inhibited and the state where black blurring is inhibited. When the off state current that can flow through the driving transistor included in the pixel circuit is extremely low, black display performed by the display apparatus can be a display with as little light leakage or the like as possible (completely black display).

One or both of the insulator 576 and the insulator 581 preferably functions as a barrier insulating film that inhibits diffusion of impurities such as water and hydrogen from above the transistor 500 into the transistor 500. Thus, for at least one of the insulator 576 and the insulator 581, it is preferable to use an insulating material having a function of inhibiting diffusion of impurities such as hydrogen atoms, hydrogen molecules, water molecules, nitrogen atoms, nitrogen molecules, nitrogen oxide molecules (e.g., N₂O, NO, or NO₂), or copper atoms (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

As one or both of the insulator 576 and the insulator 581, an insulator having a function of inhibiting diffusion of oxygen and impurities such as water and hydrogen is preferably used; for example, one or more selected from aluminum oxide, magnesium oxide, hafnium oxide, gallium oxide, indium-gallium-zinc oxide, silicon nitride, and silicon nitride oxide can be used.

An opening portion for forming a plug or a wiring is provided in the insulator 581, the insulator 576, and one of the source and drain electrodes of the transistor 500. A conductor 540 functioning as a plug or a wiring is formed in the opening portion.

The insulator 581 is preferably an insulator functioning as an interlayer film and a planarization film, for example.

The insulator 224 and the insulator 226 are formed above the insulator 581 and the conductor 540. Note that for the description of the insulator 224 and an insulator, a conductor, and a circuit element that are positioned above the insulator 224, description of the display apparatus 100 in FIG. 17 is referred to.

Note that FIG. 17 illustrates a display apparatus formed by bonding the semiconductor substrate provided with the light-emitting device 150, the pixel circuit, and the like and the semiconductor substrate provided with a driver circuit and the like; FIG. 19 illustrates a display apparatus in which the light-emitting device 150, the pixel circuit, and the like are formed over a semiconductor substrate provided with a driver circuit; however, the display apparatus for the electronic device of one embodiment of the present invention is not limited to the those in FIG. 17 and FIG. 19. The display apparatus for the electronic device of one embodiment of the present invention may have a structure where transistors are formed in only one layer, not a layered structure where transistors are stacked in two or more layers.

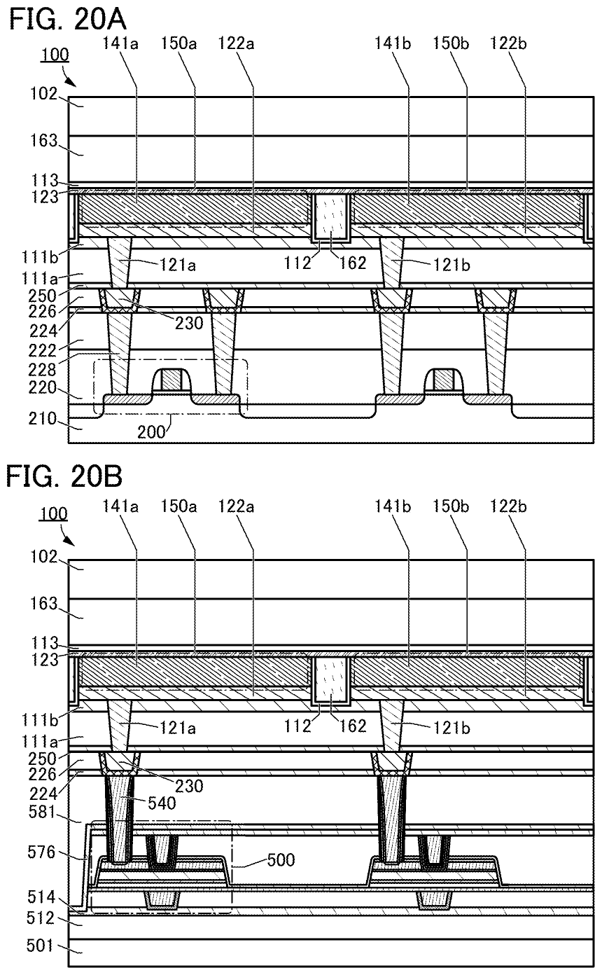

Specifically, for example, the display apparatus for the electronic device of one embodiment of the present invention may include a circuit including the transistor 200 formed over the substrate 210 and the light-emitting device 150 provided above the transistor 200, as in the display apparatus 100 illustrated in FIG. 20A. For another example, a structure may be employed where the insulator 512 is formed over a substrate 501, the transistor 500 is provided over the insulator 512, and the light-emitting device 150 is provided above the transistor 500, as in the display apparatus 100 illustrated in FIG. 20B. Note that as the substrate 501, a substrate that can be used as the substrate 310 can be used, for example, and in particular, a glass substrate is preferably used.

The display apparatus for the electronic device of one embodiment of the present invention may have a structure where transistors are provided in only one layer and the light-emitting device 150 is provided above the transistors, as in the display apparatus 100 illustrated in FIG. 20A or FIG. 20B. Although not illustrated, the display apparatus for the electronic device of one embodiment of the present invention may have a layered structure where transistors are formed in three or more layers.

### Sealing Structure Example of Display Apparatus

Next, a sealing structure of the light-emitting device 150 that can be employed for the display apparatus 100 in FIG. 17 is described.

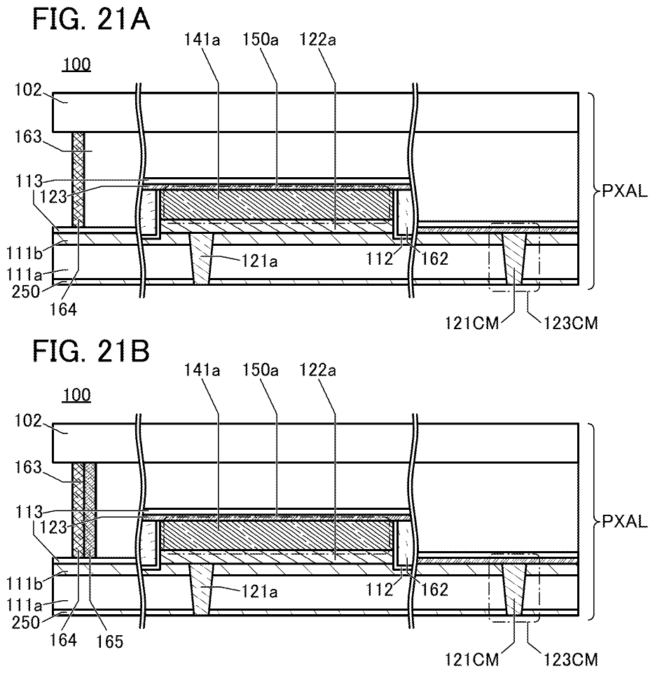

FIG. 21A is a cross-sectional view illustrating an example of a sealing structure that can be employed for the display apparatus 100 in FIG. 17. Specifically, FIG. 21A illustrates an end portion of the display apparatus 100 in FIG. 17 and components provided around the end portion. FIG. 21A selectively illustrates only part of the pixel layer PXAL of the display apparatus 100. Specifically, FIG. 21A illustrates the insulator 250, and insulators, conductors, and the light-emitting device 150a which are positioned above the insulator 250.

In a region 123CM illustrated in FIG. 21A, for example, an opening portion is provided. In the opening portion, a conductor 121CM is provided, for example. The conductor 123 is electrically connected to a wiring provided below the insulator 250 through the conductor 121CM. Thus, a potential (e.g., an anode potential and a cathode potential of the light-emitting device 150a or the like) can be supplied to the conductor 123 functioning as the common electrode. Note that one or both of a conductor included in the region 123CM and a conductor around the region 123CM is referred to as a connection electrode in some cases.

For the conductor 121CM, any of the materials usable for the conductor 121 can be used, for example.

In the display apparatus 100 in FIG. 21A, an adhesive layer 164 is provided at or around the end portion of the resin layer 163. Specifically, the display apparatus 100 is manufactured such that the insulator 113 and the substrate 102 are bonded to each other with the adhesive layer 164.

The adhesive layer 164 is preferably formed using, for example, a material inhibiting transmission of impurities such as air components and moisture. Using the material for the adhesive layer 164 can increase the reliability of the display apparatus 100.

A structure where the insulator 113 and the substrate 102 are bonded to each other with the resin layer 163 therebetween using the adhesive layer 164 is sometimes referred to as a solid sealing structure. In the case where the resin layer 163 in the solid sealing structure has a function of bonding the insulator 113 and the substrate 102 like the adhesive layer 164, the adhesive layer 164 is not necessarily provided.

By contrast, a structure where the insulator 113 and the substrate 102 are bonded to each other with an inert gas filled therebetween, instead of the resin layer 163, by using the adhesive layer 164 is sometimes referred to as a hollow sealing structure (not illustrated). Examples of an inert gas include nitrogen and argon.

In the sealing structure of the display apparatus 100 illustrated in FIG. 21A, two or more overlapping adhesive layers may be used. For example, as illustrated in FIG. 21B, an adhesive layer 165 may be further provided on the inner side of the adhesive layer 164 (between the adhesive layer 164 and the resin layer 163). Two or more overlapping adhesive layers can inhibit transmission of an impurity such as moisture more, further increasing the reliability of the display apparatus 100.

A desiccant may be mixed into the adhesive layer 165. In this case, the desiccant adsorbs moisture contained in the resin layer 163, insulators, conductors, and EL layers that are provided on the inner side of the adhesive layer 164 and the adhesive layer 165, increasing the reliability of the display apparatus 100.

Although the solid sealing structure is illustrated in the display apparatus 100 in FIG. 21B, a hollow sealing structure may be employed.

Furthermore, an inert liquid may be used instead of the resin layer 163 to fill the space in each of the sealing structures of the display apparatus 100 in FIG. 21A and FIG. 21B. An example of an inert liquid is a fluorine-based inert liquid.

### Variation Example of Display Apparatus

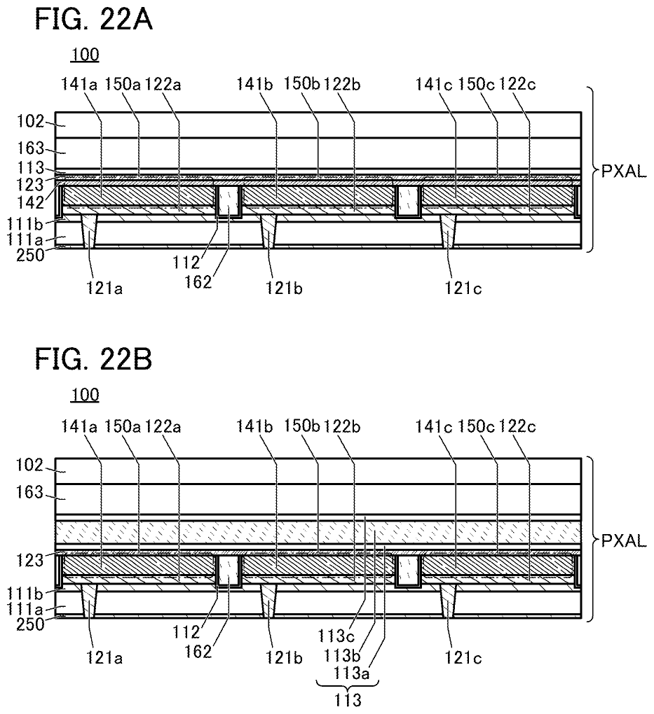

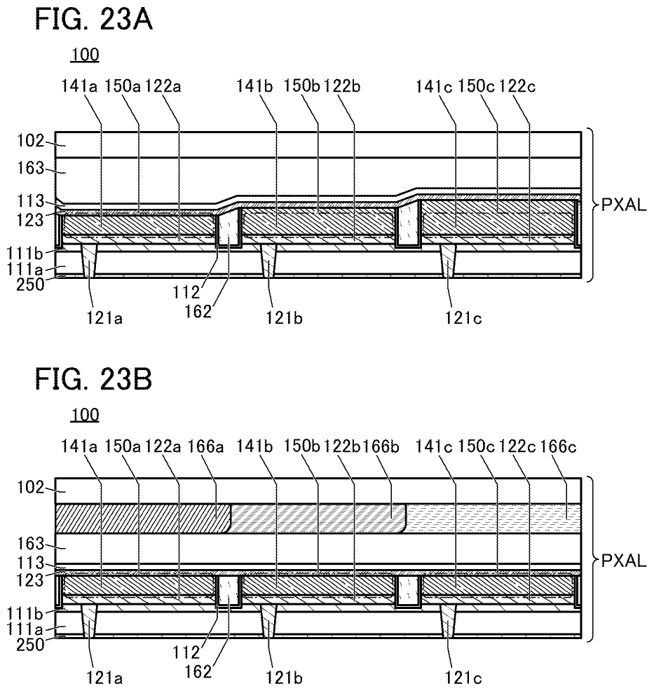

One embodiment of the present invention is not limited to the above-described structures, and the above-described structures can be changed as appropriate in accordance with circumstances. Variation examples of the display apparatus 100 in FIG. 17 are described with reference to FIG. 22A to FIG. 23B. Note that FIG. 22A to FIG. 23B selectively illustrate only part of the pixel layer PXAL of the display apparatus 100. Specifically, each of FIG. 22A to FIG. 23B illustrates the insulator 250, the insulator 111a, and insulators, conductors, and the light-emitting device 150a and the light-emitting device 150b that are positioned above the insulator 111a. In particular, each of FIG. 22A to FIG. 23B also illustrates the light-emitting device 150c, a conductor 121c, a conductor 122c, and an EL layer 141c.

Note that, for example, the color of light emitted by the EL layer 141c may be different from the colors of light emitted by the EL layer 141a and the EL layer 141b. The display apparatus 100 may have a structure where the number of colors of light emitted by the light-emitting device 150a to the light-emitting device 150c is two, for example. Alternatively, the display apparatus 100 may have a structure where the number of light-emitting devices 150 is increased so that the number of colors of light emitted by the light-emitting devices are four or more, for example (not illustrated).

The display apparatus 100 may have a structure where an EL layer 142 is formed over the EL layer 141a to the EL layer 141c, for example, as illustrated in FIG. 22A. Specifically, for example, in FIG. 18A, the EL layer 142 can include the layer 4420 when the EL layer 141a to the EL layer 141c each include the layer 4430 and the light-emitting layer 4411. In this case, the layer 4420 included in the EL layer 142 functions as a common layer shared by the light-emitting device 150a to the light-emitting device 150c. In a similar manner, for another example, in FIG. 18C, the EL layer 142 can include the layer 4420 when the EL layer 141a to the EL layer 141c each include the layer 4430, the light-emitting layer 4411, the light-emitting layer 4412, and the light-emitting layer 4413, in which case the layer 4420 included in the EL layer 142 functions as a common layer shared by the light-emitting device 150a to the light-emitting device 150c. As another example, in FIG. 18D, the EL layer 142 can include the layer 4420 of the light-emitting unit 4400b when the EL layer 141a to the EL layer 141c each include the layer 4430, the light-emitting layer 4412, and the layer 4420 that are included in the light-emitting unit 4400b, the intermediate layer 4440, and the layer 4430 and the light-emitting layer 4411 that are included in the light-emitting unit 4400a, in which case the layer 4420 of the light-emitting unit 4400a included in the EL layer 142 functions as a common layer shared by the light-emitting device 150a to the light-emitting devices 150c.

In the structure of the display apparatus 100, for example, the insulator 113 may have a stacked-layer structure of two or more layers, instead of a single layer. The insulator 113 may have a three-layer structure that includes an insulator made of an inorganic material as the first layer, an insulator made of an organic material as the second layer, and an insulator made of an inorganic material as the third layer. FIG. 22(B) illustrates a cross-sectional view of part of the display apparatus 100 in which the insulator 113 has a multilayer structure including an insulator 113a, an insulator 113b, and an insulator 113c; the insulator 113a is an insulator made of an inorganic material, the insulator 113b is an insulator made of an organic material, and the insulator 113c is an insulator made of an inorganic material.

In the structure of the display apparatus 100, for example, the EL layer 141a to the EL layer 141c may each have a microcavity structure. In the microcavity structure, for example, the conductor 122 as an upper electrode (common electrode) is formed using a light-transmitting and light-reflective conductive material, the conductor 121 as a lower electrode (pixel electrode) is formed using a light-reflective conductive material, and the distance between the bottom surface of the light-emitting layer and the top surface of the lower electrode, i.e., the thickness of the layer 4430 in FIG. 18A, is set to the thickness corresponding to the wavelength of the color of light emitted by the light-emitting layer included in the EL layer 141.

For example, light that is reflected back from the lower electrode (reflected light) considerably interferes with light that directly enters the upper electrode from the light-emitting layer (incident light); therefore, the optical path length between the lower electrode and the light-emitting layer is preferably adjusted to (2n−1)λ/4 (n is a natural number of 1 or more and λ is a wavelength of emitted light to be amplified). By adjusting the optical path length, the phases of the reflected light and the incident light each having the wavelength λ can be aligned with each other, and the light emitted from the light-emitting layer can be further amplified. In the case where the reflected light and the incident light have a wavelength other than the wavelength λ, their phases are not aligned with each other, resulting in attenuation without resonation.

In the above structure, the EL layer may include a plurality of light-emitting layers or a single light-emitting layer. Alternatively, the above-described tandem structure of a light-emitting device and a microcavity structure may be combined, for example.

With the microcavity structure, emission intensity with a specific wavelength in the front direction can be increased, whereby power consumption can be reduced. Particularly in the case of a device for XR such as VR and AR, light emitted from the light-emitting device in the front direction often enters the eyes of the user wearing the device; thus, a display apparatus of a device for XR suitable includes a microcavity structure. Note that in the case of a display apparatus which displays images with subpixels of four colors, red, yellow, green, and blue, the display apparatus can have favorable characteristics because a microcavity structure suitable for wavelengths of the corresponding color is employed in each subpixel, in addition to the effect of an improvement in luminance owing to yellow light emission.

As an example, FIG. 23A illustrates a cross-sectional view of part of the display apparatus 100 having a microcavity structure. In the case where the light-emitting device 150a includes a light-emitting layer emitting blue (B) light, the light-emitting device 150b includes a light-emitting layer emitting green (G) light, and the light-emitting device 150c includes a light-emitting layer emitting red (R) light, the thickness is preferably larger in the order of the EL layer 141a, the EL layer 141b and the EL layer 141c as illustrated in FIG. 23A. Specifically, the thicknesses of the layers 4430 included in the EL layer 141a, the EL layer 141b, and the EL layer 141c may be determined depending on the color of the light emitted by the corresponding light-emitting layer. In this case, the layer 4430 included in the EL layer 141a has the smallest thickness and the layer 4430 included in the EL layer 141c has the largest thickness.

In the structure of the display apparatus 100, for example, a coloring layer (color filter) or the like may be provided. As an example, FIG. 23B illustrates a structure where a coloring layer 166a, a coloring layer 166b, and a coloring layer 166c are included between the resin layer 163 and the substrate 102. Note that the coloring layer 166a to the coloring layer 166c can be formed on the substrate 102, for example. In the case where the light-emitting device 150a includes a light-emitting layer emitting blue (B) light, the light-emitting device 150b includes a light-emitting layer emitting green (G) light, and the light-emitting device 150c includes a light-emitting layer emitting red (R) light, the coloring layer 166a is a blue coloring layer, the coloring layer 166b is a green coloring layer, and the coloring layer 166c is a red coloring layer.

The display apparatus 100 illustrated in FIG. 23B can be manufactured in such a manner that the substrate 102 provided with the coloring layer 166a to the coloring layer 166c and the substrate 310 over which components up to the light-emitting device 150a to the light-emitting device 150c are formed are bonded to each other with the resin layer 163 therebetween. At this time, the bonding is preferably performed such that the light-emitting device 150a and the coloring layer 166a overlap with each other, the light-emitting device 150b and the coloring layer 166b overlap with each other, and the light-emitting device 150c and the coloring layer 166c overlap with each other. In the display apparatus 100 provided with the coloring layer 166a to the coloring layer 166c, for example, light emitted by the light-emitting device 150b is not extracted to above the substrate 102 through the coloring layer 166a or the coloring layer 166c, but extracted to above the substrate 102 through the coloring layer 166b. That is, light emitted from the light-emitting device 150 in an oblique direction (a direction at an elevation angle with a top surface of the substrate 102 used as a horizontal plane) can be blocked in the display apparatus 100; thus, the viewing angle dependence of the display apparatus 100 can be reduced, inhibiting the display quality of an image displayed by the display apparatus 100 from decreasing when the image is viewed from an oblique direction.

The coloring layer 166a to the coloring layer 166c formed on the substrate 102 may be covered with, for example, a resin which is referred to as an overcoat layer. Specifically, the resin layer 163, the overcoat layer, the coloring layer 166a to the coloring layer 166c, and the substrate 102 may be stacked in this order in the display apparatus 100 (not illustrated). Note that examples of the resin usable for the overcoat layer include a thermosetting material having a light-transmitting property and being based on an acrylic resin or an epoxy resin.

In the structure of the display apparatus 100, for example, a black matrix may be included in addition to the coloring layers (not illustrated). The black matrix provided between the coloring layer 166a and the coloring layer 166b, between the coloring layer 166b and the coloring layer 166c, and between the coloring layer 166c and the coloring layer 166a can block more light emitted from the light-emitting device 150 in an oblique direction (a direction at an elevation angle with the top surface of the substrate 102 used as a horizontal plane) in the display apparatus 100; thus, the display quality of an image displayed by the display apparatus 100 can be more prevented from decreasing when the image is viewed from an oblique direction.

In the case where the display apparatus includes coloring layers as illustrated in FIG. 23B or the like, the light-emitting device 150a to the light-emitting device 150c of the display apparatus may each be a light-emitting device emitting white light (not illustrated). The light-emitting device can have a single structure or a tandem structure, for example.

In the above-described structure of the display apparatus 100, the conductor 121a to the conductor 121c serve as the anodes and the conductor 122 serves as a cathode; however, the display apparatus 100 may have a structure where the conductor 121a to the conductor 121c serve as cathodes and the conductor 122 serves as an anode. In other words, in the above-described manufacturing process, the stacking order of the hole-injection layer, the hole-transport layer, the light-emitting layer, the electron-transport layer, and the electron-injection layer that are included in the EL layer 141a to the EL layer 141c and the EL layer 142 may be reversed.

### Structure Example of Insulator 162

Next, cross-sectional structures of a region including the insulator 162 and its periphery in the display apparatus 100 are described.

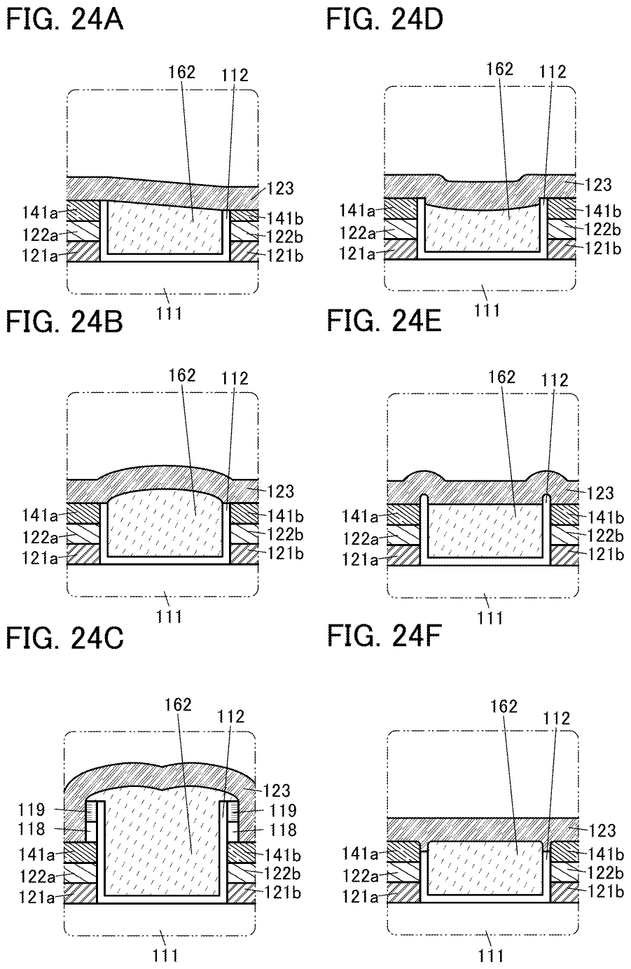

FIG. 24A illustrates an example where the EL layer 141a and the EL layer 141b have different thicknesses. The top surface level of the insulator 112 is equal to or substantially equal to the top surface level of the EL layer 141a on the EL layer 141a side, and equal to or substantially equal to the top surface level of the EL layer 141b on the EL layer 141b side. The top surface of the insulator 112 has a gentle slope such that the side closer to the EL layer 141a is higher and the side closer to the EL layer 141b is lower. In this manner, the top surfaces of the insulator 112 and the insulator 162 are preferably level with the top surface of an adjacent EL layer. Alternatively, the top surface levels of the insulators may be equal to the top surface level of any adjacent EL layer so that their top surfaces have a flat portion.

In FIG. 24B, the top surface of the insulator 162 includes a region that is at a higher level than the top surface of the EL layer 141a and the top surface of the EL layer 141b. Moreover, the top surface of the insulator 162 has a convex shape that is gently bulged toward the center.

In FIG. 24C, the top surface of the insulator 112 includes a region that is at a higher level than the top surface of the EL layer 141a and the top surface of the EL layer 141b. In a region including the insulator 162 and its vicinity, the display apparatus 100 includes a first region positioned over at least one of a sacrificial layer 118 and a sacrificial layer 119. The first region is at a higher level than the top surface of the EL layer 141a and the top surface of the EL layer 141b, and part of the insulator 162 is formed in the first region. In the region including the insulator 162 and its vicinity, the display apparatus 100 includes a second region positioned over at least one of the sacrificial layer 118 and the sacrificial layer 119. The second region is at a higher level than the top surface of the EL layer 141a and the top surface of the EL layer 141b, and part of the insulator 162 is formed in the second region.

In FIG. 24D, the top surface of the insulator 162 includes a region that is at a lower level than the top surface of the EL layer 141a and the top surface of the EL layer 141b. Moreover, the top surface of the insulator 162 has a concave shape that is gently recessed toward the center.

In FIG. 24E, the top surface of the insulator 112 includes a region that is at a higher level than the top surface of the EL layer 141a and the top surface of the EL layer 141b. That is, the insulator 112 protrudes from the formation surface of the EL layer 141 and forms a projecting portion.

In formation of the insulator 112, for example, when the insulator 112 is formed to be level with or substantially level with the sacrificial layer, a shape such that the insulator 112 protrudes is sometimes formed as illustrated in FIG. 24E.

In FIG. 24F, the top surface of the insulator 112 includes a region that is at a lower level than the top surface of EL layer 141a and the top surface of the EL layer 141b. That is, the insulator 112 forms a depressed portion on the formation surface of the EL layer 141.

As described above, the insulator 112 and the insulator 162 can have a variety of shapes.

### Structure Example of Pixel Circuit

Here, structure examples of a pixel circuit that can be included in the pixel layer PXAL are described.

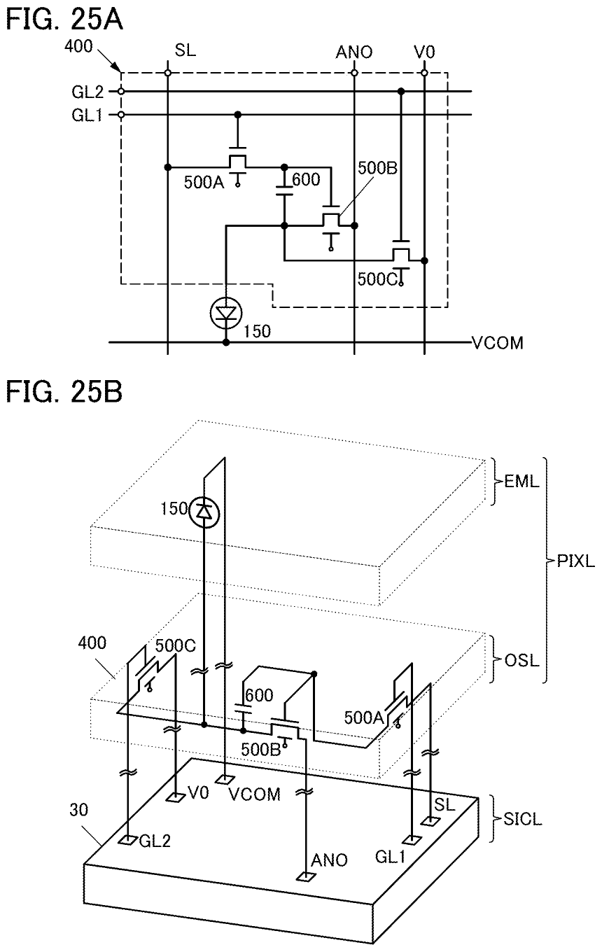

FIG. 25A and FIG. 25B illustrate a structure example of a pixel circuit that can be included in the pixel layer PXAL and the light-emitting device 150 connected to the pixel circuit. FIG. 25A is a diagram illustrating connection of circuit elements included in a pixel circuit 400 included in the pixel layer PXAL, and FIG. 25B is a diagram schematically illustrating the positional relation of the circuit layer SICL including a driver circuit 30 and the like, a layer OSL including a plurality of transistors of the pixel circuit, and a layer EML including the light-emitting device 150. Note that the pixel layer PXAL of the display apparatus 100 illustrated in FIG. 25B includes the layer OSL and the layer EML, for example. A transistor 500A, a transistor 500B, and a transistor 500C included in the layer OSL illustrated in FIG. 25B each correspond to the transistor 200 in FIG. 17. The light-emitting device 150 included in the layer EML illustrated in FIG. 25B corresponds to the light-emitting device 150a or the light-emitting device 150b in FIG. 17.

The pixel circuit 400 illustrated as an example in FIG. 25A and FIG. 25B includes the transistor 500A, the transistor 500B, the transistor 500C, and a capacitor 600. The transistor 500A, the transistor 500B, and the transistor 500C can be, for example, transistors usable as the transistor 200 described above as an example. That is, the transistor 500A, the transistor 500B, and the transistor 500C can be Si transistors. Alternatively, the transistor 500A, the transistor 500B, and the transistor 500C can be, for example, transistors usable as the transistor 500 described above as example. That is, the transistor 500A, the transistor 500B, and the transistor 500C can be OS transistors. In particular, in the case where the transistor 500A, the transistor 500B, and the transistor 500C are OS transistors, each of the transistor 500A, the transistor 500B, and the transistor 500C preferably includes a back gate electrode, in which case the structure where the back gate electrode is supplied with the same signals as those supplied to the gate electrode or the structure where the back gate electrode is supplied with signals different from those supplied to the gate electrode can be used. Although each of the transistor 500A, the transistor 500B, and the transistor 500C illustrated in FIG. 25A and FIG. 25B includes a back gate electrode, each of the transistor 500A, the transistor 500B, and the transistor 500C does not necessarily include a back gate electrode.

The transistor 500B includes a gate electrode electrically connected to the transistor 500A, a first electrode electrically connected to the light-emitting device 150, and a second electrode electrically connected to a wiring ANO. The wiring ANO supplies a potential for supplying current to the light-emitting device 150.

The transistor 500A includes a first terminal electrically connected to the gate electrode of the transistor 500B, a second terminal electrically connected to a wiring SL functioning as a source line, and the gate electrode having a function of controlling the conducting state or non-conducting state on the basis of the potential of a wiring GL1 functioning as a gate line.

The transistor 500C includes a first terminal electrically connected to a wiring V0, a second terminal electrically connected to the light-emitting device 150, and the gate electrode having a function of controlling the conducting state or non-conducting state on the basis of the potential of a wiring GL2 functioning as a gate line. The wiring V0 is a wiring for supplying a reference potential and a wiring for outputting current flowing through the pixel circuit 400 to the driver circuit 30.

The capacitor 600 includes a conductive film electrically connected to the gate electrode of the transistor 500B and a conductive film electrically connected to a second electrode of the transistor 500C.

The light-emitting device 150 includes a first electrode electrically connected to the first electrode of the transistor 500B and a second electrode electrically connected to a wiring VCOM. The wiring VCOM is a wiring for supplying a potential for supplying current to the light-emitting device 150.

Accordingly, the intensity of light emitted by the light-emitting device 150 can be controlled in accordance with an image signal supplied to the gate electrode of the transistor 500B. Furthermore, variations in the gate-source voltage of the transistor 500B can be inhibited by the reference potential of the wiring V0 supplied through the transistor 500C.

A current amount that can be used for setting pixel parameters can be output from the wiring V0. Specifically, the wiring V0 can function as a monitor line for outputting current flowing through the transistor 500B or current flowing through the light-emitting device 150 to the outside. Current output to the wiring V0 is converted into voltage by a source follower circuit or the like and output to the outside. Alternatively, current output to the wiring V0 can be converted into a digital signal by an A-D converter or the like and output to the arithmetic circuit 10 or the like described in the above embodiment.

Note that in the structure illustrated as an example in FIG. 25B, the wirings electrically connecting the pixel circuit 400 and the driver circuit 30 can be shortened, so that wiring resistance of the wirings can be reduced. Thus, data writing can be performed at high speed, leading to high-speed operation of the display apparatus 100. Therefore, even when the number of pixel circuits 400 included in the display apparatus 100 is large, a sufficiently long frame period can be ensured and thus the pixel density of the display apparatus 100 can be increased. In addition, the increased pixel density of the display apparatus 100 can increase the resolution of an image displayed by the display apparatus 100. For example, the pixel density of the display apparatus 100 can be higher than or equal to 1000 ppi, higher than or equal to 5000 ppi, or higher than or equal to 7000 ppi. Thus, the display apparatus 100 can be, for example, a display apparatus for AR or VR and can be suitably used in an electronic device with a short distance between a display portion and the user, such as an HMD.

Although FIG. 25A and FIG. 25B illustrate, as an example, the pixel circuit 400 including three transistors in total, the pixel circuit of the electronic device of one embodiment of the present invention is not limited thereto. Structure examples of a pixel circuit which can be used for the pixel circuit 400 will be described below.

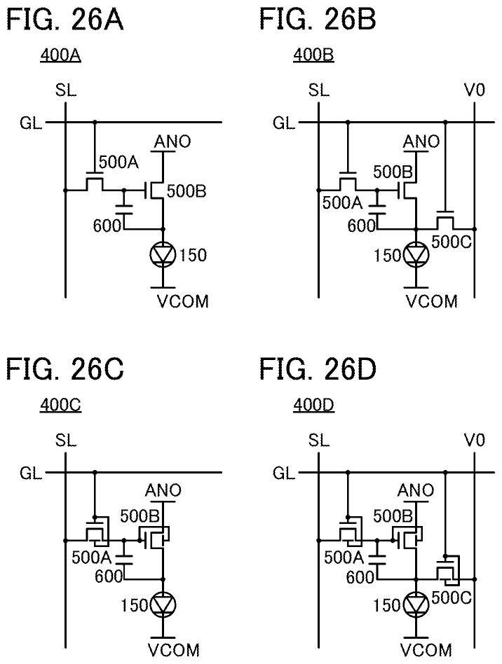

A pixel circuit 400A illustrated in FIG. 26A includes the transistor 500A, the transistor 500B, and the capacitor 600. FIG. 26A illustrates the light-emitting device 150 connected to the pixel circuit 400A. The wiring SL, the wiring GL, the wiring ANO, and the wiring VCOM are electrically connected to the pixel circuit 400A.

A gate of the transistor 500A is electrically connected to the wiring GL, one of a source and a drain of the transistor 500A is electrically connected to the wiring SL, and the other of the source and the drain of the transistor 500A is electrically connected to a gate of the transistor 500B and one electrode of the capacitor 600. One of a source and a drain of the transistor 500B is electrically connected to the wiring ANO and the other of the source and the drain of the transistor 500B is electrically connected to an anode of the light-emitting device 150. The other electrode of the capacitor 600 is electrically connected to the anode of the light-emitting device 150. A cathode of the light-emitting device 150 is electrically connected to the wiring VCOM.

A pixel circuit 400B illustrated in FIG. 26B has a structure where the transistor 500C is added to the pixel circuit 400A. In addition, the wiring V0 is electrically connected to the pixel circuit 400B.

A pixel circuit 400C illustrated in FIG. 26C is an example of the case where a transistor in which a gate and a back gate are electrically connected to each other is used as each of the transistor 500A and the transistor 500B of the pixel circuit 400A. A pixel circuit 400D illustrated in FIG. 26D is an example of the case where such transistors are used in the pixel circuit 400B. Thus, current that can flow through the transistor can be increased. Note that although a transistor in which a pair of gates are electrically connected to each other is used as all the transistors here, one embodiment of the present invention is not limited thereto. A transistor that includes a pair of gates electrically connected to different wirings may be used. For example, when a transistor in which one of the gates is electrically connected to the source is used, the reliability can be increased.

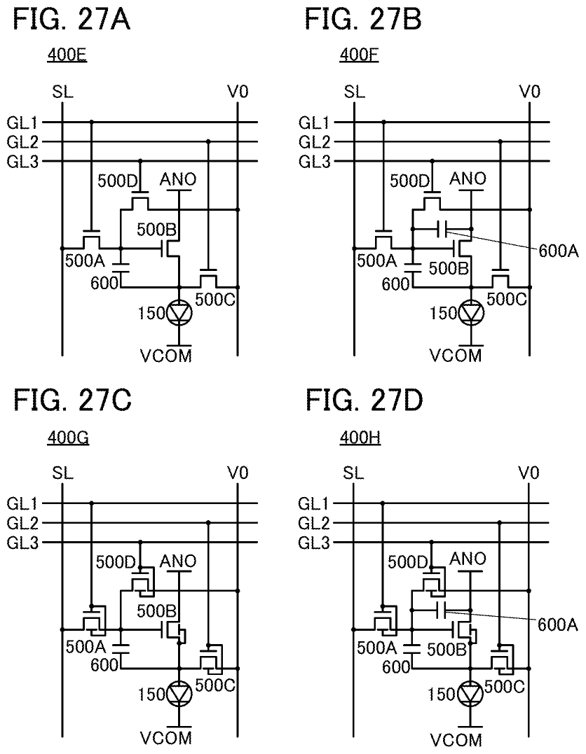

A pixel circuit 400E illustrated in FIG. 27A has a structure where a transistor 500D is added to the pixel circuit 400B. Three wirings (the wiring GL1, the wiring GL2, and a wiring GL3) functioning as gate lines are electrically connected to the pixel circuit 400E.

A gate of the transistor 500D is electrically connected to the wiring GL3, one of a source and a drain of the transistor 500D is electrically connected to the gate of the transistor 500B, and the other of the source and the drain of the transistor 500D is electrically connected to the wiring V0. The gate of the transistor 500A is electrically connected to the wiring GL1, and the gate of the transistor 500C is electrically connected to the wiring GL2.

When the transistor 500C and the transistor 500D are brought into a conducting state at the same time, the source and the gate of the transistor 500B have the same potential, so that the transistor 500B can be brought into a non-conducting state. Thus, current flowing through the light-emitting device 150 can be blocked forcibly. Such a pixel circuit is suitable for the case of using a display method in which a display period and a non-lighting period are alternately provided.

A pixel circuit 400F illustrated in FIG. 27B is an example of the case where a capacitor 600A is added to the pixel circuit 400E. The capacitor 600A functions as a storage capacitor.

A pixel circuit 400G illustrated in FIG. 27C and a pixel circuit 400H illustrated in FIG. 27D are respectively examples of the cases where transistors each including a gate and a back gate that are electrically connected to each other are used in the pixel circuit 400E and the pixel circuit 400F. A transistor in which agate and aback gate are electrically connected to each other is used as each of the transistor 500A, the transistor 500C, and the transistor 500D, and a transistor in which a gate is electrically connected to a source is used as the transistor 500B.

### <Schematic Plan View and Schematic Cross-Sectional View of Light-Emitting Device>

FIG. 28A is a schematic plan view illustrating a structure example of the case where light-emitting devices and a light-receiving device are arranged in one pixel in the display apparatus 100 of one embodiment of the present invention. The display apparatus 100 includes a plurality of light-emitting devices 150R that emit red light, a plurality of light-emitting devices 150G that emit green light, a plurality of light-emitting devices 150B that emit blue light, and a plurality of light-receiving devices 160. In FIG. 28A, light-emitting regions of the light-emitting devices 150 are denoted by R, G, and B to easily differentiate the light-emitting devices 150. In addition, light-receiving regions of the light-receiving devices 160 are denoted by PD.

The light-emitting devices 150R, the light-emitting devices 150G, the light-emitting devices 150B, and the light-receiving devices 160 are each arranged in a matrix. FIG. 28A illustrates an example where the light-emitting devices 150R, the light-emitting devices 150G, and the light-emitting devices 150B are arranged in the X direction and the light-receiving devices 160 are arranged thereunder. FIG. 28A also illustrates a structure example where the light-emitting devices 150 that emit light of the same color are arranged in the Y direction intersecting the X direction. In the display apparatus 100 illustrated in FIG. 28A, a pixel 80 can be composed of a subpixel including the light-emitting device 150R, a subpixel including the light-emitting device 150G, and a subpixel including the light-emitting device 150B, which are arranged in the X direction, and a subpixel including the light-receiving device 160 provided under the subpixels, for example.

As each of the light-emitting device 150R, the light-emitting device 150G, and the light-emitting device 150B, an EL element such as an OLED (Organic Light Emitting Diode) or a QLED (Quantum-dot Light Emitting Diode) is preferably used. Examples of a light-emitting substance contained in the EL elements include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescent (TADF) material). Note that as a TADF material, a material in which a singlet excited state and a triplet excited state are in a thermal equilibrium state may be used. Since such a TADF material enables a short emission lifetime (excitation lifetime), an efficiency decrease of a light-emitting element in a high-luminance region can be inhibited.

For example, a pn or pin photodiode can be used as the light-receiving device 160. The light-receiving device 160 functions as a photoelectric conversion element that detects light incident on the light-receiving device 160 and generates charge. The amount of generated charge depends on the amount of incident light.

It is particularly preferable to use an organic photodiode including a layer containing an organic compound, as the light-receiving device 160. An organic photodiode, which is easily made thin, lightweight, and large in area and has a high degree of freedom for shape and design, can be used in a variety of display apparatuses.

In an electronic device of one embodiment of the present invention, an organic EL element is used as the light-emitting device 150, and an organic photodiode is used as the light-receiving device 160. The organic EL elements and the organic photodiodes can be formed over one substrate. Thus, the organic photodiodes can be incorporated in a display apparatus including the organic EL elements. A photolithography method is preferably employed to separate the organic EL elements and the organic photodiodes from each other. This can reduce the interval between the light-emitting devices, between the organic photodiodes, and between the light-emitting device and the organic photodiode, achieving a display apparatus having a higher aperture ratio than that formed using, for example, a shadow mask such as a metal mask.

FIG. 28A illustrates the conductor 123 functioning as a common electrode and the conductor 121CM functioning as a connection electrode. Here, the conductor 121CM is electrically connected to the conductor 123. The conductor 121CM is provided outside a display portion where the light-emitting devices 150 and the light-receiving devices 160 are arranged. In FIG. 28A, the conductor 123 including a region overlapping with the light-emitting devices 150, the light-receiving devices 160, and the conductor 121CM is shown by dashed lines.

The conductor 121CM can be provided along the outer periphery of the display portion. For example, the conductor 121CM may be provided along one side of the outer periphery of the display portion or two or more sides of the outer periphery of the display portion. That is, the top surface shape of the conductor 121CM can be a band shape, an L shape, a square bracket shape, a quadrangle, or the like in the case where the top surface shape of the display portion is a rectangle.

FIG. 28B is a schematic plan view illustrating a structure example of the display apparatus 100 and is a variation example of the display apparatus 100 illustrated in FIG. 28A. The display apparatus 100 illustrated in FIG. 28B differs from the display apparatus 100 illustrated in FIG. 28A in that light-emitting devices 150IR that emit infrared light are included. The light-emitting devices 150IR can emit near-infrared light (light with a wavelength greater than or equal to 750 nm and less than or equal to 1300 nm), for example.

In the example illustrated in FIG. 28B, the light-emitting devices 150IR as well as the light-emitting device 150R, the light-emitting device 150G, and the light-emitting device 150B are arranged in the X direction, and the light-receiving devices 160 are arranged thereunder. The light-receiving device 160 has a function of detecting infrared light.

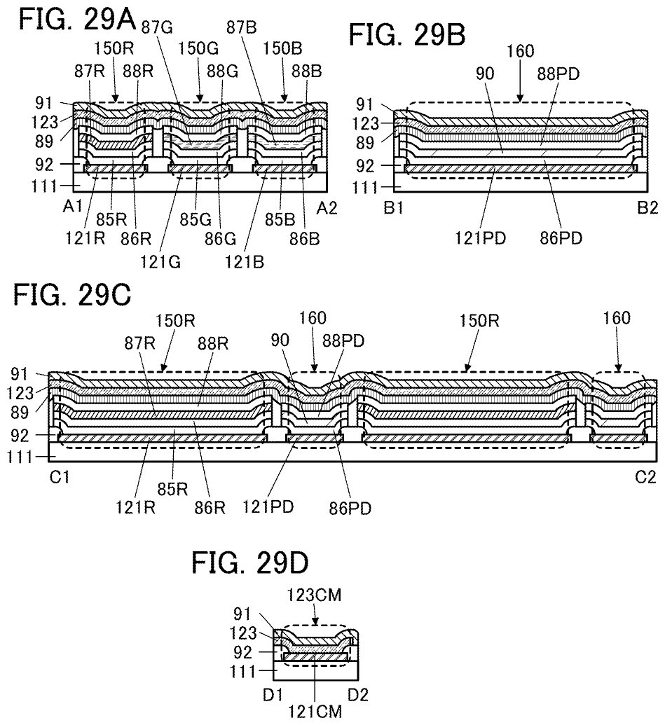

FIG. 29A is a cross-sectional view taken along dashed-dotted line A1-A2 in FIG. 28A, and FIG. 29B is a cross-sectional view taken along dashed-dotted line B1-B2 in FIG. 28A. FIG. 29C is a cross-sectional view taken along dashed-dotted line C1-C2 in FIG. 28A, and FIG. 29D is a cross-sectional view taken along dashed-dotted line D1-D2 in FIG. 28A. The light-emitting devices 150R, the light-emitting devices 150G, the light-emitting devices 150B, and the light-receiving devices 160 are provided over the insulator 111. In the case where the display apparatus 100 includes the light-emitting devices 150IR, the light-emitting devices 150IR are provided over the insulator 111.

In the case where the expression “B over A” or “B under A” is used in this specification and the like, for example, A and B do not always need to include a region where they are in contact with each other.

FIG. 29A illustrates a cross-sectional structure example of the light-emitting device 150R, the light-emitting device 150G, and the light-emitting device 150B in FIG. 28A. FIG. 29B illustrates a cross-sectional structure example of the light-receiving device 160 in FIG. 28A.

The light-emitting device 150R includes a conductor 121R functioning as a pixel electrode, a hole-injection layer 85R, a hole-transport layer 86R, a light-emitting layer 87R, an electron-transport layer 88R, a common layer 89, and the conductor 123. The light-emitting device 150G includes a conductor 121G functioning as a pixel electrode, a hole-injection layer 85G, a hole-transport layer 86G, a light-emitting layer 87G, an electron-transport layer 88G, the common layer 89, and the conductor 123. The light-emitting device 150B includes a conductor 121B functioning as a pixel electrode, a hole-injection layer 85B, a hole-transport layer 86B, a light-emitting layer 87B, an electron-transport layer 88B, the common layer 89, and the conductor 123. The light-receiving device 160 includes a conductor 121PD functioning as a pixel electrode, a hole-transport layer 86PD, a light-receiving layer 90, an electron-transport layer 88PD, the common layer 89, and the conductor 123.

As the conductor 121R, the conductor 121G, and the conductor 121B, for example, the conductor 121a, the conductor 121b, and the conductor 121c illustrated in FIG. 22A to FIG. 23B can be used.

The common layer 89 has a function of an electron-injection layer in the light-emitting device 150. Meanwhile, the common layer 89 has a function of an electron-transport layer in the light-receiving device 160. Therefore, the light-receiving device 160 does not necessarily include the electron-transport layer 88PD.

The hole-injection layer 85, the hole-transport layer 86, the electron-transport layer 88, and the common layer 89 can also be referred to as functional layers.

The conductor 121, the hole-injection layer 85, the hole-transport layer 86, the light-emitting layer 87, and the electron-transport layer 88 can each be separately provided for each element. The common layer 89 and the conductor 123 are provided to be shared by the light-emitting device 150R, the light-emitting device 150G, the light-emitting device 150B, and the light-receiving device 160.

The light-emitting device 150 and the light-receiving device 160 may each include a hole-blocking layer and an electron-blocking layer other than the layers illustrated in FIG. 29A. The light-emitting device 150 and the light-receiving device 160 may each include a layer containing, for example, a substance with a bipolar property (a substance with a high electron-transport property and a high hole-transport property).

An insulating layer 92 is provided to cover an end portion of the conductor 121R, an end portion of the conductor 121G, an end portion of the conductor 121B, and an end portion of the conductor 121PD. An end portion of the insulating layer 92 is preferably tapered. The insulating layer 92 is not necessarily provided when not needed.

For example, the hole-injection layer 85R, the hole-injection layer 85G, the hole-injection layer 85B, and the hole-transport layer 86PD each include a region in contact with the top surface of the conductor 121 and a region in contact with the surface of the insulating layer 92. In addition, an end portion of the hole-injection layer 85R, an end portion of the hole-injection layer 85G, an end portion of the hole-injection layer 85B, and an end portion of the hole-transport layer 86PD are positioned over the insulating layer 92.

A gap is provided between the common layer 89 and the insulating layer 92 described later. This can inhibit contact between the common layer 89 and each of a side surface of the light-emitting layer 87, a side surface of the light-receiving layer 90, a side surface of the hole-transport layer 86, and a side surface of the hole-injection layer 85. Thus, short-circuit in the light-emitting device 150 and short-circuit in the light-receiving device 160 can be inhibited.

The shorter the distance between the light-emitting layers 87 is, the more easily the gap is formed, for example. For example, when the distance is less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm, the gap can be favorably formed.

A protective layer 91 is provided over the conductor 123. The protective layer 91 has a function of preventing diffusion of impurities such as water into each light-emitting element from the above.

The protective layer 91 can have, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide may be used for the protective layer 91.

A stack of an inorganic insulating film and an organic insulating film can be used as the protective layer 91. For example, a structure where an organic insulating film is interposed between a pair of inorganic insulating films is preferable. Furthermore, the organic insulating film preferably functions as a planarization film. With this, the top surface of the organic insulating film can be flat, and accordingly, coverage with the inorganic insulating film thereover is improved, leading to an improvement in barrier property. The top surface of the protective layer 91 is flat, which is preferable because the influence of an uneven shape due to a structure below the protective layer 91 can be reduced in the case where a structure (e.g., a color filter, an electrode of a touch sensor, or a lens array) is provided above the protective layer 91.

FIG. 29A illustrates the light-emitting device 150 in which the conductor 121, the hole-injection layer 85, the hole-transport layer 86, the light-emitting layer 87, the electron-transport layer 88, the common layer 89 (electron-injection layer), and the conductor 123 are provided in this order from the bottom, and the light-receiving device 160 in which the conductor 121PD, the hole-transport layer 86PD, the light-receiving layer 90, the electron-transport layer 88PD, the common layer 89, and the conductor 123 are provided in this order from the bottom; however, the structure of the light-emitting device or the light-receiving device of an electronic device of one embodiment of the present invention is not limited to this example. For example, the light-emitting device 150 may include a conductor functioning as a pixel electrode, an electron-injection layer, an electron-transport layer, a light-emitting layer, a hole-transport layer, a hole-injection layer, and a conductor functioning as a common electrode in this order from the bottom, and the light-receiving device 160 may include a conductor functioning as a pixel electrode, an electron-transport layer, a light-receiving layer, a hole-transport layer, and a conductor functioning as a common electrode in this order from the bottom. In this case, the hole-injection layer included in the light-emitting device 150 can be a common layer, and the common layer can be provided between the hole-transport layer included in the light-receiving device 160 and the common electrode. In addition, the electron-injection layers can be separated between the light-emitting devices 150.

### <Pixel Layout>

Here, a pixel layout which is different from that illustrated in FIG. 28 is described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

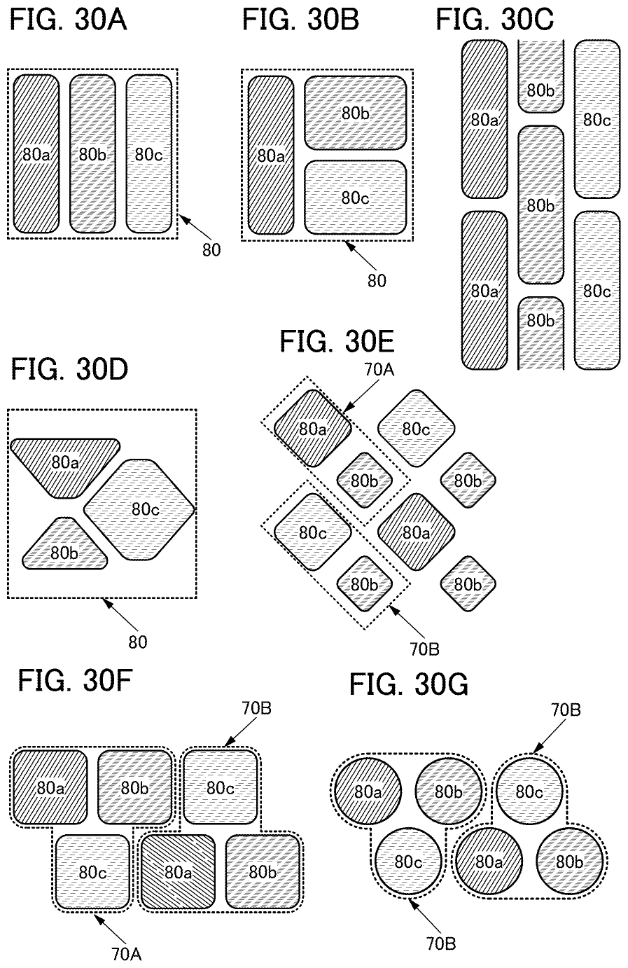

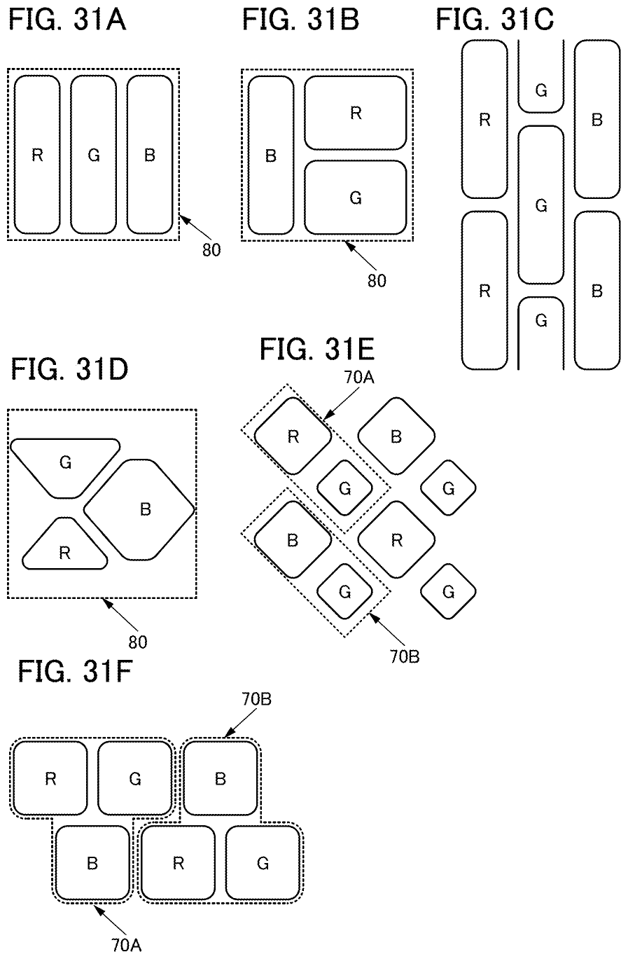

The pixel 80 illustrated in FIG. 30A employs stripe arrangement. The pixel 80 illustrated in FIG. 30A is composed of three subpixels: a subpixel 80a, a subpixel 80b, and a subpixel 80c. For example, as illustrated in FIG. 31A, the subpixel 80a may be a red subpixel R, the subpixel 80b may be a green subpixel G, and the subpixel 80c may be a blue subpixel B.

The pixel 80 illustrated in FIG. 30B employs S-stripe arrangement. The pixel 80 illustrated in FIG. 30B is composed of three subpixels: the subpixel 80a, the subpixel 80b, and the subpixel 80c. For example, as illustrated in FIG. 31B, the subpixel 80a may be the blue subpixel B, the subpixel 80b may be the red subpixel R, and the subpixel 80c may be the green subpixel G.

FIG. 30C illustrates an example where subpixels of different colors are arranged in a zigzag manner. Specifically, the positions of the top sides of two subpixels arranged in the column direction (e.g., the subpixel 80a and the subpixel 80b or the subpixel 80b and the subpixel 80c) are not aligned in the plan view. For example, as illustrated in FIG. 31C, the subpixel 80a may be the red subpixel R, the subpixel 80b may be the green subpixel G, and the subpixel 80c may be the blue subpixel B.

The pixel 80 illustrated in FIG. 30D includes the subpixel 80a whose top surface has a rough trapezoidal shape with rounded corners, the subpixel 80b whose top surface has a rough triangle shape with rounded corners, and the subpixel 80c whose top surface has a rough tetragonal or rough hexagonal shape with rounded corners. The subpixel 80a has a larger light-emitting area than the subpixel 80b. In this manner, the shapes and sizes of the subpixels can be determined independently. For example, the size of a subpixel including a light-emitting device with higher reliability can be smaller. For example, as illustrated in FIG. 31D, the subpixel 80a may be the green subpixel G, the subpixel 80b may be the red subpixel R, and the subpixel 80c may be the blue subpixel B.

A pixel 70A and a pixel 70B illustrated in FIG. 30E employ pentile arrangement. FIG. 30E illustrates an example where the pixels 70A including the subpixel 80a and the subpixel 80b and the pixels 70B including the subpixel 80b and the subpixel 80c are alternately arranged. For example, as illustrated in FIG. 31E, the subpixel 80a may be the red subpixel R, the subpixel 80b may be the green subpixel G, and the subpixel 80c may be the blue subpixel B.

The pixel 70A and the pixel 70B illustrated in FIG. 30F and FIG. 30G employ delta arrangement. The pixel 70A includes two subpixels (the subpixel 80a and the subpixel 80b) in the upper row (first row) and one subpixel (the subpixel 80c) in the lower row (second row). The pixel 70B includes one subpixel (the subpixel 80c) in the upper row (first row) and two subpixels (the subpixel 80a and the subpixel 80b) in the lower row (second row). For example, as illustrated in FIG. 31F, the subpixel 80a may be the red subpixel R, the subpixel 80b may be the green subpixel G, and the subpixel 80c may be the blue subpixel B.

FIG. 30F illustrates an example where the top surface of each subpixel has a rough tetragonal shape with rounded corners, and FIG. 30G illustrates an example where the top surface of each subpixel has a circular shape.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel can have a polygonal shape with rounded corners, an elliptical shape, or a circular shape in some cases.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an optical proximity correction (OPC) technique) may be used. Specifically, with the OPC technique, a pattern for correction is added to a corner portion or the like of a figure on a mask pattern.

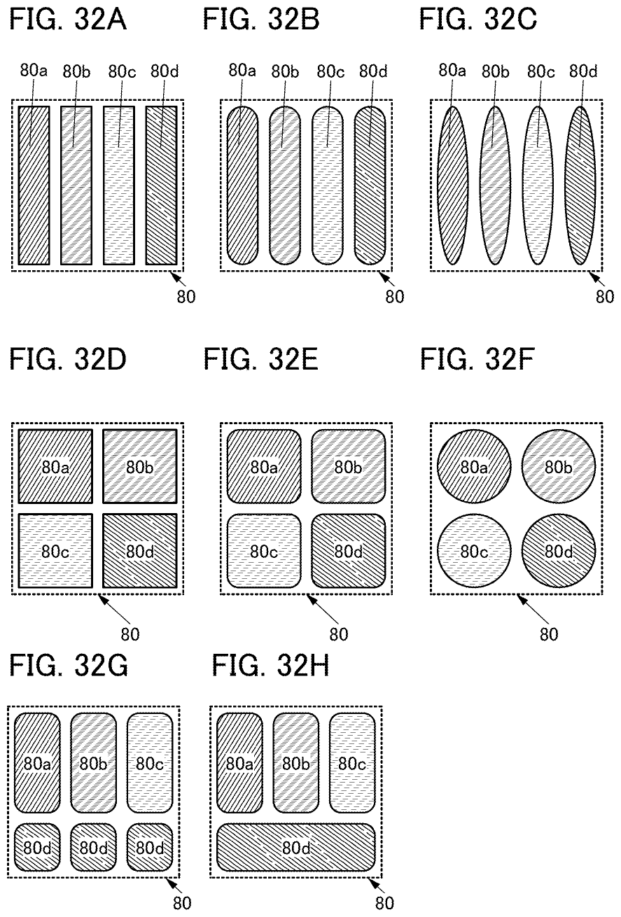

The pixels 80 illustrated in FIG. 32A to FIG. 32C employ stripe arrangement.

FIG. 32A illustrates an example where each subpixel has a rectangular top surface shape, FIG. 32B illustrates an example where each subpixel has a top surface shape formed by combining two half circles and a rectangle, and FIG. 32C illustrates an example where each subpixel has an elliptical top surface shape.

The pixels 80 illustrated in FIG. 32D to FIG. 32F employ matrix arrangement.

FIG. 32D illustrates an example where each subpixel has a square top surface shape, FIG. 32E illustrates an example where each subpixel has a substantially square top surface shape with rounded corners, and FIG. 32F illustrates an example where each subpixel has a circular top surface shape.

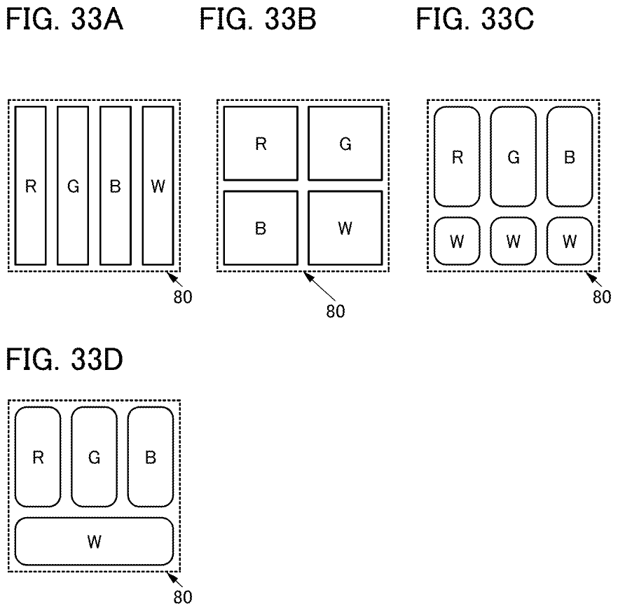

The pixels 80 illustrated in FIG. 32A to FIG. 32F are each composed of four subpixels: the subpixel 80a, the subpixel 80b, the subpixel 80c, and a subpixel 80d. The subpixel 80a, the subpixel 80b, the subpixel 80c, and the subpixel 80d emit light of different colors. For example, the subpixel 80a, the subpixel 80b, the subpixel 80c, and the subpixel 80d can be red, green, blue, and white subpixels, respectively, as illustrated in FIG. 33A and FIG. 33B. Alternatively, the subpixel 80a, the subpixel 80b, the subpixel 80c, and the subpixel 80d can be red, green, blue, and infrared-light subpixels, respectively.

The subpixel 80d includes a light-emitting device. The light-emitting device includes, for example, a pixel electrode, an EL layer, and the conductor 121CM functioning as a common electrode. For the pixel electrode, a material similar to that of the conductor 121a, the conductor 121b, the conductor 121c, the conductor 122a, the conductor 122b, or the conductor 122c can be used. For the EL layer, a material similar to that of the EL layer 141a, the EL layer 141b, or the EL layer 141c can be used, for example.

FIG. 32G illustrates an example where one pixel 80 is composed of two rows and three columns. The pixel 80 includes three subpixels (the subpixel 80a, the subpixel 80b, and the subpixel 80c) in the upper row (first row) and three subpixels 80d in the lower row (second row). In other words, the pixel 80 includes the subpixel 80a and the subpixel 80d in the left column (first column), the subpixel 80b and another subpixel 80d in the center column (second column), and the subpixel 80c and another subpixel 80d in the right column (third column). Matching the positions of the subpixels in the upper row and the lower row as illustrated in FIG. 32G enables dust and the like that would be produced in the manufacturing process to be removed efficiently. Thus, a display apparatus with high display quality can be provided.

FIG. 32H illustrates an example where one pixel 80 is composed of two rows and three columns. The pixel 80 includes three subpixels (the subpixel 80a, the subpixel 80b, and the subpixel 80c) in the upper row (first row) and one subpixel (the subpixel 80d) in the lower row (second row). In other words, the pixel 80 includes the subpixel 80a in the left column (first column), the subpixel 80b in the center column (second column), the subpixel 80c in the right column (third column), and the subpixel 80d across these three columns.

In the pixel 80 illustrated in each of FIG. 32G and FIG. 32H, for example, the subpixel 80a can be the red subpixel R, the subpixel 80b can be the green subpixel G, the subpixel 80c can be the blue subpixel B, and the subpixel 80d can be a white subpixel W, as illustrated in FIG. 33C and FIG. 33D.

The display apparatus of one embodiment of the present invention may include a light-receiving device in the pixel.

Three of the four subpixels included in the pixel 80 in FIG. 32G may include a light-emitting device and the other one may include a light-receiving device.

For example, a pn or pin photodiode can be used as the light-receiving device. The light-receiving devices function as photoelectric conversion devices (also referred to as photoelectric conversion elements) that detect light entering the light-receiving devices and generate charge. The amount of charge generated from the light-receiving devices depends on the amount of light entering the light-receiving devices.

It is particularly preferable to use an organic photodiode including a layer containing an organic compound, as the light-receiving device. An organic photodiode, which is easily made thin, lightweight, and large in area and has a high degree of freedom for shape and design, can be used in a variety of display apparatuses.

In one embodiment of the present invention, organic EL devices are used as the light-emitting devices, and organic photodiodes are used as the light-receiving devices. The organic EL device and the organic photodiode can be formed over the same substrate. Thus, the organic photodiode can be incorporated in the display apparatus including the organic EL device.

The light-receiving device includes at least an active layer that functions as a photoelectric conversion layer between a pair of electrodes. In this specification and the like, one of the pair of electrodes may be referred to as a pixel electrode and the other may be referred to as a common electrode.

For example, the subpixel 80a, the subpixel 80b, and the subpixel 80c may be subpixels for three colors of R, G, and B, and the subpixel 80d may be a subpixel including the light-receiving device. In this case, the fourth layer includes at least an active layer.

One of the pair of electrodes of the light-receiving device functions as an anode, and the other electrode functions as a cathode. Hereinafter, the case where the pixel electrode functions as an anode and the common electrode functions as a cathode is described as an example. When the light-receiving device is driven by application of reverse bias between the pixel electrode and the common electrode, light entering the light-receiving device can be detected and charge can be generated and extracted as current. Alternatively, the pixel electrode may function as a cathode and the common electrode may function as an anode.

A method for manufacturing similar to that of the light-emitting device can be employed for the light-receiving device. An island-shaped active layer (also referred to as a photoelectric conversion layer) included in the light-receiving device is formed by processing a film that is to be the active layer and formed on the entire surface, not by using a pattern of a metal mask; thus, the island-shaped active layer with a uniform thickness can be formed. In addition, a sacrificial layer provided over the active layer can reduce damage to the active layer in the manufacturing process of the display apparatus, increasing the reliability of the light-receiving device.

Here, a layer shared by the light-receiving device and the light-emitting device might have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device might have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

The active layer included in the light-receiving device includes a semiconductor. Examples of the semiconductor include an inorganic semiconductor such as silicon and an organic semiconductor including an organic compound. This embodiment illustrates an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ and C₇₀) and fullerene derivatives. Fullerene has a soccer ball-like shape, which is energetically stable. Both the HOMO level (highest occupied molecular orbital level) and the LUMO level (lowest unoccupied molecular orbital level) of fullerene are deep (low). Having a deep LUMO level, fullerene has an extremely high electron-accepting property (acceptor property). In general, when π-electron conjugation (resonance) spreads in a plane as in benzene, an electron-donating property (donor property) becomes high; however, since fullerene has a spherical shape, fullerene has a high electron-accepting property even when π-electron conjugation widely spreads therein. The high electron-accepting property efficiently causes rapid charge separation and is useful for the light-receiving element. Both C₆₀ and C₇₀ have a wide absorption band in the visible light region, and C₇₀ is especially preferable because of having a larger π-electron conjugation system and a wider absorption band in the long wavelength region than C₆₀. Other examples of fullerene derivatives include [6,6]-phenyl-C₇₁-butyric acid methyl ester (abbreviation: PC₇₀BM), [6,6]-phenyl-C₆₁-butyric acid methyl ester (abbreviation: PC₆₀BM), and 1′,1″,4′,4″-tetrahydro-di[1,4]methanonaphthaleno[1,2:2′,3′,56,60:2″,3″][5,6]fullerene-C₆₀ (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Other examples of the p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, the light-receiving device may further include a layer containing any of a substance with a high hole-transport property, a substance with a high electron-transport property, a substance with a bipolar property (a substance with a high electron-transport property and a high hole-transport property), and the like. Without limitation to the above, a layer containing one or more selected from a substance with a high hole-injection property, a hole-blocking material, a material with a high electron-injection property, and an electron-blocking material may be further included.

Either a low molecular compound or a high molecular compound can be used in the light-receiving device, and an inorganic compound may also be included. Each layer included in the light-receiving device can be formed by an evaporation method (including a vacuum evaporation method), a transfer method, a printing method, an inkjet method, or a coating method.

As the hole-transport material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for example. As the electron-transport material, an inorganic compound such as zinc oxide (ZnO) can be used.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the wavelength range. The third material may be a low molecular compound or a high molecular compound.

In the display apparatus including the light-emitting device and the light-receiving device in the pixel, the pixel has a light-receiving function, which enables detection of a touch or approach of an object while an image is displayed. For example, all the subpixels included in the display apparatus can display an image; alternatively, some of the subpixels can emit light as a light source and the other subpixels can display an image.

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or an approach or touch of an object (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting device included in the display portion, the light-receiving device can detect reflected light (or scattered light); thus, image capturing or touch detection is possible even in a dark place.

In the case where the light-receiving devices are used as the image sensor, the display apparatus can capture an image with the use of the light-receiving devices. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus; thus, the size and weight of the electronic device can be reduced.

In the case where the light-receiving devices are used as the touch sensor, the display apparatus can detect an approach or touch of an object with the use of the light-receiving devices.

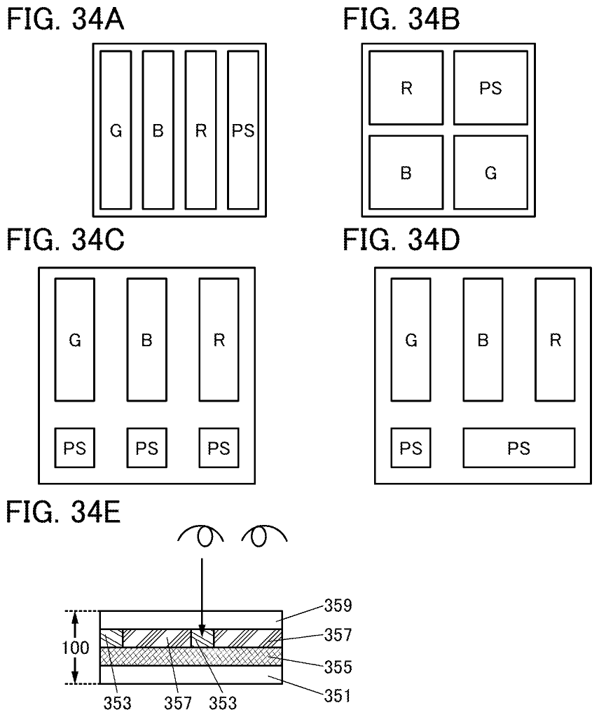

Pixels illustrated in FIG. 34A to FIG. 34D each include the subpixel G, the subpixel B, the subpixel R, and a subpixel PS.

The pixel illustrated in FIG. 34A employs stripe arrangement. The pixel illustrated in FIG. 34B employs matrix arrangement.

FIG. 34C and FIG. 34D illustrate an example where one pixel is provided in two rows and three columns. Three subpixels (the subpixel G, the subpixel B, and the subpixel R) are provided in the upper row (first row). In FIG. 34C, three subpixels PS are provided in the lower row (second row). In FIG. 34D, two subpixels PS are provided in the lower row (second row). Aligning the positions of the subpixels in the upper row and the lower row as illustrated in FIG. 34C enables dust and the like that would be produced in the manufacturing process to be removed efficiently. Thus, a display apparatus with high display quality can be provided. Note that the layout of the subpixels is not limited to the structures illustrated in FIG. 34A to FIG. 34D.

Each of the subpixel R, the subpixel G, and the subpixel B includes a light-emitting device that emits white light. In each of the subpixel R, the subpixel G, and the subpixel B, the corresponding coloring layer is provided to overlap with the light-emitting device.

The subpixel PS includes the light-receiving device. There is no particular limitation on the wavelength of light detected by the subpixel PS.

The light-receiving device included in the subpixel PS preferably detects visible light, and preferably detects one or more selected from blue light, violet light, bluish violet light, green light, yellowish green light, yellow light, orange light, and red light, for example. The light-receiving device included in the subpixel PS may detect infrared light.

The display apparatus 100 illustrated in FIG. 34E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. For example, a switch, a transistor, a capacitor, a resistor, a wiring, a terminal, and the like can be provided in the functional layer 355. Note that in the case where the light-emitting device and the light-receiving device are driven by a passive-matrix method, a structure not provided with a switch and a transistor may be employed.

For example, after light emitted from the light-emitting device in the layer 357 including light-emitting devices is reflected by a human eye and its surroundings as illustrated in FIG. 34E, the light-receiving device in the layer 353 including light-receiving devices detects the reflected light. Accordingly, information of the surroundings, surface, or inside of the human eye (e.g., the number of blinks, the movement of an eyeball, and the movement of an eyelid) can be detected.

Note that the insulators, the conductors, the semiconductors, and the like disclosed in this specification and the like can be formed by a PVD (Physical Vapor Deposition) method or a CVD method. Examples of a PVD method include a sputtering method, a resistance heating evaporation method, an electron beam evaporation method, and a PLD (Pulsed Laser Deposition) method. Examples of the CVD method include a plasma CVD method and a thermal CVD method. In particular, examples of a thermal CVD method include a MOCVD (Metal Organic Chemical Vapor Deposition) method and an ALD method.

A thermal CVD method, which is a deposition method not using plasma, has an advantage that no defect due to plasma damage is generated.

Deposition by a thermal CVD method may be performed in such a manner that a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in such a manner that pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to deposit a first thin layer; then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the thickness and is thus suitable for manufacturing a minute FET.

A variety of films such as the metal film, the semiconductor film, and the inorganic insulating film disclosed in the above-described embodiments can be formed by a thermal CVD method such as an MOCVD method and an ALD method; for example, in the case of depositing an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus using ALD method, two kinds of gases, ozone (O₃) as an oxidizer and a source gas which is obtained by vaporizing liquid containing a solvent and a hafnium precursor compound (e.g., hafnium alkoxide and hafnium amide such as tetrakis(dimethylamide)hafnium (TDMAH, Hf[N(CH₃)₂]₄)), are used. Examples of another material include tetrakis(ethylmethylamide)hafnium.

For example, in the case where an aluminum oxide film is formed with a deposition apparatus using an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)) are used. Examples of another material include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface on which a film is to be formed, and radicals of an oxidizing gas (O₂ or dinitrogen monoxide) are supplied to react with the adsorbate.

For example, in the case where a tungsten film is deposited by a deposition apparatus using an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

In the case where an In—Ga—Zn—O film is deposited as an oxide semiconductor film with a deposition apparatus using an ALD method, a precursor (generally referred to as a metal precursor or the like in some cases) and an oxidizer (generally referred to as a reactant, a non-metal precursor, or the like in some cases) are sequentially and repetitively introduced. Specifically, for example, an In(CH₃)₃ gas as a precursor and an O₃ gas as an oxidizer are introduced to form an In—O layer; a Ga(CH₃)₃ gas as a precursor and an O₃ gas as an oxidizer are introduced to form a GaO layer; and then, a Zn(CH₃)₂ gas as a precursor and an O₃ gas as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas such as Ar may be used instead of an O₃ gas, it is preferable to use an O₃ gas which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, a Zn(CH₃)₂ gas may be used.

There is no particular limitation on the screen ratio (aspect ratio) of the display portion of the electronic device of one embodiment of the present invention. For example, the display portion is compatible with a variety of screen ratios such as 1:1 (a square), 4:3, 16:9, and 16:10.

There is no particular limitation on the shape of the display portion of the electronic device of one embodiment of the present invention. The display portion can have any of various shapes such as a rectangular shape, a polygonal shape (e.g., octagon), a circular shape, and an elliptical shape.

Note that this embodiment can be combined with any of the other embodiments described in this specification as appropriate.

### Embodiment 5

In this embodiment, a display module that can be used for the electronic device of one embodiment of the present invention is described.

### Structure Example of Display Module

First, a display module including the display apparatus which can be used for the electronic device of one embodiment of the present invention is described.

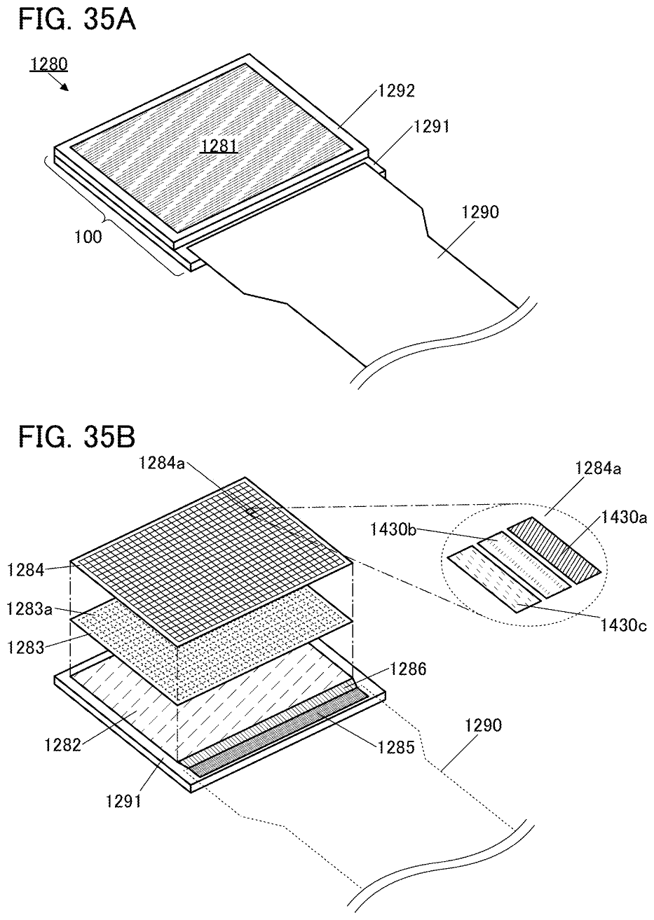

FIG. 35A is a perspective view of a display module 1280. The display module 1280 includes the display apparatus 100 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 35B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the pixel layer PXAL described above, for example. The circuit portion 1282 corresponds to the circuit layer SICL described above, for example.

The pixel portion 1284 includes a plurality of pixels 1284a arranged periodically. An enlarged view of one pixel 1284a is illustrated on the right side in FIG. 35B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 150a, the light-emitting device 150b, and the light-emitting device 150c described above. The above-described light emitting devices may be arranged in a stripe pattern as illustrated in FIG. 35B. Alternatively, a variety of arrangement methods, such as delta arrangement and pentile arrangement, can be employed.

The pixel circuit portion 1283 includes a plurality of pixel circuits 1283a arranged periodically.

One pixel circuit 1283a is a circuit that controls light emission of three light-emitting devices included in one pixel 1284a. One pixel circuit 1283a may be provided with three circuits each of which controls light emission of one light-emitting device. For example, the pixel circuit 1283a can include one or more selected from one selection transistor, one current control transistor (driving transistor), and a capacitor for one light-emitting device. In this case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of agate line driver circuit and a source line driver circuit are preferably included. In addition, one or more selected from an arithmetic circuit, a memory circuit, and a power supply circuit may be included.

The FPC 1290 functions as a wiring for supplying a video signal, a power supply potential, or the like to the circuit portion 1282 from the outside. In addition, an IC may be mounted on the FPC 1290.

The display module 1280 can have a structure where one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%. Furthermore, the pixels 1284a can be arranged extremely densely and thus the display portion 1281 can have an extremely high resolution. For example, the pixels 1284a are preferably arranged in the display portion 1281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such the display module 1280 has an extremely high resolution, and thus can be suitably used for a VR device such as a head mounted display or a glasses-type AR device. For example, even with a structure where the display portion of the display module 1280 is seen through a lens, pixels of the extremely-high-resolution display portion 1281 included in the display module 1280 are prevented from being perceived when the display portion is enlarged by the lens, so that display providing a strong sense of immersion can be performed. Without being limited thereto, the display module 1280 can be suitably used for electronic devices including a relatively small display portion. For example, the display module 1280 can be suitably used in a display portion of an electronic device that is be worn on a human body, such as a wrist-watch-type electronic device.

Note that this embodiment can be combined with any of the other embodiments described in this specification as appropriate.

### Embodiment 6

In this embodiment, electronic devices each including a display apparatus are described as examples of an electronic device of one embodiment of the present invention.

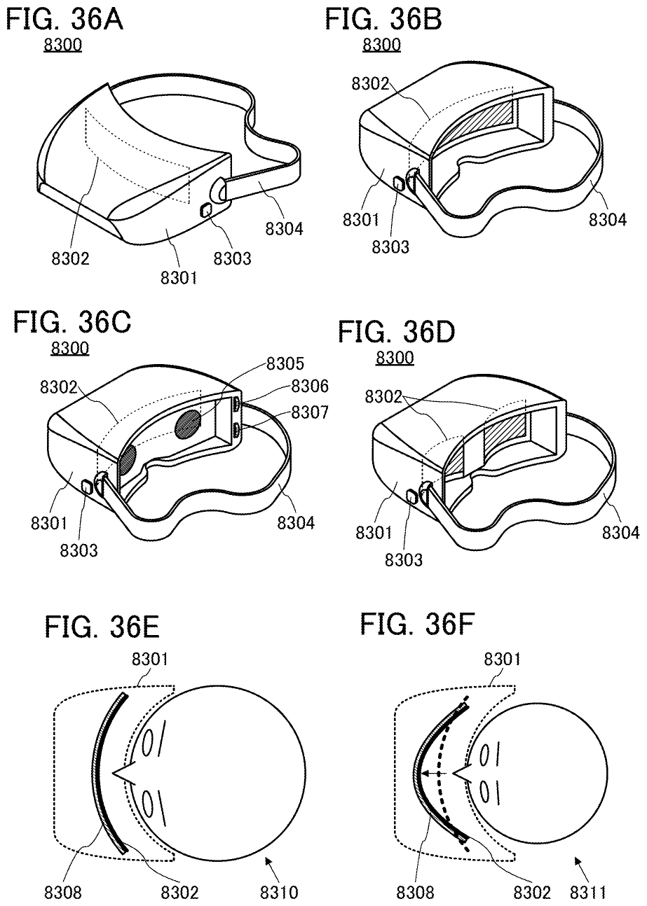

FIG. 36A and FIG. 36B each illustrate an appearance of an electronic device 8300 that is a head-mounted display.

The electronic device 8300 includes a housing 8301, a display portion 8302, an operation button 8303, and a band-shaped fixing unit 8304.

The operation button 8303 has a function of a power button or the like. The electronic device 8300 may include a button other than the operation button 8303.

As illustrated in FIG. 36C, lenses 8305 may be included between the display portion 8302 and the positions of the user's eyes. The user can see magnified images on the display portion 8302 through the lenses 8305, leading to a higher realistic sensation. In this case, as illustrated in FIG. 36C, a dial 8306 for changing the positions of the lenses and adjusting visibility may be included.

For the display portion 8302, a display apparatus with an extremely high resolution is preferably used, for example. When a high-resolution display apparatus is used for the display portion 8302, it is possible to display a more realistic image that does not allow the user to perceive pixels even when the image is magnified using the lenses 8305 as illustrated in FIG. 36C.

FIG. 36A to FIG. 36C illustrate an example where one display portion 8302 is provided. Such a structure can reduce the number of components.

The display portion 8302 can display an image for the right eye and an image for the left eye side by side on a right region and a left region, respectively. Thus, a three-dimensional image using binocular disparity can be displayed.

One image which can be seen by both eyes may be displayed on the entire display portion 8302. A panorama image can thus be displayed from end to end of the field of view, which can provide a stronger sense of reality.

Here, the electronic device 8300 preferably has, for example, a mechanism for changing the curvature of the display portion 8302 to an optimal value in accordance with one or both of the size of the user's head and the position of the user's eyes. For example, the user himself or herself may adjust the curvature of the display portion 8302 by operating a dial 8307 for adjusting the curvature of the display portion 8302. Alternatively, a sensor for detecting the size of the user's head, the position of the user's eyes, or the like (e.g., a camera, a contact sensor, and a noncontact sensor) may be provided on the housing 8301, and a mechanism for adjusting the curvature of the display portion 8302 on the basis of detection data obtained by the sensor may be provided.

In the case where the lenses 8305 are used, a mechanism for adjusting the position and angle of the lenses 8305 in synchronization with the curvature of the display portion 8302 is preferably provided. Alternatively, the dial 8306 may have a function of adjusting the angle of the lenses.

FIG. 36E and FIG. 36F illustrate an example where a driver portion 8308 controlling the curvature of the display portion 8302 is provided. The driver portion 8308 is fixed to at least a part of the display portion 8302. The driver portion 8308 has a function of changing the shape of the display portion 8302 when the part that is fixed to the display portion 8302 changes in shape or moves.

FIG. 36E is a schematic diagram illustrating the case where a user 8310 having a relatively large head wears the housing 8301. In this case, the driver portion 8308 adjusts the shape of the display portion 8302 so that the curvature is relatively small (the radius of curvature is large).

By contrast, FIG. 36F illustrates the case where a user 8311 having a smaller head than the user 8310 wears the housing 8301. The user 8311 has a shorter distance between the eyes than the user 8310. In this case, the driver portion 8308 adjusts the shape of the display portion 8302 so that the curvature of the display portion 8302 is large (the radius of curvature is small). In FIG. 36F, the position and shape of the display portion 8302 in FIG. 36E are denoted by a dashed line.

When the electronic device 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a more realistic sensation. For example, shaking can be expressed by fluctuating the curvature of the display portion 8302. In this way, it is possible to produce various effects in depending on the scene in contents, and provide the user with new experiences. A further realistic display can be provided when the display portion 8302 operates in conjunction with a vibration module provided in the housing 8301.

Note that the electronic device 8300 may include two display portions 8302 as illustrated in FIG. 36D.

Since the two display portions 8302 are included, the user's eyes can see their respective display portions. This allows a high-definition image to be displayed even when three-dimensional display using parallax is performed. In addition, the display portion 8302 is curved around an arc with the user's eye as an approximate center. This allows a uniform distance between the user's eye and display surface of the display portion; thus, the user can see a more natural image. Even when the luminance or chromaticity of light from the display portion is changed depending on the angle at which the user see it, since the user's eye is positioned in a normal direction of the display surface of the display portion, the influence of the change can be substantially ignorable and thus a more realistic image can be displayed.

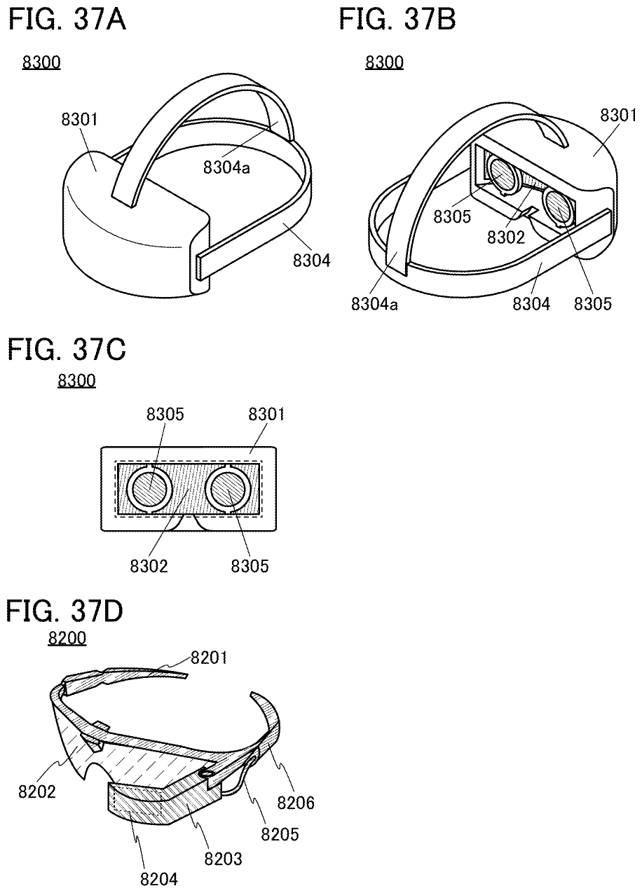

FIG. 37A to FIG. 37C are diagrams illustrating an appearance of another electronic device 8300, which is different from the electronic devices 8300 illustrated in FIG. 36A to FIG. 36D. Specifically, FIG. 37A to FIG. 37C are different from FIG. 36A to FIG. 36D in including a fixing means 8304a worn on a head and a pair of lenses 8305, for example.

A user can see display on the display portion 8302 through the lenses 8305. The display portion 8302 is preferably curved so that the user can feel high realistic sensation. Another image displayed on another region of the display portion 8302 is seen through the lenses 8305, so that three-dimensional display using parallax can be performed. Note that the structure is not limited to the structure where one display portion 8302 is provided; two display portions 8302 may be provided and one display portion may be provided per eye of the user.

For the display portion 8302, a display apparatus with a high resolution is preferably used, for example. When a high-resolution display apparatus is used for the display portion 8302, it is possible to display a more realistic image that does not allow the user to perceive pixels even when the image is magnified using the lenses 8305 as illustrated in FIG. 37C.

The head-mounted display, which is an electronic device of one embodiment of the present invention, may be an electronic device 8200 illustrated in FIG. 37D, which is a glasses-type head-mounted display.

The electronic device 8200 includes a mounting portion 8201, a lens 8202, a main body 8203, a display portion 8204, and a cable 8205. A battery 8206 is incorporated in the mounting portion 8201.

The cable 8205 supplies power from the battery 8206 to the main body 8203. The main body 8203 includes a wireless receiver and can display received video information on the display portion 8204. The main body 8203 includes a camera, and information on the movement of the eyeballs or the eyelids of the user can be used as an input means.

The mounting portion 8201 may include a plurality of electrodes capable of sensing current flowing accompanying with the movement of the user's eyeballs at a position in contact with the user to recognize his or her gaze. The mounting portion 8201 may also have a function of monitoring the user's pulse with use of current flowing through the electrodes. The mounting portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

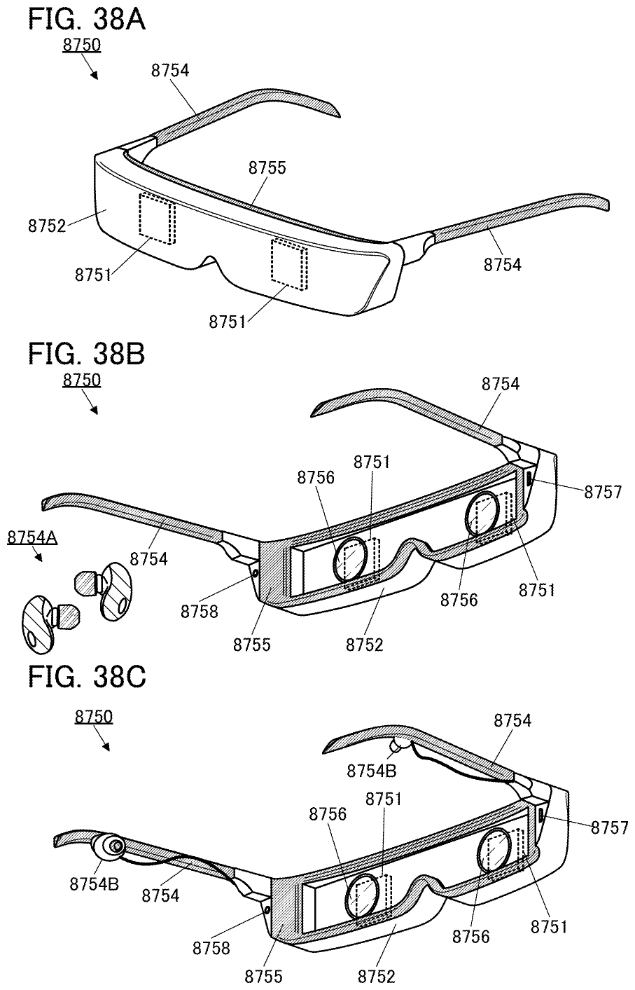

FIG. 38A to FIG. 38C are diagrams illustrating appearances of an electronic device 8750, which is different from the electronic devices 8300 illustrated in FIG. 36A to FIG. 36D and FIG. 37A to FIG. 37C and the electronic device 8200 illustrated in FIG. 37D.

FIG. 38A is a perspective view illustrating the front surface, the top surface, and the left side surface of the electronic device 8750, and FIG. 38B and FIG. 38C are each a perspective view illustrating the back surface, the bottom surface, and the right side surface of the electronic device 8750.

The electronic device 8750 includes a pair of display apparatuses 8751, a housing 8752, a pair of wearing portions 8754, a cushion 8755, a pair of lenses 8756, and the like. The pair of display apparatuses 8751 is positioned to be seen through the lenses 8756 inside the housing 8752.

Here, one of the pair of display apparatuses 8751 corresponds to the display apparatus 100A or the like illustrated in FIG. 14. Although not illustrated, the electronic device 8750 illustrated in FIG. 38A to FIG. 38C includes an electronic component including the processing unit described in the above embodiment (e.g., the functional circuit MFNC and the peripheral circuit DRV illustrated in FIG. 14). Although not illustrated, the electronic device 8750 illustrated in FIG. 38A to FIG. 38C includes a camera (e.g., the sensor PDA illustrated in FIG. 14). The camera can take an image of the user's eye and its periphery. Although not illustrated, in the housing 8752 of the electronic device 8750 illustrated in FIG. 38A to FIG. 38C, a motion detection portion, an audio, a control portion, a communication portion, and a battery are provided.

The electronic device 8750 is an electronic device for VR. A user wearing the electronic device 8750 can see an image displayed on the display apparatus 8751 through the lens 8756. Furthermore, the pair of display apparatuses 8751 may display different images, whereby three-dimensional display using parallax can be performed.

An input terminal 8757 and an output terminal 8758 are provided on the back side of the housing 8752. To the input terminal 8757, a cable for supplying a video signal from a video output device or the like, power for charging a battery provided in the housing 8752, or the like can be connected. The output terminal 8758 can function as, for example, an audio output terminal to which earphones, headphones, or the like can be connected.

The housing 8752 preferably includes a mechanism by which the left and right positions of the lens 8756 and the display apparatus 8751 can be adjusted to the optimal positions in accordance with the position of the user's eye. In addition, the housing 8752 preferably includes a mechanism for adjusting focus by changing the distance between the lens 8756 and the display apparatus 8751.

With use of the camera, the display apparatus 8751, and the above electronic component, the electronic device 8750 can estimate the state of a user of the electronic device 8750 and can display information on the estimated user's state on the display apparatus 8751. Alternatively, information on a user of an electronic device connected to the electronic device 8750 through a network can be displayed on the display apparatus 8751.

The cushion 8755 is a portion in contact with the user's face (e.g., forehead and cheek). The cushion 8755 is in close contact with the user's face, so that light leakage can be prevented, which increases the sense of immersion. A soft material is preferably used for the cushion 8755 so that the cushion 8755 is in close contact with the face of the user wearing the electronic device 8750. For example, any of a variety of materials such as rubber, silicone rubber, urethane, and sponge can be used. Furthermore, when a sponge whose surface is covered with cloth or leather (natural leather or synthetic leather) is used, a gap is unlikely to be generated between the user's face and the cushion 8755, whereby light leakage can be suitably prevented. Furthermore, using such a material is preferable because it has a soft texture and the user does not feel cold when wearing the device in a cold season, for example. The member in contact with user's skin, such as the cushion 8755 or the wearing portion 8754, is preferably detachable because cleaning or replacement can be easily performed.

The electronic device in this embodiment may further include earphones 8754A. The earphones 8754A include a communication portion (not illustrated) and have a wireless communication function. The earphones 8754A can output audio data with the wireless communication function. Note that the earphones 8754A may include a vibration mechanism to function as bone-conduction earphones.

Like earphones 8754B illustrated in FIG. 38C, the earphones 8754A can be connected to the wearing portion 8754 directly or by wiring. The earphones 8754B and the wearing portion 8754 may each have a magnet. This is preferable because the earphones 8754B can be fixed to the wearing portion 8754 with magnetic force and thus can be easily housed.

The earphones 8754A may include a sensor portion. With use of the sensor portion, the state of the user of the electronic device can be estimated.

The electronic device of one embodiment of the present invention may include one or more of an antenna, a battery, a camera, a speaker, a microphone, a touch sensor, and an operation button, in addition to any one of the above components.

The electronic device of one embodiment of the present invention may include a secondary battery, and it is preferable that the secondary battery be capable of being charged by contactless power transmission.

Examples of the secondary battery include a lithium ion secondary battery such as a lithium polymer battery using a gel electrolyte (lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display a video, information, or the like on a display portion. When the electronic device includes an antenna and a secondary battery, the antenna may be used for contactless power transmission.

A display portion in an electronic device of one embodiment of the present invention can display a video with a definition of, for example, full high definition, 4K2K, 8K4K, 16K8K, or higher.

Note that this embodiment can be combined with any of the other embodiments described in this specification as appropriate.

### REFERENCE NUMERALS

L1: region, L2: region, CA: cell array, SA: subarray, SAr: subarray, WCS: circuit, WCSa: circuit, XCS: circuit, WSD: circuit, ITS: circuit, IM: cell, IMr: cell, IMref: cell, SWS1: circuit, SWS2: circuit, WCG_s: circuit, XCSa: circuit, ITG_s: circuit, ITRZ: converter circuit, ITRZ1: converter circuit, ITRZA: converter circuit, ITRZA1: converter circuit, ITRZA2: converter circuit, CS: current source, CS1: current source, CS2: current source, CS3: current source, CS4: current source, CI: current source, CIr: current source, CM: current mirror circuit, OP1: operational amplifier, VTL: wiring, VWL: wiring, VSE: wiring, CCL: wiring, WCL: wiring, WCLr: wiring, XCL: wiring, WSL: wiring, OL: wiring, SWL1: wiring, SWL2: wiring, SWL3: wiring, VE: wiring, DW: wiring, DX: wiring, VINL1: wiring, VINIL2: wiring, VDDL: wiring, VTHL: wiring, DZ: wiring, VRL: wiring, CLL: wiring, VHE: wiring, V0: wiring, VCOM: wiring, ANO: wiring, F1: transistor, Fir: transistor, F1m: transistor, F2: transistor, F2r: transistor, F2m: transistor, F5: transistor, F5m: transistor, F6: transistor, Tr1: transistor, Tr2: transistor, Tr3: transistor, C5: capacitor, C5r: capacitor, C5m: capacitor, C6: capacitor, LE: load, SW3: switch, SW3r: switch, SW4: switch, SW4r: switch, SW5: switch, SWX: switch, OP1: operational amplifier, ADC: analog-digital converter circuit, ZCSa: circuit, SWW: switch, NN: node, NNref: node, T1: terminal, T2: terminal, SIC: circuit portion, DRV: peripheral circuit, MFNC: functional circuit, DSP: display portion, PDA: sensor, PX: pixel circuit, GL: wiring, GL1: wiring, GL2: wiring, GL3: wiring, SL: wiring, SNCL: wiring, BSL: bus wiring, PXAL: pixel layer, LINL: wiring layer, SICL: circuit layer, EML: layer, OSL: layer, ANN: neural network, 10: arithmetic circuit, 10A: arithmetic circuit, 10AA: arithmetic circuit, 10B: arithmetic circuit, 10C: arithmetic circuit, 11: source driver circuit, 12: digital-analog converter circuit, 13: gate driver circuit, 14: level shifter, 21: memory device, 22: GPU, 22a: circuit, 22b: circuit, 23: EL correction circuit, 24: timing controller, 25: CPU, 26: sensor controller, 27: power supply circuit, 30: driver circuit, 70A: pixel, 70B: pixel, 80: pixel, 80a: subpixel, 80b: subpixel, 80c: subpixel, 80d: subpixel, 85R: hole-injection layer, 85G: hole-injection layer, 85B: hole-injection layer, 86R: hole-transport layer, 86G: hole-transport layer, 86B: hole-transport layer, 86PD: hole-transport layer, 87R: light-emitting layer, 87G: light-emitting layer, 87B: light-emitting layer, 88R: electron-transport layer, 88G: electron-transport layer, 88B: electron-transport layer, 88PD: electron-transport layer, 89: common layer, 90: light-receiving layer, 91: protective layer, 92: insulating layer, 100: display apparatus, 100A: display apparatus, 102: substrate, 111: insulator, 111a: insulator, 111b: insulator, 112: insulator, 113: insulator, 113a: insulator, 113b: insulator, 113c: insulator, 118: sacrificial layer, 119: sacrificial layer, 121a: conductor, 121b: conductor, 121c: conductor, 121CM: conductor, 121B: conductor, 121G: conductor, 121R: conductor, 121PD: conductor, 122a: conductor, 122b: conductor, 122c: conductor, 123: conductor, 123CM: region, 141a: EL layer, 141b: EL layer, 141c: EL layer, 142: EL layer, 150a: light-emitting device, 150b: light-emitting device, 150c: light-emitting device, 150B: light-emitting device, 150G: light-emitting device, 150R: light-emitting device, 150IR: light-emitting device, 160: light-receiving device, 162: insulator, 163: resin layer, 164: adhesive layer, 165: adhesive layer, 166a: coloring layer, 166b: coloring layer, 166c: coloring layer, 200: transistor, 202: insulator, 210: substrate, 214: insulator, 216: conductor, 220: insulator, 222: insulator, 224: insulator, 226: insulator, 228: conductor, 230: conductor, 250: insulator, 300: transistor, 310: substrate, 312: element isolation layer, 313: semiconductor region, 314a: low-resistance region, 314b: low-resistance region, 315: insulator, 316: conductor, 317: insulator, 320: insulator, 322: insulator, 324: insulator, 326: insulator, 328: conductor, 330: conductor, 350: insulator, 351: substrate, 352: insulator, 353: layer, 354: insulator, 355: functional layer, 356: conductor, 357: layer, 359: substrate, 360: insulator, 362: insulator, 364: insulator, 366: conductor, 370: insulator, 372: insulator, 376: conductor, 380: insulator, 400: pixel circuit, 400A: pixel circuit, 400B: pixel circuit, 400C: pixel circuit, 400D: pixel circuit, 400E: pixel circuit, 400F: pixel circuit, 400G: pixel circuit, 400H: pixel circuit, 500: transistor, 500A: transistor, 500B: transistor, 500C: transistor, 500D: transistor, 501: substrate, 512: insulator, 514: insulator, 540: conductor, 576: insulator, 581: insulator, 600: capacitor, 600A: capacitor, 1280: display module, 1281: display portion, 1290: FPC, 1282: circuit portion, 1283: pixel circuit portion, 1283a: pixel circuit, 1284: pixel portion, 1284a: pixel, 1285: terminal portion, 1286: wiring portion, 1291: substrate, 1292: substrate, 1430a: light-emitting device, 1430b: light-emitting device, 1430c: light-emitting device, 4400a: light-emitting unit, 4400b: light-emitting unit, 4411: light-emitting layer, 4412: light-emitting layer, 4413: light-emitting layer, 4420: layer, 4420-1: layer, 4420-2: layer, 4430: layer, 4430-1: layer, 4430-2: layer, 4440: intermediate layer, 8200: electronic device, 8201: wearing portion, 8202: lens, 8203: main body, 8204: display portion, 8205: cable, 8206: battery, 8300: electronic device, 8301: housing, 8302: display portion, 8303: operation button, 8304: fixing unit, 8304a: fixing unit, 8305: lens, 8306: dial, 8307: dial, 8308: driver portion, 8310: user, 8311: user, 8750: electronic device, 8751: display apparatus, 8752: housing, 8754: wearing portion, 8754A: earphone, 8754B: earphone, 8756: lens, 8757: input terminal, 8758: output terminal

1. A semiconductor device comprising:
a first cell array, a second cell array, and a first converter circuit,
wherein the first cell array comprises a first cell and a second cell positioned in the same row as the first cell,
wherein the second cell array comprises a third cell and a fourth cell positioned in the same row as the third cell,
wherein the first converter circuit comprises a plurality of input terminals and a plurality of output terminals,
wherein the first cell is electrically connected to a first wiring and a second wiring,
wherein the second cell is electrically connected to the first wiring and a third wiring,
wherein each of the plurality of input terminals of the first converter circuit is electrically connected to the second wiring and the third wiring,
wherein each of the plurality of output terminals of the first converter circuit is electrically connected to a fourth wiring and a fifth wiring,
wherein the third cell is electrically connected to the fourth wiring and a sixth wiring,
wherein the fourth cell is electrically connected to the fifth wiring and a seventh wiring,
wherein the first cell is configured to make a first current with an amount corresponding to a product of a first data retained in the first cell and a second data input from the first wiring to the first cell flow to the second wiring,
wherein the second cell is configured to make a second current with an amount corresponding to a product of a third data retained in the second cell and a fourth data input from the first wiring to the second cell flow to the third wiring,
wherein the first converter circuit is configured to make a fifth data corresponding to a total amount of current flowing from the second wiring flow to the fourth wiring and is configured to make a sixth data corresponding to a total amount of current flowing from the third wiring flow to the fifth wiring,
wherein the third cell is configured to make a third current with an amount corresponding to a product of a seventh data retained in the third cell and the fifth data input from the fourth wiring to the third cell flow to the sixth wiring,
wherein the fourth cell is configured to make a fourth current with an amount corresponding to a product of an eighth data retained in the fourth cell and the sixth data input from the fifth wiring to the fourth cell flow to the seventh wiring, and
wherein the sixth wiring is electrically connected to the seventh wiring.

2. The semiconductor device according to claim 1, further comprising:
a second converter circuit,
wherein the second converter circuit comprises an input terminal and an output terminal,
wherein the input terminal of the second converter circuit is electrically connected to the sixth wiring, and
wherein the second converter circuit is configured to output a ninth data corresponding to a total amount of current flowing from the sixth wiring to the output terminal of the second converter circuit.

3. The semiconductor device according to claim 1, further comprising:
a fifth cell, a sixth cell, and a seventh cell,
wherein the first cell, the second cell, the third cell, and the fourth cell each include a first transistor, a second transistor, and a first capacitor,
wherein the fifth cell, the sixth cell, and the seventh cell each include a third transistor, a fourth transistor, and a second capacitor,
wherein, in each of the first cell, the second cell, the third cell, and the fourth cell, a gate of the first transistor is electrically connected to a first terminal of the first capacitor and a first terminal of the second transistor,
wherein, in each of the first cell, the second cell, the third cell, and the fourth cell, a first terminal of the first transistor is electrically connected to a second terminal of the second transistor,
wherein, in the first cell, the first terminal of the first transistor is electrically connected to the second wiring,
wherein, in the first cell, a second terminal of the first capacitor is electrically connected to the first wiring,
wherein, in the second cell, the first terminal of the first transistor is electrically connected to the third wiring,
wherein, in the second cell, a second terminal of the first capacitor is electrically connected to the first wiring,
wherein, in the third cell, the first terminal of the first transistor is electrically connected to the sixth wiring,
wherein, in the third cell, a second terminal of the first capacitor is electrically connected to the fourth wiring,
wherein, in the fourth cell, the first terminal of the first transistor is electrically connected to the seventh wiring,
wherein, in the fourth cell, a second terminal of the first capacitor is electrically connected to the fifth wiring,
wherein, in each of the fifth cell, the sixth cell, and the seventh cell, a gate of the third transistor is electrically connected to a first terminal of the second capacitor and a first terminal of the fourth transistor,
wherein, in each of the fifth cell, the sixth cell, and the seventh cell, a first terminal of the third transistor is electrically connected to a second terminal of the fourth transistor,
wherein, in the fifth cell, the first terminal of the third transistor is electrically connected to the first wiring,
wherein, in the fifth cell, a second terminal of the second capacitor is electrically connected to the first wiring,
wherein, in the sixth cell, the first terminal of the third transistor is electrically connected to the fourth wiring,
wherein, in the sixth cell, a second terminal of the second capacitor is electrically connected to the fourth wiring,
wherein, in the seventh cell, the first terminal of the third transistor is electrically connected to the fifth wiring, and
wherein, in the seventh cell, a second terminal of the second capacitor is electrically connected to the fifth wiring.

4. The semiconductor device according to claim 3, further comprising:
a first circuit and a second circuit,
wherein the first circuit is electrically connected to the first wiring,
wherein the second circuit is electrically connected to the fourth wiring and the fifth wiring,
wherein the first circuit is configured to input the second data to the first wiring, and
wherein the second circuit is configured to make current flow to the fourth wiring and the fifth wiring.

5. A display apparatus comprising:
a first layer comprising the semiconductor device according to claim 1 and a second layer comprising a display portion,
wherein the second layer comprises a region overlapping with the first layer.

6. An electronic device comprising the display apparatus according to claim 5 and a housing.
